(19) United States
(12) Patent Application Publication
(10) Pub. No.: US 2023/0163013 A1
(43) Pub. Date: May 25, 2023

(54) PROCESSES AND APPLICATIONS FOR CATALYST INFLUENCED CHEMICAL ETCHING

(71) Applicant: Board of Regents, The University of Texas System, Austin, TX (US)

(72) Inventors: Sidlgata V. Sreenivasan, Austin, TX (US); Paras Ajay, Austin, TX (US); Akhila Mallavarapu, Philadelphia, PA (US); Crystal Barrera, Austin, TX (US)

(21) Appl. No.: 18/090,471

(22) Filed: Dec. 28, 2022

Related U.S. Application Data
(63) Continuation of application No. 18/010,456, filed on Jan. 1, 0001.
(60) Provisional application No. 63/167,462, filed on Mar. 29, 2021.
(60) Provisional application No. 63/174,128, filed on Apr. 13, 2021.
(60) Provisional application No. 63/215,807, filed on Jun. 28, 2021.

(51) Int. Cl. H01L 21/683; H01L 21/3065; H01L 21/67; H01L 21/687; H01L 23/544; H01L 27/06

(52) U.S. Cl. CPC H01L 21/6833; H01L 21/3065; H01L 21/6838; H01L 21/67069; H01L 21/68721; H01L 21/67259; H01L 21/6836; H01L 23/544; H01L 27/0688; H01L 2221/68327; H01L 2223/54426

(57) ABSTRACT

A system for assembling fields from a source substrate onto a second substrate. The source substrate includes fields. The system further includes a transfer chuck that is used to pick at least four of the fields from the source substrate in parallel to be transferred to the second substrate, where the relative positions of the at least four of the fields is predetermined.

### TECHNICAL FIELD

The present invention relates generally to etching, and more particularly to equipment and process technologies for catalyst influenced chemical etching.

### BACKGROUND

In semiconductor device fabrication, etching refers to any technology that will selectively remove material from a thin film on a substrate (with or without prior structures on its surface) and by this removal create a pattern of that material on the substrate. The pattern may be defined by a mask that is resistant to the etching process. Once the mask is in place, etching of the material that is not protected by the mask can occur, by either wet chemical or by “dry” physical methods.

One type of etching is Catalyst Influenced Chemical Etching (CICE), which is a catalyst-based etching method that can be used to fabricate features in semiconductors, such as silicon, germanium, etc., where such features have high aspect ratios, low sidewall taper, low sidewall roughness, and/or controllable porosity. This method is used to create higher density and higher performance Static Random-Access Memory (SRAM) as well as low-loss waveguides.

Unfortunately, there are currently limitations in fabricating features in semiconductors using CICE.

### SUMMARY

In one embodiment of the present invention, a system for changing a relative position of a group of items comprises a first set of parallel rails, where each parallel rail in the first set of parallel rails is moveable with respect to each other. The system further comprises a second set of parallel rails, where each parallel rail in the second set of parallel rails is moveable with respect to each other and the first set of parallel rails. The system additionally comprises a guiding mechanism configured to guide one or more items of the group of items on one or more of the first and second sets of parallel rails.

In another embodiment of the present invention, a method to chuck dies of various sizes comprises identifying addressable regions of one or more dies using vacuum or electrostatic attraction. The method further comprises chucking the one or more dies using the identified addressable regions, where the one or more dies have a size ranging from 0.5 mm on a side to 200 mm on the side, and where the chucking utilizes a material that has a higher hardness in comparison to the one or more dies.

In a further embodiment of the present invention, a three-dimensional (3D) integrated circuit (IC) comprises one or more two-dimensional (2D)-die, where the one or more 2D-die are fabricated by assembling the one or more 2D-die onto a product substrate, where one or more of the one or more 2D-die comprise a light sensitive pixel array, and where the assembling is enabled by: selectively picking the one or more 2D-die from a source wafer by a superstrate attached to the one or more 2D-die and placing and bonding the selectively picked one or more 2D-die onto the product substrate with precision overlay, where the precision overlay is enabled by a fluid deployed between the one or more 2D-die and the product substrate, and where the precision overlay comprises a difference between a vector position of points on the one or more 2D-die and a vector position of corresponding points on the product substrate.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates an exemplary tool for pick-and-place assembly in accordance with an embodiment of the present invention;

FIGS. 2A-2B illustrate an exemplary design for the source/product/intermediate substrate chucks in accordance with an embodiment of the present invention;

FIG. 3 illustrates an exemplary design for the source substrate chuck with an ultraviolet (UV) light emitting diode (LED) array for field release in accordance with an embodiment of the present invention;

FIG. 4A illustrates a transfer chuck with attached fields in accordance with an embodiment of the present invention;

FIG. 4B illustrates a cross-section view of the transfer chuck in accordance with an embodiment of the present invention;

FIG. 4C illustrates a top view of an xy actuator layer in accordance with an embodiment of the present invention;

FIG. 4D illustrates a top view of the pneumatic valve layer in accordance with an embodiment of the present invention;

FIG. 4E illustrates an alternative top view of the pneumatic value layer in accordance with an embodiment of the present invention;

FIG. 5A illustrates an exemplary illustration of a transfer chuck (TC) that contains custom-fabricated layers for each new field type in accordance with an embodiment of the present invention;

FIG. 5B illustrates an expanded view of the transfer chuck that contains custom-fabricated layers for each new field type in accordance with an embodiment of the present invention;

FIG. 6A illustrates an exemplary transfer chuck (TC) composed of compliant pins in accordance with an embodiment of the present invention;

FIG. 6B illustrates an expanded view of a portion of the top metal layer of the transfer chuck in accordance with an embodiment of the present invention;

FIG. 6C illustrates an expanded view of the thin skins located on the bottom portion of the top metal layer of the transfer chuck as shown in FIG. 6B in accordance with an embodiment of the present invention;

FIG. 7 illustrates the exemplary labelling of the fields in a rectangular bounding region that is assemble-able using an actuator grid using 9 labels (9 assembly steps) in accordance with an embodiment of the present invention;

FIG. 8 illustrates an exemplary process showing intermediate substrates used for assembly in accordance with an embodiment of the present invention;

FIG. 9 illustrates an exemplary illustration of multiple TCs being used during assembly in accordance with an embodiment of the present invention;

FIG. 10 illustrates an exemplary reconfigurable-grid TC in accordance with an embodiment of the present invention;

FIGS. 11A-11B illustrate an exemplary TC with closed-boundary vacuum and/or pressure regions in accordance with an embodiment of the present invention;

FIGS. 12A-12B illustrate an alternative embodiment of an exemplary TC with closed-boundary vacuum and/or pressure regions in accordance with an embodiment of the present invention;

FIGS. 13A-13C are a further alternative embodiment of an exemplary TC with closed-boundary vacuum and/or pressure regions in accordance with an embodiment of the present invention;

FIG. 14 illustrates an exemplary sensor arrangement for an exemplary metrology module in accordance with an embodiment of the present invention;

FIG. 15 illustrates an alternative exemplary sensor arrangement for an exemplary metrology module in accordance with an embodiment of the present invention;

FIG. 16 illustrates an exemplary reconfiguring-grid sensor arrangement for an exemplary metrology module in accordance with an embodiment of the present invention;

FIG. 17 illustrates the reconfiguring-grid sensor arrangement shown in FIG. 16 expanded out to acquire 30 mm×3 mm fields in accordance with an embodiment of the present invention;

FIGS. 18A-18D illustrate an exemplary alignment metrology framework for an exemplary metrology module in accordance with an embodiment of the present invention;

FIGS. 19A-19C illustrate an alternative exemplary alignment metrology framework for an exemplary metrology module in accordance with an embodiment of the present invention;

FIGS. 20A-20C illustrate the details regarding an exemplary metrology module in accordance with an embodiment of the present invention;

FIG. 21 illustrates an exemplary metrology framework in accordance with an embodiment of the present invention;

FIG. 22 illustrates an exemplary field containing a 2×2 array of dies in accordance with an embodiment of the present invention;

FIG. 23 illustrates an exemplary metrology framework in accordance with an embodiment of the present invention;

FIG. 24 illustrates another embodiment of an exemplary metrology framework in accordance with an embodiment of the present invention;

FIG. 25 illustrates a further embodiment of an exemplary metrology framework in accordance with an embodiment of the present invention;

FIGS. 26A-26B illustrate an exemplary known-bad-die replacement chuck (KRC) in accordance with an embodiment of the present invention;

FIGS. 27A-27C illustrate exemplary source substrate types in accordance with an embodiment of the present invention;

FIGS. 28A-28B illustrate an exemplary field with an exemplary multi-layer encapsulation in accordance with an embodiment of the present invention;

FIGS. 29A-29B illustrate an exemplary face-to-back (F2B) and face-to-face (F2F) device stacks in accordance with an embodiment of the present invention;

FIG. 30 illustrates an exemplary assembly of static random access memory (SRAM) on a logic field in accordance with an embodiment of the present invention;

FIG. 31 illustrates an exemplary assembly of multiple stacked static random access memory (SRAM) on a logic field in accordance with an embodiment of the present invention;

FIG. 32 illustrates an exemplary assembly of static random access memory (SRAM) on a logic field with an error-correcting interposer in the middle in accordance with an embodiment of the present invention;

FIG. 33 illustrates an exemplary sequence for pick-and-place assembly in accordance with an embodiment of the present invention;

FIG. 34 illustrates an alternative exemplary sequence for pick-and-place assembly in accordance with an embodiment of the present invention;

FIG. 35 illustrates a further alternative exemplary sequence for pick-and-place assembly in accordance with an embodiment of the present invention;

FIGS. 36A-36B illustrate an exemplary transfer chuck in accordance with an embodiment of the present invention;

FIGS. 37A-37O illustrate an alternative exemplary transfer chuck in accordance with an embodiment of the present invention;

FIGS. 38A-38C illustrate an exemplary reconfiguring transfer chuck (TC) in accordance with an embodiment of the present invention;

FIGS. 39A-39C illustrate an exemplary transfer chuck showing an array of adaptive chucking modules (ACMs) that are movable with respect to one another using a variable pitch mechanism (VPM) in accordance with an embodiment of the present invention;

FIGS. 40A-40B illustrate an alternative exemplary transfer chuck showing an array of elongated adaptive chucking modules (ACMs) that are movable with respect to one another using a variable pitch mechanism (VPM) in accordance with an embodiment of the present invention;

FIG. 41 illustrates a further alternative exemplary transfer chuck showing an array of elongated adaptive chucking modules (ACMs) that are movable with respect to one another using a variable pitch mechanism (VPM) in accordance with an embodiment of the present invention;

FIGS. 42A-42B illustrate an exemplary adaptive chucking module (ACM) in accordance with an embedment of the present invention;

FIGS. 43A-43C illustrate an additional exemplary transfer chuck showing an array of adaptive chucking modules (ACMs) that are movable with respect to one another using a variable pitch mechanism (VPM) in accordance with an embodiment of the present invention;

FIGS. 44A-44F illustrate an exemplary transfer substrate in accordance with an embodiment of the present invention;

FIG. 45 illustrates an alternative exemplary transfer substrate in accordance with an embodiment of the present invention;

FIGS. 46A-46B illustrate an exemplary interference prevention method (during field assembly onto the transfer substrate) in accordance with an embodiment of the present invention;

FIGS. 47A-47E illustrate an exemplary source substrate in accordance with an embodiment of the present invention;

FIG. 48 is a flowchart of a method for creating source substrates for assembly from substrates with sacrificial layers in accordance with an embodiment of the present invention;

FIGS. 49A-49F depict the cross-sectional views for creating source substrates for assembly from substrates with sacrificial layers using the steps described in FIG. 48 in accordance with an embodiment of the present invention;

FIGS. 50A-50C illustrates an exemplary yield management flow in accordance with an embodiment of the present invention;

FIGS. 51A-51D illustrates an exemplary method for dicing and alignment mark creation in accordance with an embodiment of the present invention;

FIG. 52A illustrates registering picked fields on the transfer chuck to a stable reference grid in accordance with an embodiment of the present invention;

FIG. 52B illustrates registering the position of ACMs with respect to a stable reference grid in accordance with an embodiment of the present invention;

FIGS. 53A-53B illustrate an exemplary approach for Metal-Assisted Catalytic Etching (MACE)-based dicing using an inkjetted catalyst in accordance with an embodiment of the present invention;

FIGS. 54A-54B illustrate an alternative exemplary approach for MACE-based dicing using an inkjetted catalyst in accordance with an embodiment of the present invention;

FIGS. 55A-55B illustrate an exemplary method for substrate dicing post back-grinding in accordance with an embodiment of the present invention;

FIG. 56 illustrates an exemplary method for creating dice cuts in the source substrate prior to back-grinding in accordance with an embodiment of the present invention;

FIG. 57 is a flowchart of a method for creating a metal break for substrate dicing using metal assisted chemical etching in accordance with an embodiment of the present invention;

FIGS. 58A-58C depict the cross-section views for creating a metal break for substrate dicing using metal assisted chemical etching using the steps described in FIG. 57 in accordance with an embodiment of the present invention;

FIG. 59 is a flowchart of a method for patterning a catalyst using selective atomic layer deposition (ALD), such that the catalyst is part of “collapse-avoiding caps,” in accordance with an embodiment of the present invention;

FIGS. 60A-60E depict the cross-section views for patterning a catalyst using selective atomic layer deposition (ALD), such that the catalyst is part of “collapse-avoiding caps,” using the steps described in FIG. 59 in accordance with an embodiment of the present invention;

FIG. 61 is a flowchart of a method for creating collapse-avoiding caps as well as catalyst patterning by directional deposition and atomic layer etching of the catalyst in accordance with an embodiment of the present invention;

FIGS. 62A-62D depict the cross-section views for creating collapse-avoiding caps as well as catalyst patterning by directional deposition and atomic layer etching of the catalyst using the steps described in FIG. 61 in accordance with an embodiment of the present invention;

FIGS. 63A-63D illustrate wandering of isolated catalysts during CICE in accordance with an embodiment of the present invention;

FIGS. 64A-64D show exemplary geometries for the stabilizing patterns or supporting structures in accordance with an embodiment of the present invention;

FIG. 65 is a flowchart of a method for making isolated catalyst dots with circular catalyst buttresses with Ru as the catalyst in accordance with an embodiment of the present invention;

FIGS. 66A-66E depict the cross-section views for making isolated catalyst dots with circular catalyst buttresses with Ru as the catalyst using the steps described in FIG. 65 in accordance with an embodiment of the present invention;

FIGS. 67A-67E depict the top views for making isolated catalyst dots with circular catalyst buttresses with Ru as the catalyst using the steps described in FIG. 65 in accordance with an embodiment of the present invention;

FIG. 68A illustrates a catalyst along with nanostructures composed of porous silicon in accordance with an embodiment of the present invention;

FIG. 68B illustrates a catalyst along with nanostructures composed of alternating layers of porous silicon and non-porous silicon in accordance with an embodiment of the present invention;

FIGS. 69A-69D illustrate removing silicon buttresses (“stabilizing patterns”) (“catalyst buttresses”) after CICE with isolated catalysts having buttresses to prevent wandering in accordance with an embodiment of the present invention;

FIGS. 70A-70C illustrate designing the collapsed pillars to deterministically collapse in a certain direction, such as by placement of the buttress pattern towards one side of the etch, in accordance with an embodiment of the present invention;

FIG. 71 is a flowchart of a method for fabricating line/space patterns with lithographic links using CICE in accordance with an embodiment of the present invention;

FIG. 72 illustrates a top view of the desired line/space pattern using the steps described in FIG. 71 in accordance with an embodiment of the present invention;

FIGS. 73A-73C depict cross-section views for fabricating line/space patterns with lithographic links using CICE using the steps described in FIG. 71 in accordance with an embodiment of the present invention;

FIGS. 74A-74B show an exemplary polysilicon nanowire array fabricated using CICE with gold as a catalyst in accordance with an embodiment of the present invention;

FIG. 75 shows an exemplary geometry that converts silicon fins to holes using atomic layer deposition (ALD) of silicon oxide in accordance with an embodiment of the present invention;

FIG. 76 is a flowchart of a method for the tone-reversal process with CICE in accordance with an embodiment of the present invention;

FIGS. 77A-77D depict the top views for the tone-reversal process with CICE using the steps described in FIG. 76 in accordance with an embodiment of the present invention;

FIGS. 78A-78D depict the cross-section views for the tone-reversal process with CICE using the steps described in FIG. 76 in accordance with an embodiment of the present invention;

FIG. 79 is a flowchart of a method for performing the tone-reversal process with CICE of polysilicon which includes the catalyst removal using a selective chemical etch in accordance with an embodiment of the present invention;

FIGS. 80A-80D depict the top views for performing the tone-reversal process with CICE of polysilicon which includes the catalyst removal using a selective chemical etch using the steps described in FIG. 79 in accordance with an embodiment of the present invention;

FIGS. 81A-81F depict the cross-section views for performing the tone-reversal process with CICE of polysilicon which includes the catalyst removal using a selective chemical etch using the steps described in FIG. 79 in accordance with an embodiment of the present invention;

FIG. 82 is a flowchart of a method for performing the tone-reversal process with CICE of polysilicon which includes the catalyst removal using a selective chemical etch and where the etch stop layer is removed in the final device in accordance with an embodiment of the present invention;

FIGS. 83A-83D depict the top views for performing the tone-reversal process with CICE of polysilicon which includes the catalyst removal using a selective chemical etch and where the etch stop layer is removed in the final device using the steps described in FIG. 82 in accordance with an embodiment of the present invention;

FIGS. 84A-84G depict the cross-section views for performing the tone-reversal process with CICE of polysilicon which includes the catalyst removal using a selective chemical etch and where the etch stop layer is removed in the final device using the steps described in FIG. 82 in accordance with an embodiment of the present invention;

FIG. 85 is a flowchart of a method for fabricating metal interconnects and vias using a tone-reversal process with CICE of polysilicon in accordance with an embodiment of the present invention;

FIGS. 86A-86F depict the top views for fabricating metal interconnects and vias using a tone-reversal process with CICE of polysilicon using the steps described in FIG. 85 in accordance with an embodiment of the present invention;

FIGS. 87A-87L depict the cross-section views for fabricating metal interconnects and vias using a tone-reversal process with CICE of polysilicon using the steps described in FIG. 85 in accordance with an embodiment of the present invention;

FIG. 88 is a flowchart of a method for forming superlattices with tone-reversal CICE and selective growth in accordance with an embodiment of the present invention;

FIGS. 89A-89D depict the top views for forming superlattices with tone-reversal CICE and selective growth using the steps described in FIG. 88 in accordance with an embodiment of the present invention;

FIGS. 90A-90D depict the cross-section views for forming superlattices with tone-reversal CICE and selective growth using the steps described in FIG. 88 in accordance with an embodiment of the present invention;

FIG. 91 is a flowchart of a method for deterministic lateral displacement (DLD) device fabrication using CICE and silicon wafer exfoliation in accordance with an embodiment of the present invention;

FIGS. 92A-92G depict the cross-section views for DLD device fabrication using CICE and silicon wafer exfoliation using the steps of FIG. 91 in accordance with an embodiment of the present invention;

FIG. 93 is a flowchart of a method for bonding cover plates to the DLD pillars to create a DLD device after CICE without causing pillar collapse in accordance with an embodiment of the present invention;

FIGS. 94A-94E depict the cross-section views for bonding cover plates to the DLD pillars to create a DLD device after CICE without causing pillar collapse using the steps of FIG. 93 in accordance with an embodiment of the present invention;

FIG. 95 is a flowchart of a method for improving pillar height using porous stabilizing material in accordance with an embodiment of the present invention;

FIGS. 96A-96C depict the cross-section views for improving pillar height using porous stabilizing material using the steps of FIG. 95 in accordance with an embodiment of the present invention;

FIG. 97 is a flowchart of a method for bonding the cover plate for the DLD device after CICE without causing pillar collapse in accordance with an embodiment of the present invention;

FIGS. 98A-98D depict the cross-section views for bonding the cover plate for the DLD device after CICE without causing pillar collapse using the steps of FIG. 97 in accordance with an embodiment of the present invention;

FIG. 99 is a flowchart of a method for improving collapse of thin pillars by starting with thick pillars and reducing pillar size after cover plate bonding in accordance with an embodiment of the present invention;

FIGS. 100A-100D depict the cross-section views for improving collapse of thin pillars by starting with thick pillars and reducing pillar size after cover plate bonding using the steps of FIG. 99 in accordance with an embodiment of the present invention;

FIG. 101 is a flowchart of a method for multi-stack DLD device fabrication using CICE of polysilicon in accordance with an embodiment of the present invention;

FIGS. 102A-102F depict the cross-section views for multi-stack DLD device fabrication using CICE of polysilicon using the steps of FIG. 101 in accordance with an embodiment of the present invention;

FIG. 103 illustrates the cross-section of multi-stack DLD devices in nanoscale areas to improve the overall throughput in accordance with an embodiment of the present invention;

FIG. 104 illustrates a metasurface that includes four arrays of pillars for focusing of various wavelengths of light using silicon nanopillars and oxidized porous silicon nanopillars made by CICE in accordance with an embodiment of the present invention;

FIG. 105 illustrates an exemplary 3D stacked image sensor in accordance with an embodiment of the present invention; and

FIG. 106 illustrates an exemplary petal-ed imager die in accordance with an embodiment of the present invention.

### DETAILED DESCRIPTION

As stated in the Background section, in semiconductor device fabrication, etching refers to any technology that will selectively remove material from a thin film on a substrate (with or without prior structures on its surface) and by this removal create a pattern of that material on the substrate. The pattern may be defined by a mask that is resistant to the etching process. Once the mask is in place, etching of the material that is not protected by the mask can occur, by either wet chemical or by “dry” physical methods.

One type of etching is Catalyst Influenced Chemical Etching (CICE), which is a catalyst-based etching method that can be used to fabricate features in semiconductors, such as silicon, germanium, etc., where such features have high aspect ratios, low sidewall taper, low sidewall roughness, and/or controllable porosity. This method is used to create higher density and higher performance Static Random-Access Memory (SRAM) as well as low-loss waveguides.

Unfortunately, there are currently limitations in fabricating features in semiconductors using CICE.

The principles of the present invention provide a means for utilizing the CICE process to effectively fabricate features in semiconductors using the equipment and process technologies for catalyst influenced chemical etching of the present invention.

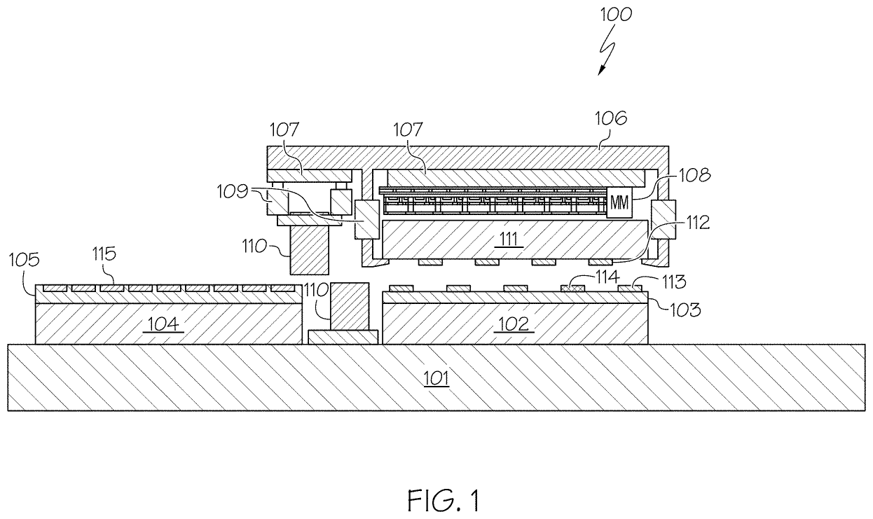

Referring now to the Figures in detail, FIG. 1 illustrates an exemplary tool 100 for pick-and-place assembly in accordance with an embodiment of the present invention.

As shown in FIG. 1, tool 100 includes a nano procession xy stage 101 to support a source substrate chuck 102 (used to hold a source substrate 103) and a product substrate chuck 104 (used to hold a product substrate 105).

Tool 100 further includes a precision pick-and-place module frame 106 supporting short-stroke xy stages 107. Furthermore, as shown in FIG. 1, tool 100 includes an optional metrology module 108 on a short-stroke xy stage 107. Additionally, tool 100 includes voice coils 109 and plasma units 110 along with a transfer chuck (TC) 111 in which a subset of the fields 112 have been picked up by transfer chuck 111 from source substrate 103 as shown in FIG. 1.

Furthermore, as shown in FIG. 1, there remains singulated fields 113 on source substrate 103, in which field 114 contains a known bad die.

Additionally, as shown in FIG. 1, layer 1 (element 115) with field 1 of product substrate 105 is already assembled.

Furthermore, FIG. 1 shows in particular an exemplary tool 100 for pick-and-place assembly of fields from one or more source substrates 103 to product substrate 105. A “field,” as used herein, refers to the largest contiguous portion of a substrate that is created after substrate singulation. A field could contain one or more dies, chiplets or devices. In one embodiment, source substrates 103 each contain a single type of field. In another embodiment, source substrate 103 contains multiple types of fields. In one embodiment, the fields in source substrates 103 can range in size from 0.5 mm on a side to up to 200 mm on a side.

In one embodiment, tool 100 for pick-and-place assembly incorporates one or more of the following components: a source substrate chuck 102, a product substrate chuck 104, an intermediate substrate chuck (holds an intermediate substrate) (not shown in FIG. 1), a transfer chuck (TC) 111, plasma units 110 for pre-bonding surface activation and a metrology module (MM) 108.

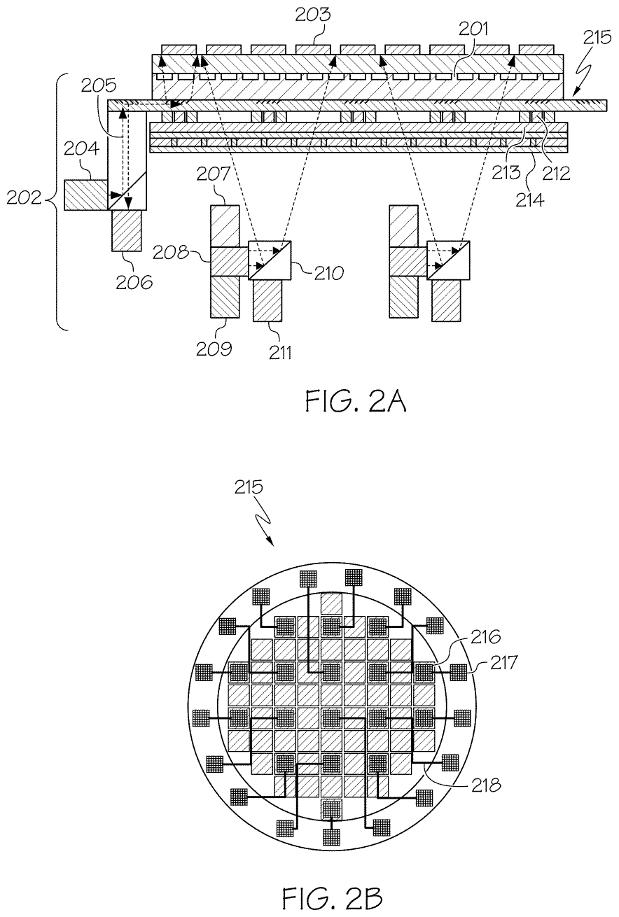

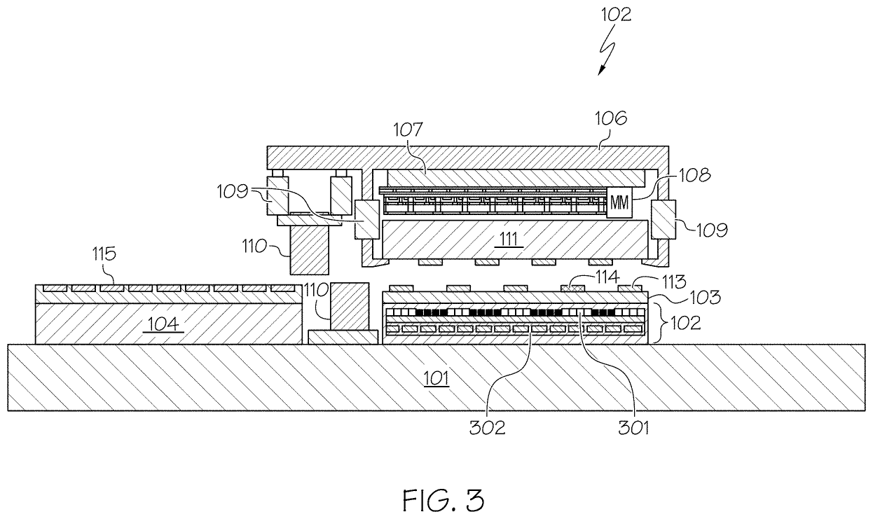

Referring now to FIGS. 2A-2B and 3, in conjunction with FIG. 1, FIGS. 2A-2B illustrate an exemplary design for the source chuck/product chuck/intermediate chuck in accordance with an embodiment of the present invention. FIG. 3 illustrates an exemplary design for the source substrate chuck, such as source substrate chuck 102, with an ultraviolet (UV) light emitting diode (LED) array for field release in accordance with an embodiment of the present invention.

As shown in FIG. 2A, transparent source/product/intermediate substrate 201 touches a portion of chuck 202 (representing source substrate chuck 102 or product substrate chuck 104 or an intermediate substrate chuck). In one embodiment, such a substrate 201 includes chiplets 203.

In one embodiment, source/product/intermediate substrate chuck 202 includes an optional light source 204 for field release (e.g., fiber-based) via a light path 205. Furthermore, in one embodiment, source/product/intermediate substrate chuck 202 includes an optional imager 206 for in-situ metrology. Additionally, in one embodiment, source/product/intermediate substrate chuck 202 includes an optional light source 207 for thermal actuation, a DMD assembly 208 and another optional light source 209 for field release (e.g., fiber-based).

Furthermore, in one embodiment, source/product/intermediate substrate chuck 202 includes an optional projector 210 to project optical signals as well as another optional imager 211 for in-situ metrology.

Additionally, in one embodiment, source/product/intermediate substrate chuck 202 includes an optional group of thermoelectric coolers 212, an optional transparent, thermally conductive printed circuit board (PCB) 213, and an optional cooling assembly 214 with a transparent covering.

As shown in FIG. 2B, FIG. 2B illustrates a top view of the exemplary optional photonic waveguide substrate 215. Such a substrate 215 includes an out-coupling grating 216 and an in-coupling grating 217. Additionally, FIG. 2B illustrates that photonic waveguide substrate 215 includes a two-dimensional photonic crystal pathway 218 for in-plane light transmission.

Furthermore, as shown in FIG. 3, source substrate chuck 102 includes an optional addressable ultraviolet (UV) light emitting diode (LED) array 301 along with an optional cooling system assembly 302.

A further discussion of FIGS. 2A-2B and 3, in conjunction with FIG. 1, is provided below.

In one embodiment, the primary function of the substrate chucks 202 is to hold the source/product/intermediate substrates, respectively, in a thermo-mechanically stable state during field assembly as well as to change the thermo-mechanical state of the substrates in a controlled manner (if needed).

In one embodiment, substrate chucks 202 are constructed using one or more of the following: silicon carbide (SiC), sapphire, fused silica, glass, silicon, flexible substrates (such as polycarbonate, etc.). In one embodiment, the substrate-touching-surfaces of the chuck are coated with a hard material, such as, for instance, one or more of the following: silicon nitride (SiN), silicon carbide (SiC), etc.

In one embodiment, one or more of substrate chucks 202 have transparent portions. The transparent portions (in the relevant spectrum) could allow through-chuck light transmission to facilitate field-release/temporary-bonding from/to the substrates and/or through-chuck metrology. Light-based field-release solutions are commercially available. Light is incident from the underside of substrate chuck 202, or alternatively from the sides, or a combination of the two. In one embodiment, waveguide-based solutions are used to direct light from the side of substrate chuck 202, where the light is incident, to the substrate underside. If the minimum feature size needed in the waveguide substrate is larger than 100 nm, direct write methods could be used for patterning of the substrate (for instance, laser direct writing). If the minimum feature size is smaller than 100 nm, nanoimprint lithography (NIL), along with a limited number of standardized NIL templates, could be used for the patterning. The standard templates could consist of quantized pattern pieces, such as a 1 mm vertical waveguide channel, a 1 mm horizontal waveguide channel, a +90° waveguide channel, a −90° waveguide channel, etc. These could be used to pattern custom waveguide paths from any out-coupling grating 216 to an in-coupling grating 217. In one embodiment, in-coupling gratings 217 are placed at a location on the periphery that satisfies the quantized X and Y separation constraints imposed by the quantized waveguide pieces. In another embodiment, an addressable UV LED array is used for field release from source substrate 103.

In one embodiment, one or more of the substrate chucks 202 incorporate metrology modules (e.g., metrology module 108) to allow in-situ metrology.

In one embodiment, one or more of the substrate chucks 202 have thermal actuators, embedded or otherwise. Thermal actuators could be used to control one or more of the following: temperature on the source/product/intermediate substrates, field distortion, and field topography. In one embodiment, thermal actuation could be performed using an array of thermoelectric coolers (TEC). A heat exchanger could be utilized to exchange heat with the thermal actuators. In one embodiment, the heat exchanger uses a liquid, such as water, as the working fluid. In one embodiment, the thermal actuators are mounted on a thermally conductive printed circuit board 213. In one embodiment, printed circuit board 213 is transparent.

In another embodiment, thermal actuation is performed using incident spatially modulated radiation that is absorbed by the source/product/intermediate substrates, for instance, using one or more digital micromirror devices (DMDs). The radiation could incorporate one or more of the following: Short Wavelength Infrared Radiation (SWIR), Middle Wavelength Infrared Radiation (MWIR), and Long Wavelength Infrared Radiation (LWIR).

In one embodiment, one or more of the substrate chucks 202 are inert to source substrate sacrificial layer etchants. In another embodiment, one or more of the chucks 202 could be coated with a material that is inert to sacrificial layer etchants, for instance, PTFE, high-density polyethylene (HDPE), etc.

In one embodiment, one or more of the source substrate chucks 102 are mounted on a motion stage. In one embodiment, one or more of the source substrate chucks 102 are mounted on a motion stage that moves independently of other stages in an n-MASC tool (tool for nanometer-scale modular assembly of semiconductor chiplets).

In one embodiment, the n-MASC tool incorporates multiple substrate chucks 202 for simultaneous handling and/or processing of multiple source/product/intermediate substrates, each of which might be independently movable.

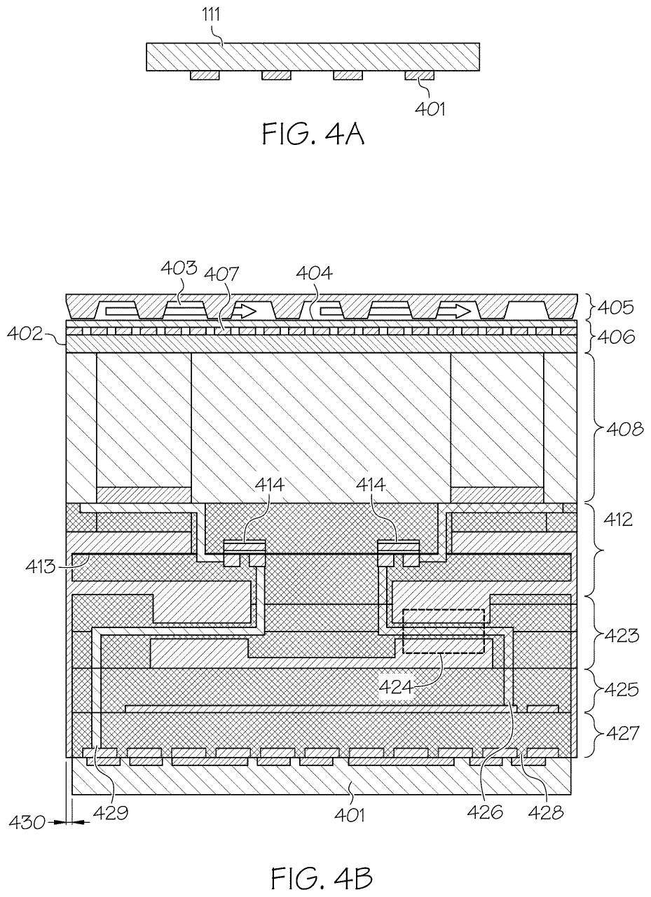

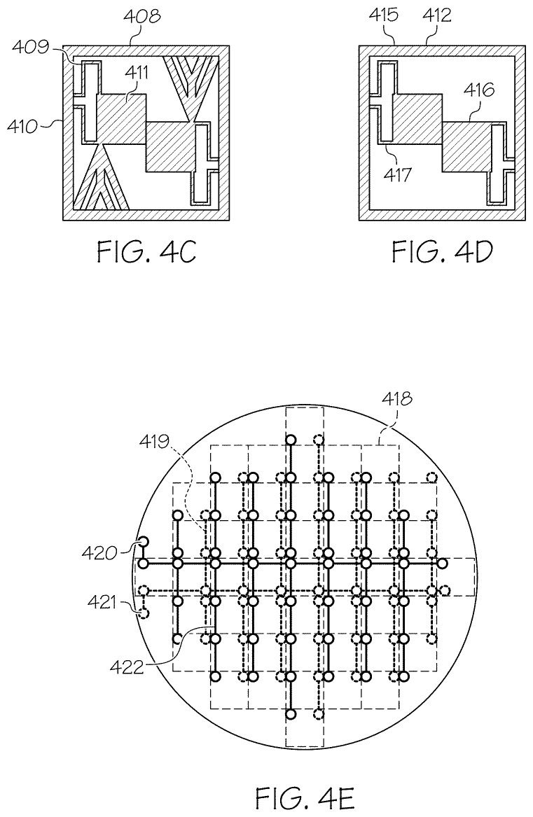

Referring now to FIGS. 4A-4E, FIGS. 4A-4E illustrate the details regarding an exemplary transfer chuck (TC) 111.

As shown in FIG. 4A, FIG. 4A illustrates a transfer chuck (TC) 111 with attached fields 401 in accordance with an embodiment of the present invention.

A cross-section view of transfer chuck (TC) 111 is shown in FIG. 4B in accordance with an embodiment of the present invention

Referring to FIG. 4B, TC 111 includes optional microfabricated pins 402 in silicon, for instance, to connect the stationary thermal actuator layer to the moving thermal actuator arms. In one embodiment, the diameter of such microfabricated pins 402 is 2 μm with a height of 10 μm.

In one embodiment, TC 111 includes heat exchanger fluid 403 and a thermally conductive printed circuit board 404. Furthermore, in one embodiment, TC 111 includes a heat exchanger layer 405 and a thermal actuator layer 406 which may contain thermoelectric coolers 407. Additionally, in one embodiment, TC 111 includes an xy actuator layer 408. In one embodiment, xy actuator layer 408 is comprised of stainless steel. In one embodiment, xy actuator layer 408 has a thickness of 5 mm. A top view of such an xy actuator layer 408 is shown in FIG. 4C in accordance with an embodiment of the present invention.

Referring to FIG. 4C, xy actuator layer 408 includes xy flexures 409, a stationary portion 410 and a moving portion 411.

Returning to FIG. 4B, TC 111 further includes a pneumatic valve and xy flexure layers 412. Such layers 412 include an optional flexible layer 413 (e.g., a polymer) that creates valve seals in the pneumatic valve layer 412. Additionally, such layers 412 include flow valves 414 that, for example, may be actuated electrostatically.

An illustration of the top view of the pneumatic valve layer 412 is shown in FIG. 4D in accordance with an embodiment of the present invention. As shown in FIG. 4D, pneumatic valve layer 412 includes stationary portion 415 and a moving portion 416. Furthermore, as shown in FIG. 4D, pneumatic valve layer 412 includes xy flexures 417. In one embodiment, such xy flexures 417 can be used to route vacuum and pressure from stationary portion 415 to moving portion 416.

A further illustration of an alternative top view of the pneumatic value layer 412 is shown in FIG. 4E in accordance with an embodiment of the present invention. As shown in FIG. 4E, pneumatic valve layer 412 includes an exemplar actuation grid 418, an optional pressure line 419, an optional vacuum source 420 at the layer edge, an optional pressure source 421 and an optional vacuum line 422. As illustrated in FIG. 4E, pneumatic valve layer 412 may include vacuum and pressure distribution lines from the edge of the layer to each actuation unit. In one embodiment, the pressure and vacuum are sourced through channels etched into the layer substrate(s). In one embodiment, the pressure and vacuum distribution lines are on different sides of the same substrate.

Returning to FIG. 4B, in one embodiment, TC 111 includes a z-flexure layer 423 (two bonded layers to create an internal fluid channel). In one embodiment, each layer of the internal fluid channel has a thickness of 0.25 mm. In one embodiment, z-flexure layer 423 includes a z-flexure 424.

Additionally, in one embodiment, TC 111 includes a pressure manifold layer 425 for field bowing. In one embodiment, layer 425 has a thickness of 0.3 mm. In one embodiment, pressure manifold layer 425 includes an optional pressure line 426.

Furthermore, in one embodiment, TC 111 includes a vacuum suction layer 427. In one embodiment, vacuum suction layer 427 has a thickness of 0.3 mm.

Additionally, FIG. 4B illustrates field contacting pins 428. In one embodiment, such pins can be optionally coated with a hard material, such as SiN, SiC, etc. Furthermore, FIG. 4B illustrates a field 401 and an optional vacuum line 429. Lastly, FIG. 4B illustrates a gap 430 between the actuation unit boundary and the xy-movable layers.

Furthermore, as shown in FIG. 4B, in one embodiment, the regions that are shaded lighter may be filled with a sacrificial materials, such as SiO₂, during TC fabrication. In one embodiment, these regions could provide structural stability during operations, such as TC pin polishing, but could be etched away, for instance, using vapor HF, once TC 111 has been fabricated.

Additionally, as shown in FIG. 4B, in one embodiment, the regions that are shaded darker may be fabricated with silicon.

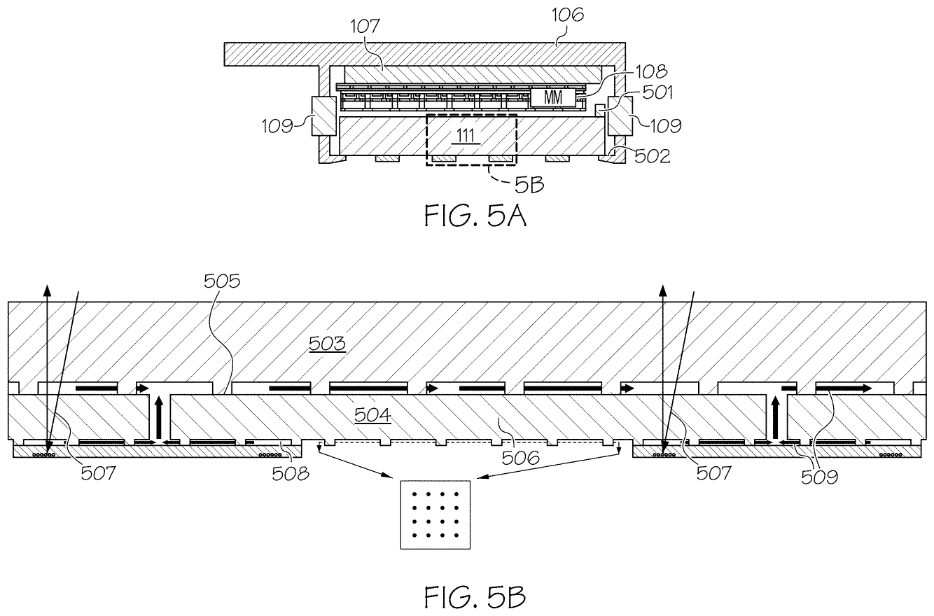

Referring now to FIG. 5A, FIG. 5A illustrates an exemplary illustration of a transfer chuck (TC) 111 that contains custom-fabricated layers for each new field type in accordance with an embodiment of the present invention.

As shown in FIG. 5A, TC 111 can optionally include a vacuum supply 501 to the TC vacuum manifold. Furthermore, as shown in FIG. 5A, TC 111 is optionally secured to frame 106 using an annular contact 502 on the periphery.

FIG. 5B illustrates an expanded view of transfer chuck 111 that contains custom-fabricated layers for each new field type in accordance with an embodiment of the present invention.

As shown in FIG. 5B, transfer chuck 111 contains a primary vacuum manifold 503 and a secondary vacuum manifold 504. In one embodiment, primary and secondary vacuum manifolds 503, 504 are optionally bonded together, such as shown at element 505.

In one embodiment, TC 111 has no vacuum supply in regions where fields will not be assembled, such as shown at element 506.

In one embodiment, primary and secondary vacuum manifolds 503, 504 are optionally designed in a manner such that the pins do not interfere with the waveguide multilayer memory (WMM) beam paths, such as shown at element 507.

Furthermore, in one embodiment, TC 111 includes a vacuum section 508 in secondary vacuum manifold 504 that holds the fields to the manifold pins.

Additionally, FIG. 5B illustrates the exemplar airflow direction 509.

In one embodiment, secondary vacuum manifold 504 is fabricated from a standard silicon substrate. In one embodiment, primary vacuum manifold 503 is fabricated using thick silicon substrates to provide added structural strength against sagging to gravity.

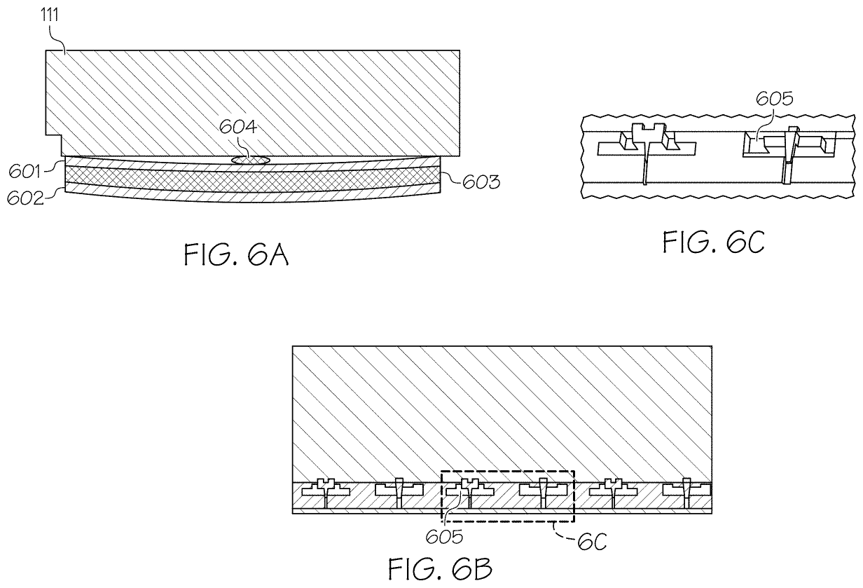

Referring now to FIG. 6A, FIG. 6A illustrates an exemplary transfer chuck (TC) 111 composed of compliant pins in accordance with an embodiment of the present invention.

As shown in FIG. 6A, TC 111 includes a top metal layer 601 and a back transistor layer 602 with an nMASC field 603 (multilayer Al₂O₃—SiO₂ combination) between layers 601, 602. Furthermore, as shown in FIG. 6A, an exemplary particle 604 is located on the surface of top metal layer 601.

An expanded view of a portion of top metal layer 601 is shown in FIG. 6B in accordance with an embodiment of the present invention. FIG. 6C illustrates an expanded view of the thin skins 605 located on the bottom portion of top metal layer 601 as shown in FIG. 6B in accordance with an embodiment of the present invention.

A discussion regarding FIGS. 4A-4E, 5A-5B and FIGS. 6A-6C is provided below.

The primary function of TC 111 is to pick-up/place one or more fields from/onto the source/product/intermediate substrates in a thermo-mechanically stable manner as well as to change the thermo-mechanical state of the fields in a controlled manner (if needed).

In one embodiment, one or more of the TCs 111 are constructed using one or more of the following: silicon carbide (SiC), sapphire, fused silica, glass, silicon, flexible substrates (such as polycarbonate, etc.). In one embodiment, the substrate-touching-surfaces of one or more of the TCs 111 are coated with a hard material (e.g., silicon nitride (SiN), silicon carbide (SiC), etc.).

In one embodiment, one or more of the TCs 111 have transparent portions. The transparent portions (in the relevant spectrum) could allow through-TC light transmission to facilitate field-release/temporary-bonding from/to the substrates and/or through-TC metrology. Light could be incident from the underside of the substrate chuck, or alternatively from the sides, or a combination of the two. In one embodiment, waveguide-based solutions are used to direct light from the side of the substrate chuck, where the light is incident, to the substrate underside.

In one embodiment, the chuck, such as TC 111, incorporates one or more metal layers, such as metal layer 601. The metal layer, such as metal layer 601, could be used to provide structural stability to TC 111. The metal layer, such as metal layer 601, could be machined using macro-machining techniques (e.g., computerized numerical control (CNC) machining). In one embodiment, the metal layer, such as metal layer 601, is made of a high thermal expansion material. In one embodiment, the metal layer, such as metal layer 601, is made of a low thermal conductivity material. In one embodiment, the metal layer, such as metal layer 601, is made using stainless steel.

In one embodiment, TC 111 incorporates a thick substrate (e.g., thick silicon, thick sapphire), of 0.775 mm thickness or more. The thick substrate could be used to provide structural stability to TC 111.

In one embodiment, TC 111 incorporates layers to facilitate bonding of various TC layers (e.g., chrome thin film, polymer films, adhesive polymer films, etc.).

In one embodiment, TC 111 incorporates layers to prevent contamination of n-MASC tool components (including TC sub-components) by the sacrificial layer etchant (e.g., chrome thin film, polymer films, adhesive polymer films, etc.).

In one embodiment, the multiple layers which constitute TC 111 are joined together using one or more of the following: anodic bonding, fusion bonding, hybrid bonding, pneumatic suction, an adhesive, etc.

In one embodiment, TC 111 utilizes vacuum suction to hold fields 401. In one embodiment, TC 111 incorporates integrated valve assemblies to turn on and off the vacuum suction for individual picked fields. TC 111 could also incorporate integrated valve assemblies to turn on and off a pressure source corresponding to individual picked fields. The pressure source could be utilized to create a thin fluidic lubricating layer just prior to field pickup or field bonding. Holes and recesses needed for enabling vacuum and pressure supply to the picked fields could be created using deep etching processes, such as Metal-assisted Chemical Etching (MACE), Deep Reactive Ion Etching (DRIE), etc. Furthermore, TC 111 utilizes flexure mechanisms machined into one or more of the TC layers to source the pressure and vacuum from the movable parts of TC 111 to the fixed parts of TC 111.

In one embodiment, the valve assembly (to turn pressure/vacuum on and off) consists of a hole in TC 111, a flexible membrane (made of a polymer, for instance), a membrane actuation mechanism (for instance, a voice coil along with a magnetically sensitive material deposited or attached to the flexible membrane), a relay (using a transistor, for instance) to turn the actuation mechanism on and off. In one embodiment, the actuation mechanism utilizes thermal expansion.

In one embodiment, TC 111 incorporates porous layers to create vacuum suction on fields 401. In one embodiment, TC 111 incorporates a layer with hybrid porous and non-porous structures to create vacuum suction on fields 401.

In one embodiment, TC 111 uses electrostatic force to hold fields 401. In one embodiment, TC 111 uses Johnsen-Rahbek-type electrostatic chucking to hold fields 401 only where they contact TC 111. In one embodiment, the chucking mechanism incorporates an array of switches to modulate the electrostatic holding force. In one embodiment, the array of switches is addressed using a multiplexer electronic circuit.

In one embodiment, TC 111 utilizes an adhesive to hold fields 401. In one embodiment, TC 111 utilizes UV-release glue to hold fields 401.

In one embodiment, TC 111 contacts fields 401 using an array of pins, such as pins 428. The pin could be in the shape of a truncated frustum. The pins could have one or more holes through which vacuum or pressure is sourced. In another embodiment, TC 111 contacts fields 401 using an array of rings. The ring regions could include one or more holes to source vacuum or pressure.

In one embodiment, the pins, such as pins 428, are compliant in the z-axis.

In one embodiment, the TC contact surfaces are polished post-assembly of TC 111. Any recesses in the TC layers could be filled with fluid-etchable layers, such as silicon oxide (which is etchable using vapor HF). The fluid-etchable layers could be etched away post-polishing.

In one embodiment, TC 111 incorporates integrated mechanical actuators (e.g., one or more piezoelectric actuators, thermal actuators, electrostatic actuators, etc.) to perform actuation in the X, Y, and/or theta axes, for one or more of the picked fields 401. In one embodiment, TC 111 incorporates flexure layers to facilitate in-plane motion of fields 401 as well as specific portions of TC 111. In one embodiment, thermal actuators are used to perform said in-place motion by suitable heating and cooling of the flexure arms. Thermal actuation of the flexure arms may be produced using an array of thermoelectric elements. In one embodiment, the thermoelectric elements are used to transfer heat to the flexures using an array of flexible pillars. Alternatively, thermoelectric elements are used to transfer heat to the flexures using a thin, low coefficient-of-friction material (e.g., a thin film of polytetrafluoroethylene (PTFE), a thin film of a thermally conductive paste, etc.). In another embodiment, thermal actuation of the flexure arms is performed using spatially modulated radiation that is absorbed by the flexure arms, such as by using one or more digital micromirror devices (DMDs). In one embodiment, piezoelectric transducers are placed areally around fields 401 (that are arranged in a checkerboard arrangement) to perform in-plane actuation of fields 401. In one embodiment, thermal actuation is performed in a timed manner, where, at a certain time tₐ after the start of thermal actuation, and for a duration Ata, desired control is maintained.

In one embodiment, the integrated mechanical actuators, described above, are used to correct one or more components of the first-order overlay errors. In one embodiment, the integrated mechanical actuators, described above, are used to correct one or more components of the higher-order overlay errors.

In one embodiment, TC 111 incorporates pressurize-able regions to create a bow in fields 401 just prior to bonding. In one embodiment, TC 111 incorporates pressurize-able regions to actuate fields 401 in the z-axis.

In one embodiment, TC 111 incorporates one or more heat exchanger layers, such as heat exchanger layer 405, to transport excess heat or cold away from TC 111.

In one embodiment, TC 111 incorporates one or more layers which incorporate flexures which are constrained to move in the z-axis. The flexures could have a motion range of 10 μm or more. In one embodiment, the flexures are actuated using thermal actuators, piezoelectric actuators, and/or pneumatic actuators.

In one embodiment, the thickness variation of fields 401 is actively sensed. In one embodiment, the thickness variation of fields 401 is sensed using air gages.

In one embodiment, TC 111 has optically clear pathways to allow in-situ metrology through TC 111. In one embodiment, TC 111 has optically clear pathways for infrared radiation.

In one embodiment, one or more custom TCs 111 are used for every new field design, with the TC actuator grid (defined by the array of repeating actuator groups, where each actuator group is used to actuate a single field of default dimensions) matched to the field dimensions. In one embodiment, custom TCs 111 could be swapped using a robot arm and lift pins.

In one embodiment, TCs 111 with a fixed grid (corresponding to a default field dimension) are adapted to assemble fields of varying dimensions. An algorithm to achieve this is described below—
A bounding region W∈R² is defined, which could be a of circle of diameter d_{substrate}.
The following two tilings are defined:
   T_{actuator} is a set of tiles, each of which is of size (width_{actuator}, height_{actuator}), such that T_{actuator} tessellates W. The tiles in T_{actuator} are translatable as a group in X and Y.
   T_{field} is a set of tiles, each of which is of size (width_{field}, height_{field}), such that T_{field} tessellates W.
For a given set of labels n, all tiles in T_{field} are labelled such that, for the set of tiles that share a label, the center-to-center distance between each field and its nearest tile in T_{actuator} is minimized, and is strictly lower than (width_{actuator}−width_{field})/2 along the X axis, and strictly lower than (height_{actuator}−height_{field})/2 along the Y axis. Such a labeling is found by first producing m₀ random assignments of the n labels for the tiles in T_{field}, and checking, for each random assignment, the maximum center-to-center distance for all fields belonging to a label, across all labels, by sliding the actuator tiles in X and Y axes by small, fixed amounts until an area of (width_{actuator}, height_{actuator}) is covered. Better label assignments are then be produced using a heuristic optimizer, for instance, a genetic-algorithm-type minimizer, where the label assignments are crossed-over, mutated and selected for the minimum of the maximum center-to-center distance.
An overarching heuristic optimizer is run, that minimizes the set of labels n.

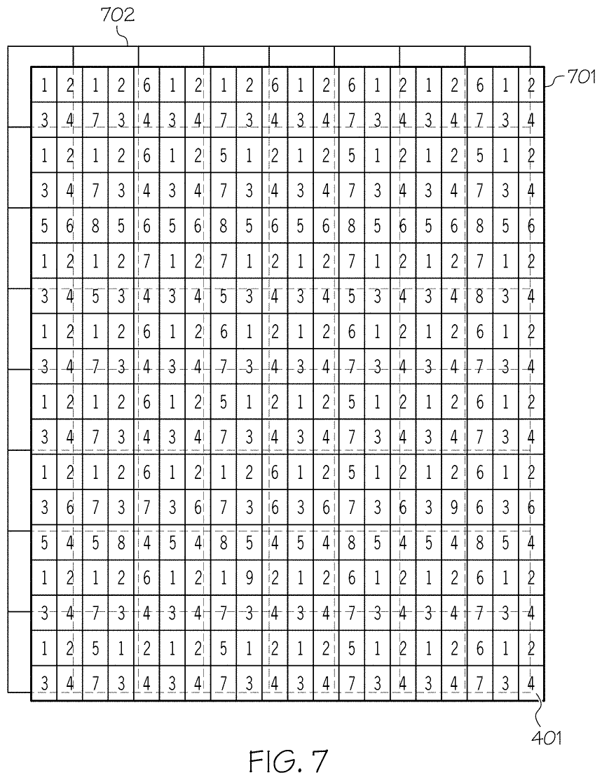

One such labelling is shown in FIG. 7, which is discussed below.

FIG. 7 illustrates the exemplary labelling of fields 401 in a rectangular bounding region 701 that is assemble-able using an actuator grid 702 using 9 labels (9 assembly steps) in accordance with an embodiment of the present invention.

In one embodiment, TC 111 is held using a structural member in the form of a thin ring that contacts TC 111 in an annular region that is etched into the sides of TC 111.

In one embodiment, sacrificial layer etchants are sourced through TC 111 through holes in the etchant-inert part of TC 111. In one embodiment, sacrificial layer etchants are sourced through the parts of TC 111 that are made from silicon.

The following discussion is based on FIG. 8. FIG. 8 illustrates an exemplary process showing intermediate substrates used for assembly in accordance with an embodiment of the present invention. In one embodiment, a cascade of TCs 111 is used to transfer fields 401 from one source/intermediate/product substrate 103/801/105 to a different source/intermediate product substrate 103/801/105.

In one embodiment, a cascade of TCs 111 is used to transfer fields from source substrate 103 to product substrate 105. One or more TCs 111 pick up a subset of fields 401 from source substrate 103 and transfer them (in a field-by-field manner, for instance) to an intermediate substrate 801, while ensuring that the pitch of the fields along the X axis, as well as the pitch of the fields along the Y axis, matches the corresponding X and Y pitch of fields 401 in product substrate 105. In one embodiment, one or more TCs 111 are used to flip the orientation of a subset of fields 401 from source substrate 103 or one of the intermediate substrates 801 such that the correct side required for bonding faces product substrate 105. In one embodiment, one or more TCs 111 perform overlay control and hybrid bonding for the subset of fields 401 being assembled onto product substrate 105.

In another embodiment, a cascade of TCs 111 is used to transfer fields 401 from source substrate 103 to product substrate 105. One or more TCs 111 pick up a subset of fields 401 from source substrate 103 and transfer them in a column-by-column manner to an intermediate substrate 801 while ensuring that the pitch of the fields along the X axis matches the pitch of fields 401 in product substrate 105. In one embodiment, one or more TCs 111 that pick up a subset of fields 401 from intermediate substrate 801 and transfer them in a row-by-row manner to a different intermediate substrate 801 while ensuring that the pitch of the fields along the Y axis matches the pitch of fields 401 on product substrate 105. In one embodiment, one or more TCs 111 are used to flip the orientation of a subset of fields 401 from source substrate 103 or one of the intermediate substrates 801 such that the correct side required for bonding faces product substrate 105. In one embodiment, one or more TCs 111 perform overlay control and hybrid bonding for the subset of fields 401 being assembled onto product substrate 105.

In one embodiment, intermediate substrates 801 are made from silicon, silicon oxide, glass, polymers (such as polycarbonate), and/or sapphire. In one embodiment, intermediate substrates 801 have metrology marks embedded inside. In one embodiment, the metrology marks in intermediate substrates 801 are utilized to align fields to a known precise grid.

In one embodiment, source substrate 103 consists of singulated fields on a dicing tape frame. In one embodiment, intermediate substrate 801 consists of a glass substrate with embedded alignment marks. In one embodiment, temporary bonding onto intermediate substrate 801 is performed using inkjetted UV-curable adhesive. Furthermore, in one embodiment, final bonding is between fields 401 attached to intermediate substrate 801 and product substrate 105.

In one embodiment, TC 111 is geometrically bounded by a cylinder with a diameter of 300 mm. In another embodiment, TC 111 is geometrically bounded by a cuboid. In one embodiment, TC 111 is bounded by a cuboid two sides of which are larger than 300 mm.

Furthermore, as shown in FIG. 8, source substrate 103 (identified as “source substrate 2”) includes fields 401 that are facing down. Such fields 401 are transferred by TCs 111 to intermediate substrate 801. In one embodiment, there is an embedded alignment grid 802 to assist with ensuring that the pitch of the fields along the X axis, as well as the pitch of the fields along the Y axis, matches the corresponding X and Y pitch of fields 401 in product substrate 105. In one embodiment, there is an optional varying density glue 803 that is dispensed to compensate for filed thickness variation.

Additionally, FIG. 8 illustrates exemplary fields 401 from a source substrate 103 (identified as “source substrate 1”) that is already assembled onto product substrate 105 as shown via element 804. Furthermore, FIG. 8 illustrates that product substrate 105 being optionally plasma treated, such as immediately prior to assembly.

Furthermore, FIG. 8 illustrates exemplary fields 401 from source substrate 103 (identified as “source substrate 2”) on product substrate 105 that is optionally plasma treated as shown via element 805. It is noted that fields 401 are facing up on product substrate 105.

Such fields 401 of product substrates 105 are bonded forming the assembled product substrate 105 as shown via element 806.

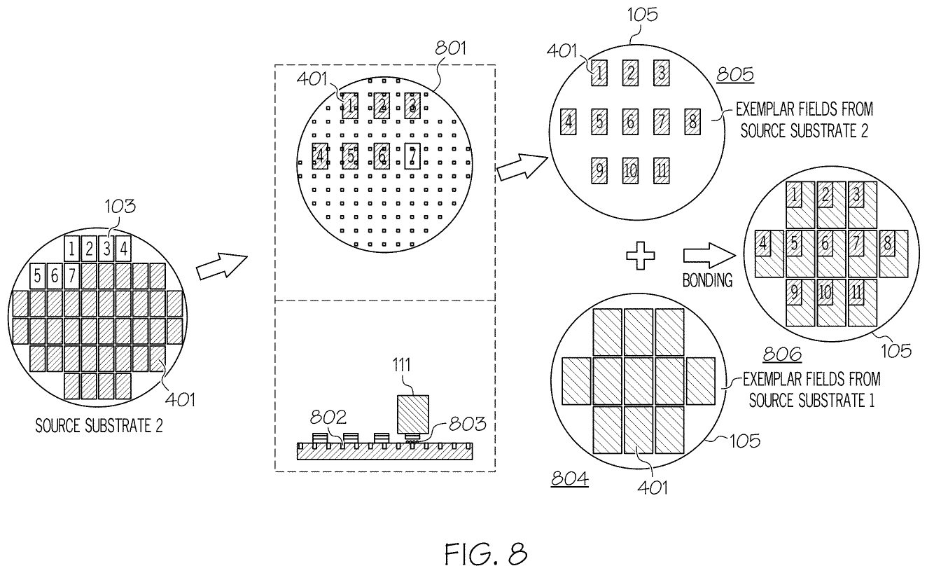

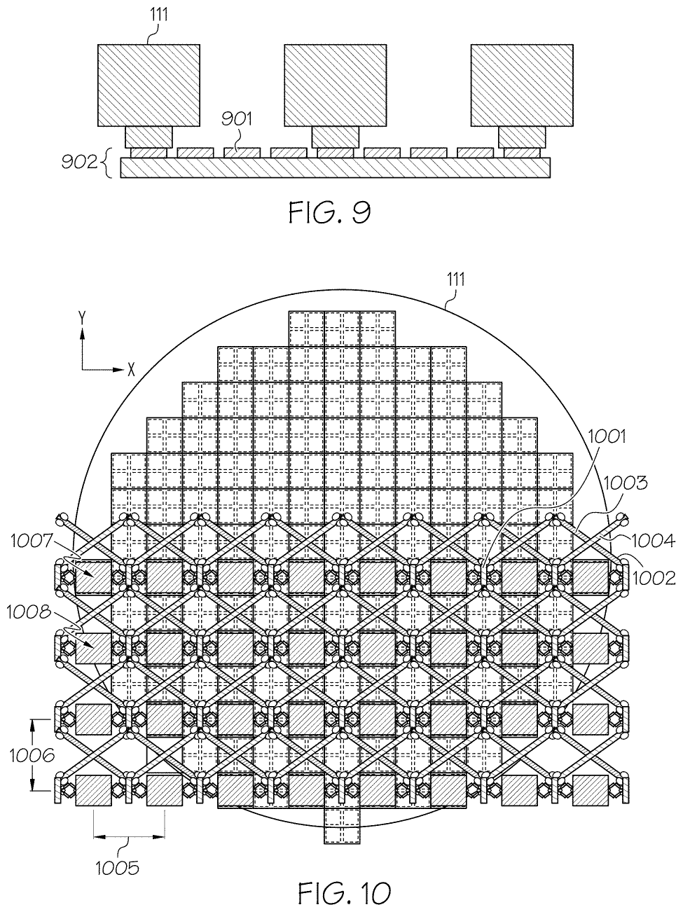

Referring now to FIG. 9, FIG. 9 illustrates an exemplary illustration of multiple TCs 111 being used during assembly in accordance with an embodiment of the present invention.

As shown in FIG. 9, multiple TCs 111 are used in parallel to assemble fields represented as dies 901 on a source wafer 902. In one embodiment, each TC 111 is configured to pick up and assemble a single die 901. It is noted that each TC 111 could be actuatable in the X, Y and/or Z axes and have independently controllable pressure and vacuum supplies.

In one embodiment, multiple TCs 111 are used in parallel to assemble fields 401 (e.g., dies 901), where each TC 111 can pick-up, overlay and bond one or more fields 401. In one embodiment, multiple TCs 111 are used in parallel to assemble fields 401, where each TC 111 can pick-up, overlay and bond one field.

Referring now to FIG. 10, FIG. 10 illustrates an exemplary reconfigurable-grid TC 111 (e.g., 300 mm×300 mm) in accordance with an embodiment of the present invention.

As shown in FIG. 10, there is a pair of overload “base plates” 1001. These base plates 1001 are optionally unconnected, which facilitates independent X and Y expansion. Furthermore, as shown in FIG. 10, there is optionally a monolithically fabricated Y reconfiguring array 1002. Links 1003 (darker shaded) lie in a different plane compared to the lighter shaded links 1004. The X reconfiguring array (now shown in FIG. 10) could be fabricated separately and optionally overlaid on top of Y reconfiguring array 1002.

Furthermore, FIG. 10 illustrates the locations 1005 for an exemplar force application to reconfigure the TC X grid. Additionally, FIG. 10 illustrates the locations 1006 for an exemplar force application to reconfigure the TC Y grid.

Additionally, FIG. 10 illustrates the single actuation units 1007 as well as illustrates that faulty actuation units 1008 can be individually replaced.

In one embodiment, a TC 111 with a reconfiguring actuation grid is used. In one embodiment, the reconfiguring mechanism is fabricated monolithically. In one embodiment, the reconfiguring arrangement is constructed by stacking one or more layers, each of which is monolithically fabricated. In one embodiment, the reconfiguring mechanism is made using bulk metal, bulk polymer, thin coatings, etc. or any combination thereof. In one embodiment, the reconfiguring mechanism is made using steel, stainless steel, chrome, etc. or any combination thereof. In one embodiment, the reconfiguring mechanism consists of flexure elements. In one embodiment, the flexure elements are arranged so as to form scissor mechanisms between each pair of actuation units 1007. In one embodiment, separate reconfiguring mechanisms are utilized for expansion along the X and Y directions. These mechanisms could be stacked on top of each other. Each mechanism could be actuatable in one direction while being free to move in the orthogonal direction. In one embodiment, the actuation of the reconfiguring mechanism is produced using actuators (e.g., voice coil motors, piezoelectric actuators, thermal actuators, etc.) placed at one or more locations on or within the periphery of the reconfiguring mechanism. In one embodiment, the actuators are placed on the axes of symmetry of the reconfiguring mechanism. In one embodiment, each actuation unit 1007 is moved in X and/or Y using or more dedicated actuators. In one embodiment, groups of one or more actuation units are moved in X and/or Y using groups of one or more actuators. In one embodiment, the reconfiguring mechanism rests on fluidic bearings. In one embodiment, the reconfiguring mechanism could be stepped and/or scanned across the relevant substrate. In one embodiment, the reconfiguring grid is in the shape of a rectangle, the shorter arm of which is smaller than the size of the source/product/intermediate substrates. In one embodiment, the reconfiguring grid is in the shape of a single horizontal or vertical line of actuation units.

In one embodiment, the TC actuation units 1007 are attached to a plate such that the pitch of actuation units 1007 is an integer multiple of the field pitch on the source/product/intermediate substrates 103/105/801. The plate could be custom fabricated for each new field layout. The plate could have recesses, or slots, to position actuation units 1007. In one embodiment, the plate has alignment features (pins, for instance) to align actuation units 1007 in the X, Y, Z, θ_{X}, θ_{Y}, and/or θ_{Z} axes. In one embodiment, actuation units 1007 are attached to the plate using an adhesive, flexure-based snap-in mechanisms, magnets, electromagnets, vacuum, etc. or any combination thereof.

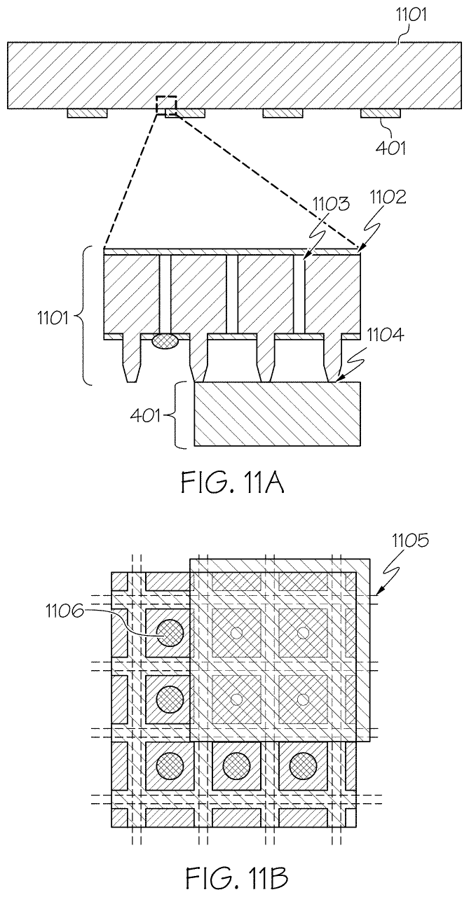

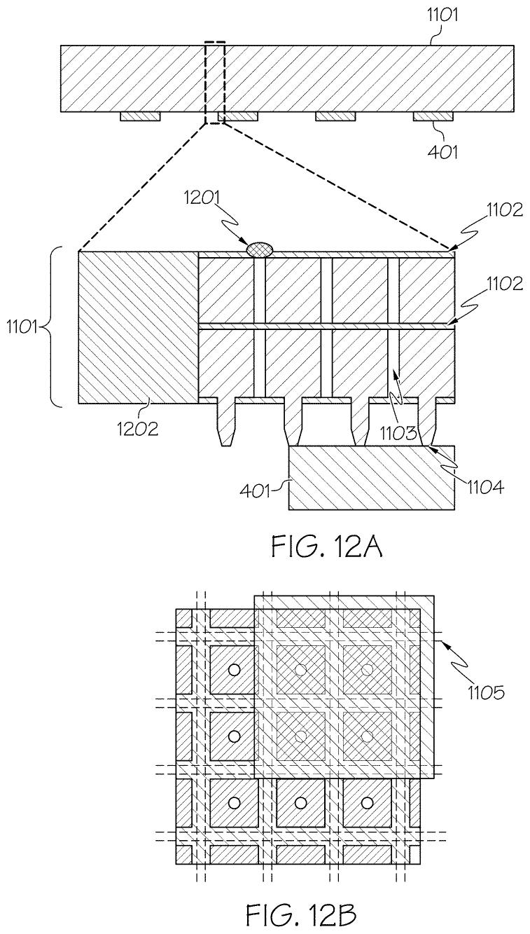

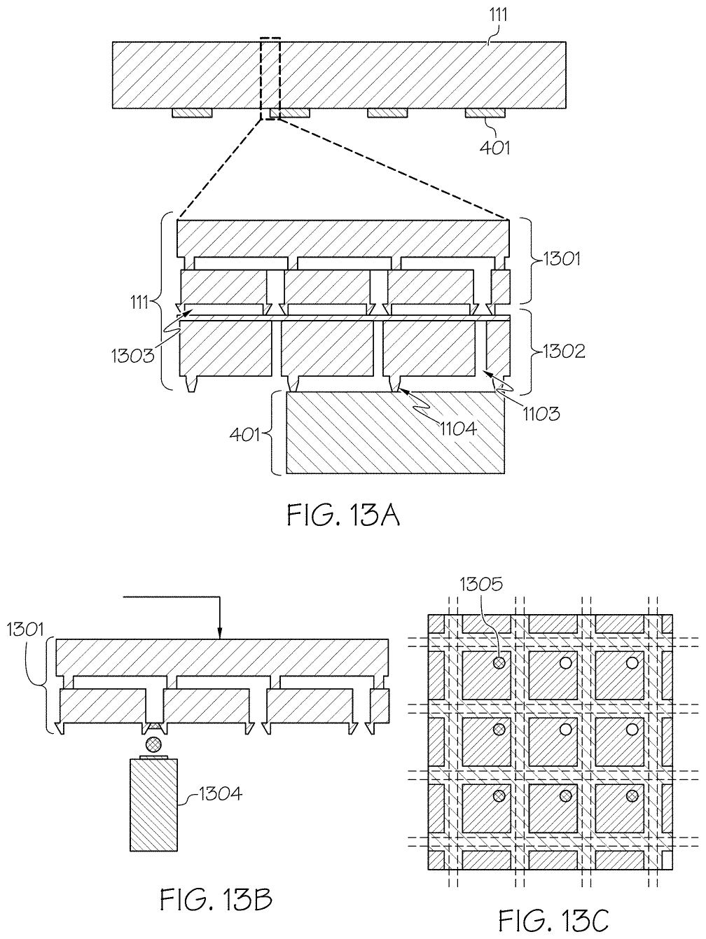

Referring now to FIGS. 11A-11B, FIGS. 11A-11B illustrate an exemplary TC 111 with closed-boundary vacuum and/or pressure regions in accordance with an embodiment of the present invention. FIGS. 12A-12B illustrate an alternative embodiment of an exemplary TC 111 with closed-boundary vacuum and/or pressure regions in accordance with an embodiment of the present invention. FIGS. 13A-13C illustrate a further alternative embodiment of an exemplary TC 111 with closed-boundary vacuum and/or pressure regions in accordance with an embodiment of the present invention.

As shown in FIG. 11A, there is an grid of TCs 111 represented by the assembly of TCs 1101 (identified as “ATC”). As further shown in FIG. 11A, there are optional porous filter membranes 1102 to filter particles in the airstream from reaching the ATC (assembly of TCs) field interface. Furthermore, as shown in FIG. 11A, there is a hole 1103 in filter membranes 1102 for vacuum and/or pressure.

Additionally, as shown in FIG. 11A, there are pins 1104 used to hold fields 401. In one embodiment, such pins 1104 could be optionally tapered at their base to reduce contact area with fields 401.

FIG. 11B illustrates the actual contact edge between ATC 1101 and field 401 at element 1105. Furthermore, FIG. 11B illustrates the optional material 1106 to plug vacuum holes. For example, such material 1106 could be inkjetted.

As shown in FIG. 12A, there are optional porous filter membranes 1102 to filter particles in the airstream from reaching the ATC (assembly of TCs) field interface. Furthermore, as shown in FIG. 12A, there is a hole 1103 in filter membranes 1101 for vacuum and/or pressure running through the thickness of ATC 1101.

Furthermore, as shown in FIG. 12A, there are pins 1104 used to hold fields 401. In one embodiment, such pins 1104 could optionally be tapered at their base to reduce contact area with fields 401.

Additionally, as shown in FIG. 12A, plugging material 1201 is dispensed and/or deposited at the top of ATC 1101. This could prevent contamination of the ATC field interface by such plugging material 1201.

Furthermore, as shown in FIG. 12A, ATC sub-components 1202, such as thermal actuators, X/Y/Z flexures, valve units, etc., are located on the periphery of the vacuum/pressure holes 1103.

FIG. 12B illustrates the actual contact edge between ATC 1101 and field 401 at element 1105.

As shown in FIG. 13A, the top part 1301 of TC 111 could, in one embodiment, be attached to the bottom part using vacuum suction and could be detached to cover the holes using an inkjet.

In one embodiment, bottom part 1302 of TC 111 (that contacts with the picked dies) remains fixed. Furthermore, FIG. 13A illustrates the hole 1103 for vacuum as well as the pins 1104 to hold fields 401. In one embodiment, such pins 1104 could optionally be tapered at their base to reduce contact area with fields 401.

Furthermore, FIG. 13A illustrates an optional porous filter membrane 1303 to filter particles in the airstream from reaching the TC-field interface. In one embodiment, porous filter membrane 1303 is fabricated of porous silicon of sub-100 nm pore size so that it acts as an effective medium. Alternatively, an array of normally-closed silicon cantilever could be used to fabricate porous filter membrane 1303.

In one embodiment, top part 1301 of TC 111 could be brought back to its default un-clogged state using a piranha clean, UV-based cleaning, etc. If the cleaning process is slow, multiple TCs 111 could be used.

FIG. 13B illustrates an inkjet 1304 dispensing UV-curable adhesive into the conical hole 1103. In one embodiment, in order to minimize surface area, the drop may rest stably at the top of the cone.

FIG. 13C illustrates the vacuum holes 1103 being plugged as shown at element 1305.

Referring to FIGS. 11A-11B, 12A-12B and 13A-13C, in one embodiment, TC 1101 has closed-boundary vacuum and/or pressure regions (in contrast to the conventional open-boundary vacuum regions in semiconductor pin chucks). Pins 1104 could have a tapered cross-section to reduce the contact area between TC 111 and the picked fields 401. The tapering could be produced using etch techniques including crystallographic etching, isotropic etching, anisotropic etching (for instance, reactive ion etching), etc. and any combinations thereof. In one embodiment, the vacuum and/or pressure in the closed-boundary regions is switched on and off by plugging them with a plugging material 1201. The plugging could be performed using an inkjet. Alternatively, a masked plasma-based deposition process could be used to deposit plugging material 1201. In one embodiment, plugging is done using a SiLK-type volatile-liquid-and-oxide mixture. The pore size of the porous oxide (left behind after evaporation of volatile components) could be optimized such that the airflow through the oxide is minimal. Plugging material 1201 could later be removed by a plasma jet, chemical etchant (vapor HF, for instance), heating (to evaporate the plugging material) to return TC 111 back to its default state, etc. and any combination thereof. In one embodiment, the field size (X and/or Y) is constrained to be an integer multiple of the pitch of TC pins 1104. In one embodiment, the plugging material dispenser is part of the pick-and-place tool. TC 111 could also contain optional porous membranes 1102 as shown in FIGS. 11A and 12A, to limit particle contamination from one part of TC 111 to another part. In one embodiment, porous membranes 1102 could be made of a transparent (for instance, in IR radiation) porous polymer, porous silicon, etc. or any combination thereof. The pore size of porous membranes 1102 could be optimized such that the airflow restriction is minimal while contaminants are filtered out. Alternatively, a normally closed array of micromachined cantilevers placed above each vacuum/pressure hole 1103 could be used for contaminant filtering. These could be made from silicon, silicon oxide, transparent polymer, etc. or any combination thereof. Optionally, the vacuum and/or pressure holes 1103 could have conical geometries (in part or entirety) such that dispensed adhesive has a preferred resting spot that is at the top of the conical geometry. The conical geometry could, for instance, be constructed using crystallographic etching.

In one embodiment, the suction-creating layer on TC 111 (that touches the picked field) could be custom fabricated to match the grid of the picked fields 401. The custom suction-creating layer could be attached to the rest of TC 111 using vacuum suction, adhesive(s), electrostatic forces, magnetic forces, electromagnetic forces, etc. or any combination thereof.

In one embodiment, plasma producing units, such as plasma units 110, are utilized to clean the bonding surfaces immediately prior to bonding.

In one embodiment, plasma producing units, such as plasma units 110, operate at atmospheric pressure. In one embodiment, such plasma producing units are produced by Surfx® Technologies.

In one embodiment, plasma units, such as plasma units 110, cover the area of the entire source/product/intermediate substrates 103/105, 801.

In one embodiment, plasma units, such as plasma units 110, are scanned over the area of the source/product/intermediate substrates 103/105/801. Plasma units, such as plasma units 110, could be mounted on motion stages that can travel along the X axis, Y axis, and/or Z axis. In one embodiment, plasma units, such as plasma units 110, are mounted on a retractable plate that retracts out of the way of fields 401 once plasma treatment is completed.

In one embodiment, plasma units, such as plasma units 110, face upwards to treat downward facing fields 401.

In one embodiment, plasma units, such as plasma units 110, face downwards to treat upward facing fields 401.

In one embodiment, the upward and downward facing plasma heads are synchronized such that as the upward facing units treat the downward facing fields 401, the downward facing units treat the upward facing fields 401.

In one embodiment, multiple source/product/intermediate substrates 103/105/801 are plasma treated in a separate chamber of the n-MASC tool.

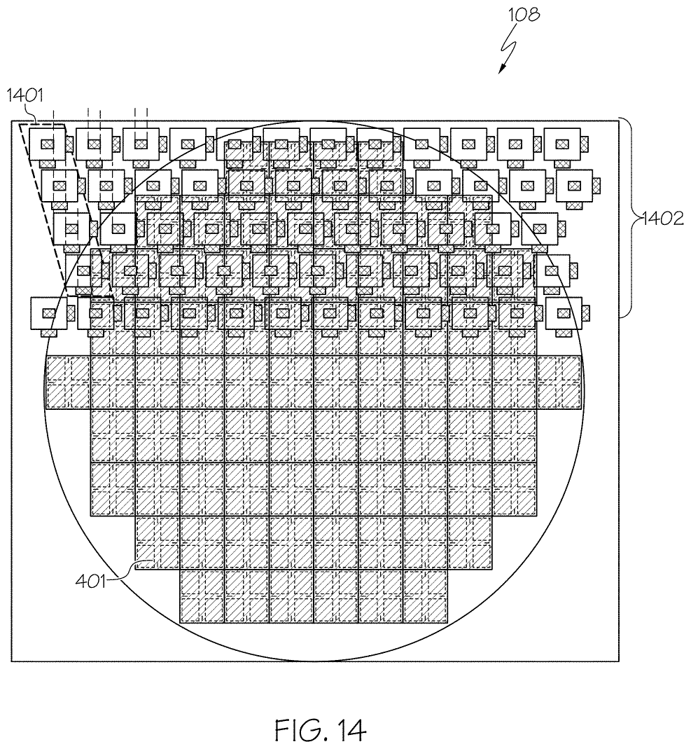

Referring now to FIG. 14, FIG. 14 illustrates an exemplary sensor arrangement for an exemplary metrology module 108 in accordance with an embodiment of the present invention.

As shown in FIG. 14, metrology module 108 includes an exemplary single interchangeable unit of imagers 1401. In one embodiment, metrology module 108 has about 30 such units in total. In one embodiment, image sensors 1401 could have a light insensitive region surrounding the light sensitive region.

Furthermore, as shown in FIG. 14, metrology module 108 has an exemplary single “line” of imagers 1402. In one embodiment, metrology module 108 has about 2.5 total lines of imagers. Additionally, FIG. 14 illustrates an exemplary scanning-based approach to acquire X and Y alignment data for all fields 401 picked by TC 111.

In one embodiment, metrology module 108 corresponds to a full reconfigurable array of imagers 1401 that is 300 mm×300 mm.

In one embodiment, the exemplary field 401 has a horizontal length of 25 mm and a vertical length of 30 mm. In one embodiment, field 401 has up to 8 total alignment marks (4 for X and 4 for Y alignment). Furthermore, field 401 may have alignment marks in layer 0 or half-kerf.

In one embodiment, imager 1401 consists of a short-wave infrared (SWIR) sensor (e.g., Sony® IMX990-AABJ-C). In one embodiment, there are about 130 such sensors in metrology module 108.

In one embodiment, an exemplary Y-scan for metrology module 108 travels about 300 mm. In one embodiment, an exemplary X-scan for metrology module 108 travels about 190 mm.

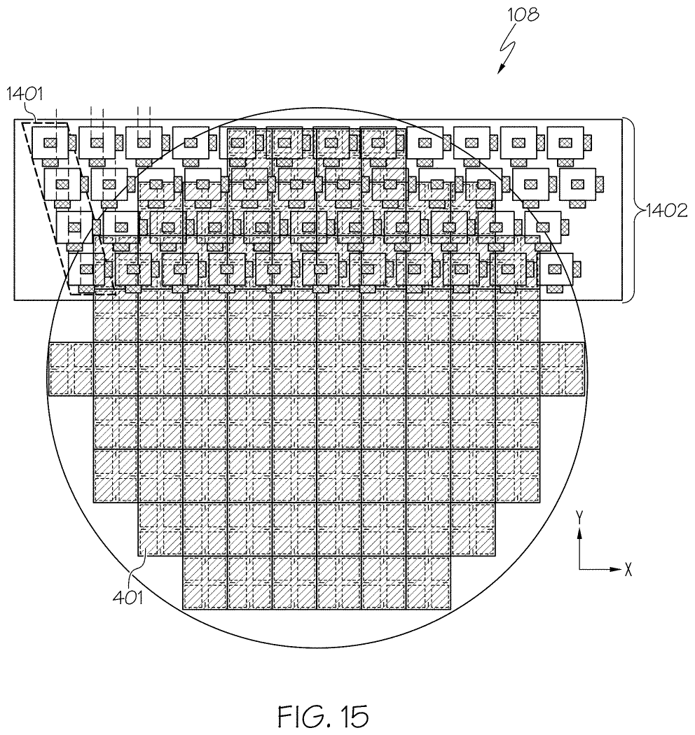

Referring now to FIG. 15, FIG. 15 illustrates an alternative exemplary sensor arrangement for an exemplary metrology module 108 in accordance with an embodiment of the present invention.

As shown in FIG. 15, metrology module 108 includes an exemplary single interchangeable unit of imagers 1401. In one embodiment, metrology module 108 has about 12 such units in total.

Furthermore, as shown in FIG. 15, metrology module 108 has an exemplary single “line” of imagers 1402. In one embodiment, metrology module 108 has only 1 line of imagers.

In one embodiment, an exemplary Y-scan for metrology module 108 travels about 500 mm. In one embodiment, an exemplary X-scan for metrology module 108 travels about 3×190 mm (i.e., performs an X-scan of metrology module 108 that travels 190 mm 3 separate times).

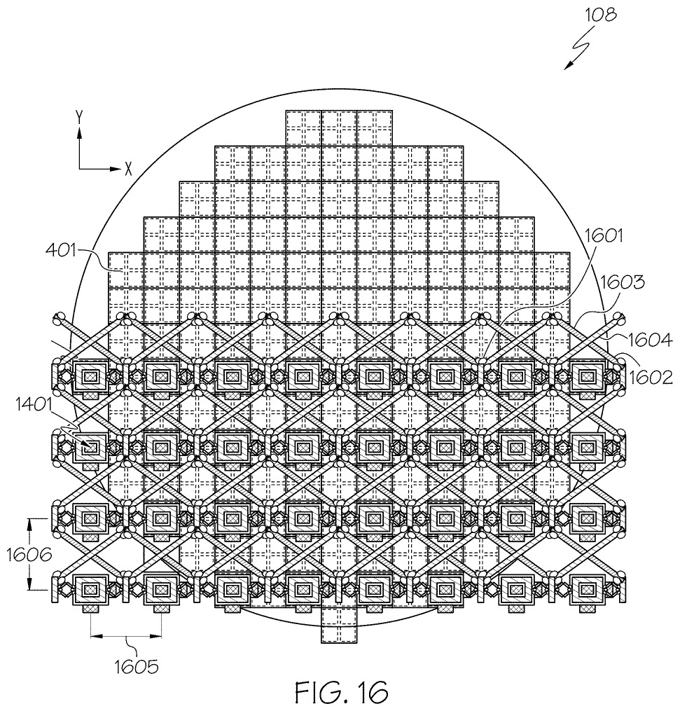

FIG. 16 illustrates an exemplary reconfiguring-grid sensor arrangement for an exemplary metrology module 108 in accordance with an embodiment of the present invention.

As shown in FIG. 16, there is optionally a pair of overlaid “base plates” 1601. These base plates 1601 are optionally unconnected, which facilitates independent X and Y expansion.

Furthermore, as shown in FIG. 16, there is optionally a monolithically fabricated Y reconfiguring array 1602. Links 1603 (darker shaded) lie in a different plane compared to the lighter shaded links 1604. The X reconfiguring array (not shown in FIG. 16) could be fabricated separately and optionally overlaid on top of Y reconfiguring array 1602.

Furthermore, FIG. 16 illustrates the locations 1605 for an exemplar force application to reconfigure the imager X grid. Additionally, FIG. 16 illustrates the locations 1606 for an exemplar force application to reconfigure the imager Y grid.

Additionally, FIG. 16 illustrates that faulty imagers 1401 can be individually replaced.

In one embodiment, the exemplar field 401 has a horizontal length of 20 mm and a vertical length of 20 mm. In one embodiment, field 401 has up to 8 total alignment marks (4 for X and 4 for Y alignment).

In one embodiment, imager 1401 consists of a short-wave infrared (SWIR) sensor (e.g., Sony® IMX990-AABJ-C). In one embodiment, there are about 20 such sensors in metrology module 108.

In one embodiment, metrology module 108 corresponds to a full reconfigurable array of imagers 1401 that is 300 mm×300 mm.

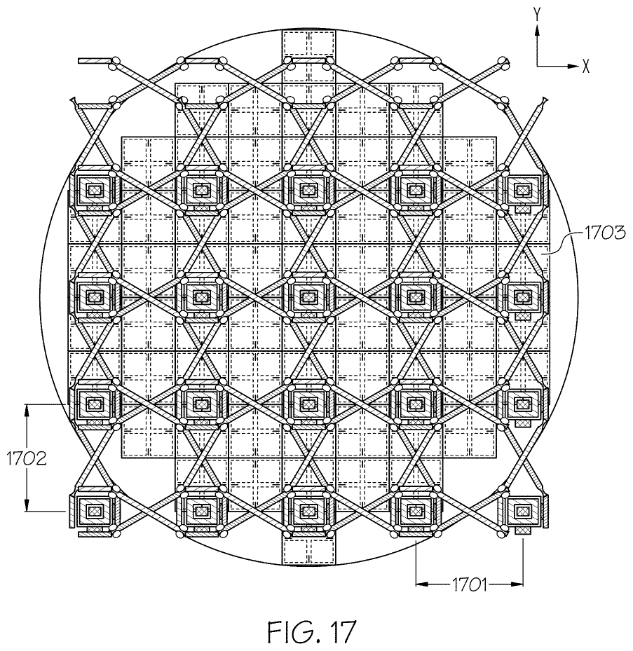

Referring now to FIG. 17, FIG. 17 illustrates the reconfiguring-grid sensor arrangement shown in FIG. 16 expanded out to acquire 30 mm×3 mm fields in accordance with an embodiment of the present invention.

FIG. 17 illustrates the locations 1701 for an exemplary force application to reconfigure the imager X grid. Additionally, FIG. 17 illustrates the locations 1702 for an exemplary force application to reconfigure the imager Y grid.

Furthermore, FIG. 17 illustrates the X reconfiguring array 1703 that is overload on top of the Y reconfiguring array (not shown in FIG. 17).

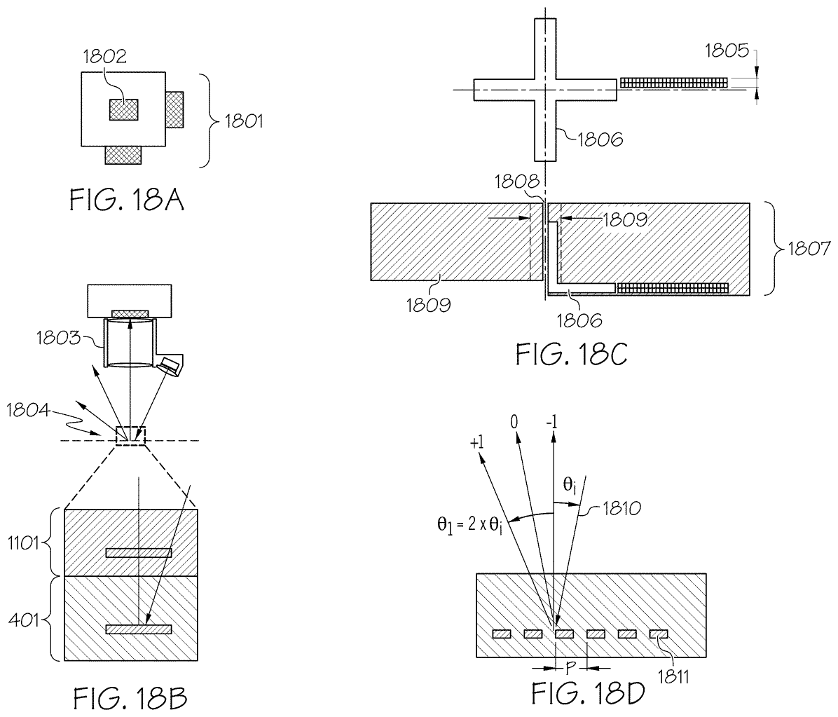

Referring now to FIGS. 18A-18D, FIGS. 18A-18D illustrate an exemplary alignment metrology framework for an exemplary metrology module 108 in accordance with an embodiment of the present invention.

As shown in FIG. 18A, such a framework includes a top view of the SWIR imager sub-assembly 1801 which includes a light sensitive region 1802 of the SWIR sensor. In one embodiment, both coarse (box-in-box type) and fine (moiré) alignment marks are acquired by the same imager and optics. In one embodiment, 1× magnification optics are implemented. In one embodiment, reflective moiré is utilized.

Furthermore, telecentric focusing optics 1803 are utilized. In one embodiment, such optics 1803 include a numerical aperture of about 0.2, a resolution at 1.4 μm of about 4.2 μm, a depth-of-field at 1.4 μm of about 20 μm and a magnification of 1X.

Additionally, FIG. 18A illustrates a staggered sensor design 1804 that ensures that the back-reflected light from the 0^{th} and 1^{st} orders do not end up contaminating the neighboring imagers.

FIG. 18B illustrates a cross-section view of the staggered sensor design, such as the portion of the ATC 1101 containing an alignment mark as well as a portion of field 401 containing an alignment mark.

FIG. 18C illustrates the top views of the staggered sensor design consisting of two counter-propagating moiré marks 1805. In one embodiment, the total height is around 20 μm.

Furthermore, FIG. 18C illustrates imaging-based marks 1806, such as in the picked fields 1807, as well as illustrates the improved kerf (about 5 μm) at 1808, where the standard kerf is about 60 μm at 1809.

If the alignment marks are patterned on layer 0, or in the inter-die kerf (in the case when an entire field composed of multiple dies is picked up), full kerf width could potentially be available for creating alignment marks.

Alternatively, a MAC-based dicing technique could be used to create micrometer-scale-thick kerf cuts with sharp corners. This could allow most of the kerf region that was previously unavailable to be used for alignment mark placement.

FIG. 18D illustrates the normally-back-diffracting moiré metrology. As shown in FIG. 18D, incident light 1810 is reflected from moiré gratings 1811. For the 1^{st} order to return along the grating normal towards the SWIR sensor, the following grating equation would be satisfied: sin(θ₁)=sin(2θᵢ)=sin(θᵢ)+λ/ρ.

The detection precision using imaging-based marks (assuming 5 μm SWIR pixel pitch and 1/10 sub-pixel detection) is approximately 0.5 μm. However, the detection precision using moiré marks (assuming ρ₁, ρ₂=3, 3.05 μm, 1/10 sub-pixel detection) is approximately 8 nm. Furthermore, the moiré phase-unambiguous capture range is approximately 1.5 μm,

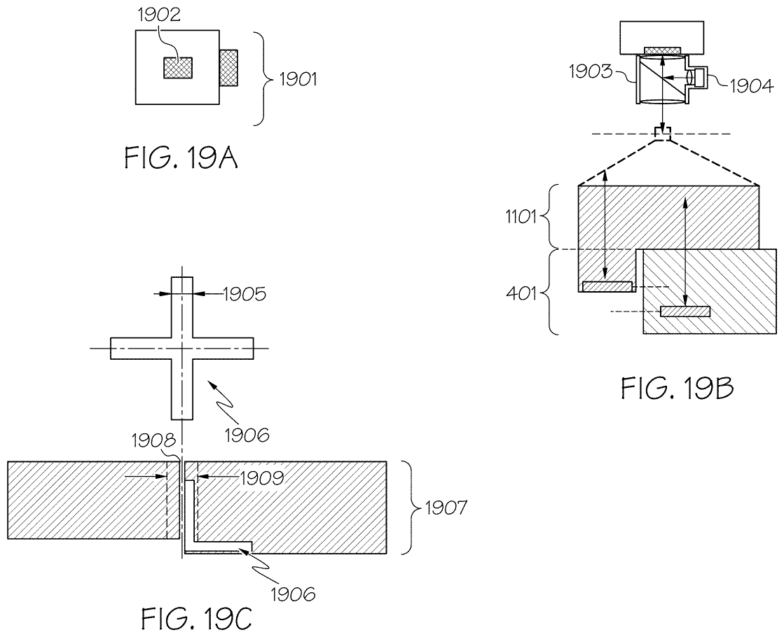

FIGS. 19A-19C illustrate an alternative exemplary alignment metrology framework for an exemplary metrology module 108 in accordance with an embodiment of the present invention.

FIG. 19A illustrates a top view of the SWIR imager sub-assembly 1901 which includes a light sensitive region 1902 of the SWIR sensor. In one embodiment, 1× magnification optics are implemented. In one embodiment, reflective imaging is utilized.

Furthermore, FIG. 19A illustrates focusing optics 1903. In one embodiment, such optics 1903 include a numerical aperture of about 0.5, a resolution at 1.4 μm of about 1.8 μm, a depth-of-field at 1.4 μm of about 3.6 μm and a magnification of 1X.

Additionally, FIG. 19A illustrates that focusing optics 1903 includes IR LED and focusing optics 1904

FIG. 19B illustrates a cross-section of the metrology plane, which includes a portion of the ATC 1101 containing an alignment mark as well as a portion of field 401 containing an alignment mark.

FIG. 19C illustrates the top views of the metrology plane consisting of two counter-propagating moiré marks 1905.

Furthermore, FIG. 19C illustrates imaging-based marks 1906, such as in the picked fields 1907, as well as illustrates the improved kerf (about 5 μm) at 1908, where the standard kerf is about 60 μm at 1909.

If the alignment marks are patterned on layer 0, or in the inter-die kerf (in the case when an entire field composed of multiple dies is picked up), full kerf width could potentially be available for creating alignment marks.

Alternatively, a MAC-based dicing technique could be used to create micrometer-scale-thick kerf cuts with sharp corners. This could allow most of the kerf region that was previously unavailable to be used for alignment mark placement.

Furthermore, in such an embodiment, the detection precision using imaging-based marks (assuming 1 μm SWIR pixel pitch and 1/20 sub-pixel detection) is approximately 90 nm.

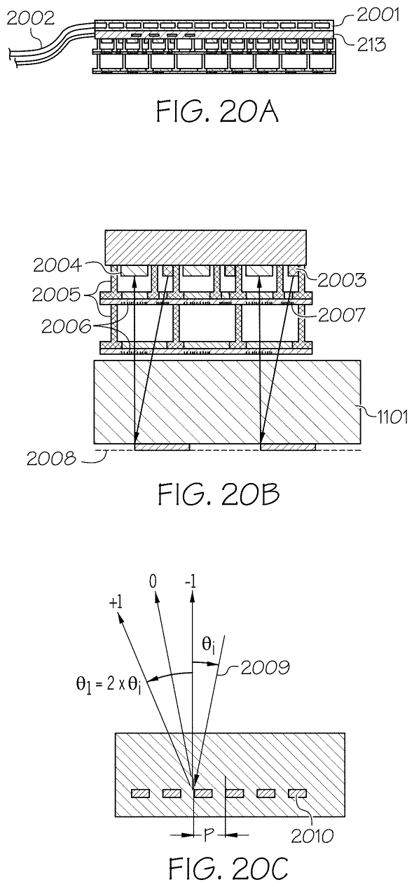

FIGS. 20A-20C illustrate the details regarding an exemplary metrology module 108 in accordance with an embodiment of the present invention.

FIG. 20A illustrates the flow-based cooler 2001 for the SWIR sensors and LEDs. Furthermore, FIG. 20A illustrates the custom 300 mm thermally-conductive PCB board 213 for the IR sensor and the LED array. Additionally, FIG. 20A illustrates PCB wiring and heat exchanger fluid harnesses 2002.

FIG. 20B illustrates the SWIR LED 2003 and the SWIR sensor 2004 being directly integrated onto the custom PCB 213. Furthermore, FIG. 20B illustrates the machined metal frame 2005 which acts as an LED/sensor enclosure. Additionally, FIG. 20B illustrates flat lenses 2006 forming a magnifying telecentric pair, microfabricated on 300 mm glass substrates. Additionally, FIG. 20B illustrates the off-axis LED focusing optics 2007 and the moiré plane 2008.

FIG. 20C illustrates the expanded view of ATC 1101 along the moiré plane 2008. As shown in FIG. 20C, incident light 2009 is reflected from moiré gratings 2010. For the 1^{st} order to return along the grating normal towards the SWIR sensor, the following grating equation would be satisfied: sin(θ₁)=sin(2θᵢ)=sin(θᵢ)+λ/ρ. For example, with an incident wavelength of 1.4 μm and a grating pitch of 5 μm, the incident angle θ that satisfies the above condition is approximately 18 degrees.

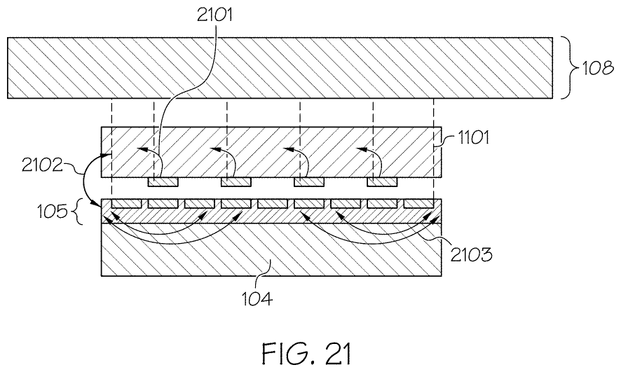

FIG. 21 illustrates an exemplary metrology framework in accordance with an embodiment of the present invention.

Referring to FIG. 21, FIG. 21 illustrates the alignment measurement between ATC 1101 and the picked fields (using MM 108) via element 2101. Furthermore, FIG. 21 illustrates a global alignment 2102 between ATC 1101 and product wafer 105. Additionally, FIG. 21 illustrates product substrate 105 with layer 1 already assembled as well as product substrate chuck 104 to hold product substrate 105.

Furthermore, FIG. 21 illustrates that the registration of fields 401 on product wafer 105 is pre-characterized (see element 2103), potentially outside the MM tool 108.

It is noted that FIG. 21 only shows the bounding box for MINI 108. The actual MM assembly could be within this bounding box.

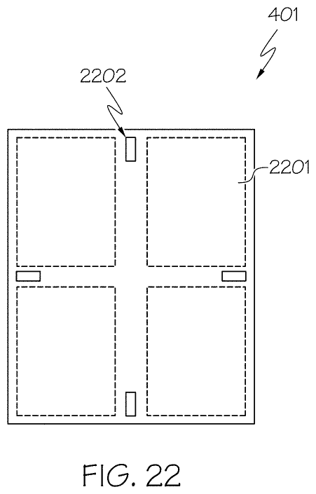

FIG. 22 illustrates an exemplary field 401 containing a 2×2 array of dies 2201 in accordance with an embodiment of the present invention. Furthermore, FIG. 22 illustrates alignment mark locations 2202.

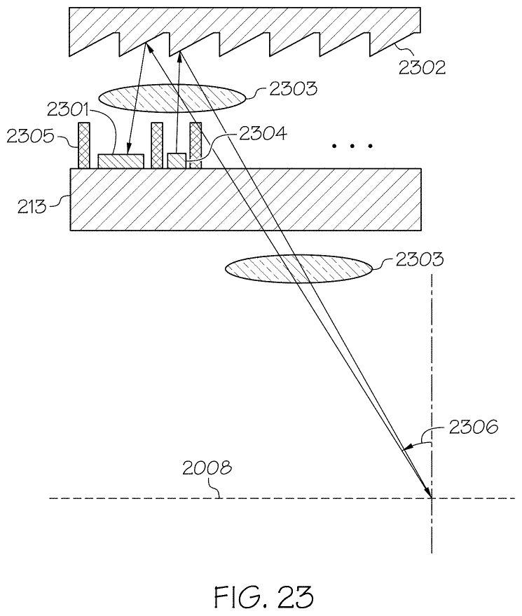

FIG. 23 illustrates an exemplary metrology framework in accordance with an embodiment of the present invention.

As shown in FIG. 23, imager 2301 (e.g., SWIR sensor) includes reflective blaze gratings 2302. Furthermore, as shown in FIG. 23, the metrology framework may include focusing optics 2303 to focus light from a light source 2304 (e.g., LEDs) onto opaque enclosure walls 2305 on a transparent PCB 213.

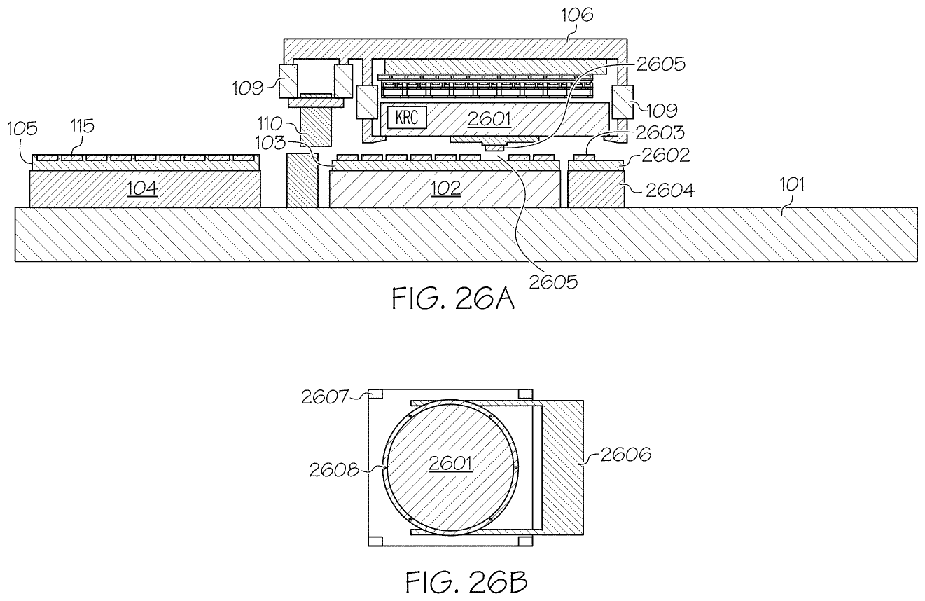

Furthermore, as shown in FIG. 26, a Littrow angle 2306 is formed from the reflected light at the moiré plane 2008.

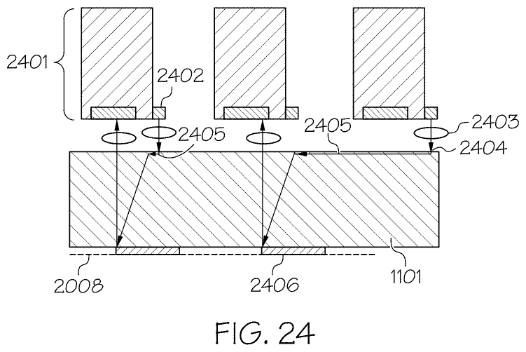

FIG. 24 illustrates another embodiment of an exemplary metrology framework in accordance with an embodiment of the present invention.

As shown in FIG. 24, an integer assembly 2401 comprised of light sources 2402 (e.g., LEDs) with focusing optics 2403 to focus light emanating from light sources 2402 to ATC 1101.

In one embodiment, diffractive elements at the locations identified by element 2404 couple light into and out of light guides at specified angles. Photonic light guides 2405 patterned into ATC 1101 could be fabricated in a custom layer which is attached to the rest of ATC 1101 using adhesive, vacuum, electromagnetic force, magnetic force, electrostatic force, etc. or any combinations thereof.

In one embodiment, photonic light guides 2405 guides the light onto picked fields 2406 on ATC 1101 at the moiré plane 2008.

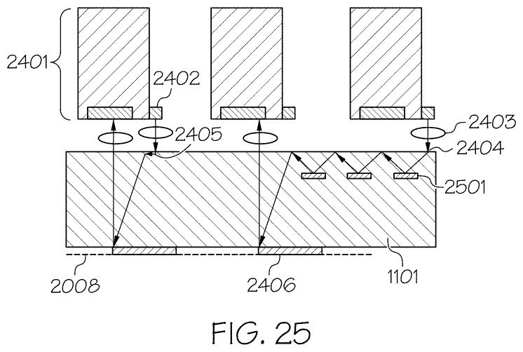

FIG. 25 illustrates a further embodiment of an exemplary metrology framework in accordance with an embodiment of the present invention.

Referring to FIG. 25, FIG. 25 illustrates a series of diffractive elements 2501 to guide light from the light source to the alignment mark.

Referring to FIGS. 14-17, 18A-18D, 19A-19C, 20A-20C and 21-25, in one embodiment, metrology module 108 is used to measure overlay, alignment, in-plane, and/or out-of-plane distortion errors of picked fields 401, TCs 111, source substrates 103, intermediate substrates 801, and/or product substrates 105. In one embodiment, metrology module 108 is used to measure overlay of fields 401 just prior to assembly onto product substrate 105. In one embodiment, metrology module 108 is used to measure the in-plane distortion of one or more fields 401 on source substrates 103, intermediate substrates 801, and/or product substrates 105.

In one embodiment, metrology module 108 conducts measurements on all fields 401 on TC 111 simultaneously.

In one embodiment, metrology module 108 incorporates one or more imager units 1401. In one embodiment, imager units 1401 are sensitive to visible radiation, infrared radiation, short-wavelength infrared radiation (SWIR), etc.

In one embodiment, one or more light sources 2402 are used to illuminate the metrology targets. In one embodiment, light source 2402 incorporates light emitting diodes (LED), laser diodes, fiber guided light sources, vertical-cavity surface-emitting lasers (VCSELs), etc. or any combination thereof. Alternatively, edge-lighting could be used as light source 2402 for the metrology, where the light is injected from the sides of an edge-lighting substrate and transported to the relevant regions using photonic crystal-based light guiding, for instance. In one embodiment, light sources 2402 are mounted on a printed circuit board. In one embodiment, light sources 2402 are mounted adjacent to imager units 1401. In one embodiment, light source 2402 sends light towards the metrology targets at an angle using an off-axis lens. Alternatively, light source 2402 sends light towards the metrology target at an angle using one or more mirrors. The mirror assembly could be constructed using reflective blaze gratings. The blaze gratings could be coated with a metal. The blaze gratings could be manufactured on silicon, sapphire, silicon oxide, glass, and/or polymer substrates. In one embodiment, the light from light source 2402 is incident at the Littrow angle 2306. In another embodiment, the light from light source 2402 is incident at an angle such that one of the first diffracted orders from the metrology marks returns towards imagers 1401 along the field normal direction.

In one embodiment, imager units 1401 are mounted on a printed circuit board. In one embodiment, light sources 2402 are mounted on a printed circuit board. In one embodiment, imager units 1401 and light sources 2402 are mounted together on a printed circuit board. In one embodiment, light sources 2402 and imager units 1401 mounted on the printed circuit board are optically isolated using a dark machined frame. In one embodiment, the printed circuit board is thermally conductive.

In one embodiment, an array of lenses patterned on silicon, sapphire, glass, silicon oxide, and/or polymer substrates are utilized to direct light from light source 2402 onto the metrology marks and focus light from the metrology marks onto the imager array. In one embodiment, the lens array incorporates annular lens-like regions etched into the lens array substrate. In one embodiment, the lens array incorporates a group of concentric metal annuli. Alternatively, the lens array incorporates meta-lenses that are made out of etched substrate, metal, and high refractive index materials, such as titanium oxide. In one embodiment, the lens arrays form telecentric couples for focusing light onto the imager array.

In one embodiment, the metrology scheme is based on the principle of moiré-based spatial phase sensing. In one embodiment, the metrology scheme is based on on-axis moiré metrology. In one embodiment, the metrology scheme is based on circular moiré metrology. In one embodiment, purely imaging-based metrology is utilized (e.g., box-in-box alignment mark metrology). In one embodiment, a focus variation system is utilized to maintain focus at two or more different planes during metrology. Focus variation could, for instance, be achieved using a zoom lens. In one embodiment, one or more of the methods mentioned in this paragraph are utilized concurrently.

In one embodiment, metrology is performed in a reflective mode, where light source 2402 is on the same side of the metrology marks as imager units 1401. In another embodiment, metrology is performed in a transmissive mode, where light source 2402 is on the opposite side of imager units 1401.

In one embodiment, the metrology scheme uses visible light. In one embodiment, the metrology scheme uses infrared light.

In one embodiment, de-magnifying optics is used to observe a substrate area larger than the size of imager units 1401. In another embodiment, magnifying optics are used to observe a substrate area smaller than the size of imager units 1401. In one embodiment, sub-pixel edge-detection techniques are used to detect edges in the metrology signal.

In one embodiment, metrology module 108 is placed on a motion stage that moves in the X, Y, and/or Z axes. In one embodiment, metrology module 108 captures information from all fields currently being assembled by stepping and/or scanning by appropriate amounts along the X, Y, and/or Z axes.

In one embodiment, metrology marks are placed near one or more corners of fields 401 being assembled. Fields 401 could be free of circuit elements in the layers above and below the metrology marks. In one embodiment, metrology marks are placed in the kerf region of fields 401. In one embodiment, field 401 consists of two or more dies, each of which is separated from one another by a kerf region, and this inter-die kerf region contains one or more alignment marks.

In one embodiment, metrology is conducted in real-time as fields 401 are being bonded onto product substrate 105. In another embodiment, metrology is conducted prior to the bonding occurring. In one embodiment, a feedforward model is utilized to correct the repeatable components of field distortions.

In one embodiment, metrology module 108 measures alignment between fields 401 picked up by TC 111, where TC 111 has embedded alignment marks that match the field grid. Metrology module 108 could subsequently align TC 111 to product substrate 105 using metrology marks placed near the edge region and/or the kerf regions of TC 111 and product substrate 105. In one embodiment, real-time topography mapping of the picked fields 401 and product substrate 105 is performed, and the predicted error compensated for by overlay control actuators (thermal actuators, for instance). In one embodiment, a single topography measurement is performed on each field 401. The topography mapping could be performed using air gages (for instance). The array of air gages could be installed next to PCB 213, for instance. Air curtains could also be used to cool product substrate 105 and the picked fields 401 in case PCB 213 heats them up to a significant extent.

In one embodiment, on-axis alignment methods are used in metrology module 108.

In one embodiment, TC 111 has gratings attached and/or patterned on it to track XY displacement with high accuracy.

In one embodiment, alignment marks are placed on fields 401 within the half-kerf region (as shown in FIGS. 18C and 19C). As an alternative to patterning the alignment marks inside half of the kerf (or half-kerf), a MACE based dicing process could be used to enable alignment marks in the full kerf region. In one embodiment, alignment marks are placed on fields 401 in the metal 0 (M0) layer.

In one embodiment, very large sensors are used for alignment detection in metrology module 108.

In one embodiment, photonic crystal-based light guiding techniques are used to illuminate the alignment marks at the correct angle and location.

In one embodiment, local data processors are associated and placed in close proximity to one or more of the image sensors 1401. These data processors could be used to perform sensor-local image processing. In one embodiment, the data processing is fabricated as part of image sensor 1401 (an in-sensor computer).

In one embodiment, a fixed grid of image sensors 1401 is used. In one embodiment, image sensors 1401 are arranged in a linear array, a staircase-type array, or a combination of the two. In one embodiment, image sensors 1401 are arranged such that the region of the substrate captured by one of the sensors overlaps with the region of the substrate captured by the next nearest image sensor 1401, such that the entire array of sensors captures a continuous and uninterrupted swath of the substrate. In one embodiment, image sensors 1401 contain a light sensitive area surrounding a light insensitive area. In one embodiment, light sources 2402 are mounted in this light insensitive area, at an angle if required, and encased on the sides in an opaque covering (to prevent contamination of the sensor with stray light). Light from light source 2402 is passed through focusing optics 2303 and is incident towards the metrology plane. Light source 2402 is designed such that the depth of the beam (along the Z axis) is the same as the depth of image sensor 1401. If the incident light lands upon overlaid metrology marks, light is reflected in the direction normal to the substrate towards image sensors 1401. The light incident towards image sensors 1401 from the metrology mark plane is focused onto the sensors using 1× magnification low-numerical-aperture optics. The sensor array is scanned in the X direction (see FIGS. 14 and 15) to gather Y overlay data (for instance) for the entire substrate. A second sensor array, which is orthogonal to the first sensor array, is used to gather X overlay data (for instance) for the entire substrate. Alternatively, the same sensor array, as is used for Y overlay data collection, could be used for gathering X overlay data as well by scanning in a serpentine, stepping to a new location, and scanning a serpentine again (see FIGS. 14 and 15).

In one embodiment, a reconfiguring arrangement of image sensors 1401 is used. In one embodiment, the reconfiguring arrangement is fabricated monolithically. In one embodiment, the reconfiguring arrangement is constructed by stacking one or more layers, each of which is monolithically fabricated. In one embodiment, the reconfiguring arrangement is made using bulk metal, bulk polymer, thin coatings, etc. In one embodiment, the reconfiguring arrangement is made using steel, stainless steel, chrome, etc. In one embodiment, the reconfiguring arrangement consists of flexure elements. In one embodiment, the flexure elements are arranged so as to form scissor mechanisms between each pair of image sensors. In one embodiment, separate reconfiguring arrangements are utilized for reconfiguring along the X and Y directions. These arrangements could be stacked on top of each other. Each arrangement could be actuatable in one direction while being free to move in the orthogonal direction. In one embodiment, the actuation of the reconfiguring arrangement is produced using actuators (e.g., voice coil motors, piezoelectric actuators, thermal actuators, etc.) placed at one or more locations on or within the periphery of the reconfiguring arrangements. In one embodiment, the actuators are placed on the axes of symmetry of the reconfiguring arrangement. In one embodiment, each sensor is moved in the X and/or Y direction using one or more dedicated actuators. In one embodiment, groups of sensors are moved in the X and/or Y direction using groups of actuators. In one embodiment, the reconfiguring arrangement rests on fluidic bearings. In one embodiment, the reconfiguring arrangement could be stepped and/or scanned across TC 111. In one embodiment, the reconfiguring arrangement is in the shape of a rectangle, the shorter arm of which is smaller than the size of the source/product/intermediate substrates 103/105/801. In one embodiment, the reconfiguring arrangement is in the shape of a single horizontal or vertical line of sensors.

In one embodiment, image sensors 1401 are attached to a plate such that the pitch of image sensors 1401 is an integer multiple of the field pitch on the TC(s)/source/product/intermediate substrates (111/103/105/801). The plate could be custom fabricated for each new field layout. The plate could have recesses, or slots, to position image sensors 1401. The plate could have alignment features (pins 1104, for instance) to align image sensors 1401 in the X, Y, Z, θ_{X}, θ_{Y}, and/or θ_{Z} axes. Image sensors 1401 are attached to the plate using an adhesive, flexure-based snap-in mechanisms, magnets, electromagnets, vacuum, etc.

In one embodiment, metrology module 108 is separated from the rest of the pick-and-place tool using a transparent window. In one embodiment, metrology module 108 is placed behind a transparent window such that there is no mass transfer between metrology module 108 and the rest of the pick-and-place tool. In one embodiment, metrology module 108 is placed in a hermetically sealed chamber with a transparent window facing TC 111. In one embodiment, the hermetically sealed chamber has a door to take out and/or put in metrology module 108.

In one embodiment, the topography (as well as the registration of fields 401 to a known grid) on product substrate 105 is measured prior to the attachment of picked fields 401 onto one or more intermediate substrates. In one embodiment, the topography of picked fields 401 on TC 111 (as well as the registration of picked fields 401 to a known grid) is measured prior to the attachment of fields 401 onto one or more intermediate substrates. In one embodiment, the measured topography and registration information on product substrate 105 and picked fields 401 on TC 111 is utilized to actuate picked fields 401, and partially or wholly compensate for the overlay error which would result if the final bonding step onto product substrate 105 (intermediate substrate to product substrate bonding) was uncompensated. The prediction of the overlay error based on topography and registration data could be conducted using mechanical modeling techniques. In one embodiment, the temperature of fields 401 on TC 111, as well as the temperature of product substrate 105, are maintained within a small window (e.g., 10 mK, for instance). In one embodiment, a single topography measurement is performed on each field 401 on TC 111 and product substrate 105. The topography mapping could be performed using air gages (for instance).

In one embodiment, groups of image sensors 1401 (consisting of one or more image sensors 1401) use a dedicated and/or local data processor to process the entire or a portion of the image processing pipeline used to determine the metrology output (e.g., overlay, alignment, topography, etc.) from the captured images. In one embodiment, the data processor is a single-board computer.

In one embodiment, custom light paths (that transport light incident from light sources 2402 to locations ideal for projection onto the alignment marks) are patterned into TC 111. In one embodiment, the light paths are made in a custom layer which is attached to the rest of TC 111. In one embodiment, the attachment is performed using adhesive, vacuum, electromagnetic force, magnetic force, electrostatic force, etc. In one embodiment, the light paths consist of only transmissive and reflective diffracting structures. In one embodiment, the light paths are created using nanoimprint lithography (NIL). In one embodiment, the light paths consist of repeating standardized sections, which could be patterned using a limited number of fixed masks or reticles.

The bulk HF etcher is used to create tethers in the sacrificial layer of one or more source substrates.

In one embodiment, substrates are arranged horizontally on a multi-substrate chuck. In another embodiment, substrates are arranged vertically on a multi-substrate rack.

In one embodiment, in-situ metrology for endpoint and uniformity measurement is conducted for one or more of the substrates being etched.

A stocker unit could be used to store multiple, fully and partially populated, source/product/intermediate substrates 103/105/801. The stocker unit could be used to store TC unit 111 and metrology unit 108 as well. In one embodiment, TCs 111 could have fields 401 attached to them. In one embodiment, the stocker unit has dedicated vacuum sources with emergency power backup to supply vacuum to the stored TCs 111.

In one embodiment, the stocker unit has temperature and humidity control.

In one embodiment, single or multiple robotic handler units could be used to move individual substrates, substrate groups, TCs 111, metrology units 108 between various parts of the n-MASC tool, etc.

Referring now to FIGS. 26A-26B, FIGS. 26A-26B illustrate an exemplary known-bad-die replacement chuck (KRC) 2601 in accordance with an embodiment of the present invention.

As shown in FIG. 26A, a buffer substrate 2602 is populated with known good dies 2603, where buffer substrate 2602 is held by buffer substrate chuck 2604.

Furthermore, as shown in FIG. 26A, a known bad die 2605 is replaced with a known good die, such as known good die 2603, on source substrate 103.

FIG. 26B is an expanded view of the cross-section of precision module frame 106 illustrating an exemplary way to load and unload KRC 2601 using a robot arm 2606 that attaches on the periphery of KRC 2601. It is noted that TCs 111 could be loaded and unloaded in the same way.

Furthermore, FIG. 26B illustrates voice coil posts 2607 (posts to voice coils 109) as well as pin lifts 2608.

A further discussion regarding FIGS. 26A-26B is provided below.

A Known-bad-die Replacement Chuck (KRC) 2601 is used to replace known bad dies (KBDs) 2605 with known good dies (KGDs) 2603. One or more buffer substrates 2604 are used as the source of KGDs 2603. KRC 2601 could replace KBDs 2605 (with KGDs 2603) on one or more of the source/intermediate/product substrates 103/108/105. The design of KRC 2601 could be similar to TC 111 in its ability to chuck fields 401, sense and correct overlay, maintain thermal stability, etc.

In one embodiment, KRC 2601 replaces KBDs 2605 on source substrate 103. KBDs 2605 are selectively released from source substrate 103, for instance, using localized UV exposure of the UV release adhesive, and replaced by a KGD 2603 using KRC 2601. In one embodiment, TC 111 picks up groups of two or more dies from source substrate 103 that has had one or more or all of its KBDs 2605 replaced with KGDs 2603, and proceeds with assembly onto product substrate 105.

In one embodiment, KRC 2601 assembles KGDs 2603 on product substrate 105. KBDs 2605 are either removed directly from TCs 111 after pickup from source substrate 103, or alternatively TC 111 avoids picking up KBDs 2605 from source substrate 103. The space on product substrate 105 that would have been occupied by KBDs 2605 is filled by KGDs 2603 picked from buffer substrates 2602 and assembled onto product substrate 105 using KRC 2601.

In one embodiment, KRC 2601 assembles KGDs 2603 on an intermediate substrate (not shown in FIGS. 26A-26B). KBDs 2605 are either removed directly from TCs 111 after pickup from source substrate 103, or alternatively TC 111 avoids picking up KBDs 2605 from source substrate 103. The space on the intermediate substrate that would have been occupied by KBDs 2605 is filled by KGDs 2603 picked from buffer substrates 2602 and assembled onto the intermediate substrate using KRC 2601.

In one embodiment, the dies (e.g., dies 2603) on buffer substrate 2602 are height mapped, such that KRC 2601 could pick up KGDs 2603 of the correct height to place onto the source/intermediate/product substrates 103/801/105. Height mapping could be performed using a variety of methods, such as air gages, confocal laser sensors, etc.

In one embodiment, KRC 2601 is attached to the n-MASC tool using a z-actuation assembly that is independent of the z-actuation assembly for TCs 111. In another embodiment, KRC 2601 is mounted onto the same z-actuation assembly as TC 111 (with the TCs 111 unloaded from the z-actuation assembly temporarily).

The pick-and-place assembly tool could be designed to operate in various regimes of throughput, overlay and yield.

Exemplary throughput options are as follows—
1. On the high end of the throughput spectrum: (a) Full-substrate assembly (all fields 401 are assembled in parallel), (b) Half-checkerboard assembly (half the fields 401 on source substrate 103 are assembled in parallel in which fields 401 are arranged in the form of a checkerboard pattern that contains half the fields 401 on source substrate 103 and/or product substrate 105. In the case of any 3×3 array of dies that are contiguous on source substrate 103 and/or product substrate 105, a half-checkerboard consists of the five fields that do not share an edge or alternatively the four fields that also do not share an edge and are closest to the center of the 3×3 array), (c) Quarter-checkerboard assembly (a quarter of all fields 401 on source substrate 103 are assembled in parallel in which fields 401 are arranged in the form of a checkerboard pattern that contains a quarter of all fields 401 on source substrate 103 and/or product substrate 105).
2. On the low end of the throughput spectrum: (a) 9 field assembly, (b) 4 field assembly, (c) Field-by-field assembly, (d) 6 field assembly, (e) 8 field assembly, (f) 12 field assembly, (g) 14 field assembly, (h) 16 field assembly, (i) 18 field assembly, (j) 20 field assembly, (k) 24 field assembly, (l) 25 field assembly, (m) 36 field assembly, (n) 50 field assembly, and (o) 64 field assembly.
   Exemplary overlay options are as follows—
1. On the precise end of the overlay spectrum: (a) Sub-10 nm (3σ) overlay control on product substrate, (b) Sub-50 nm (3σ) overlay control on product substrate, (c) Sub-100 nm (3σ) overlay control on product substrate.
2. On the less precise end of the overlay spectrum: (a) Sub-200 nm (3σ) overlay control on product substrate, (b) Sub-500 nm (3σ) overlay control on product substrate, (c) Sub-1 μm (3σ) overlay control on product substrate.
   Exemplary yield options are as follows—
1. Full-replace: Replacement of all known bad dies 2605 using known good dies 2603 using KRC 2601.
2. Half-replace: Replacement of approximately half of known bad dies 2605 with known good dies 2603 using KRC 2601.
3. Quarter-replace: Replacement of approximately a quarter of known bad dies 2605 with known good dies 2603 using KRC 2601.
4. No-replace: Replacement of none of known bad dies 2605.

TABLE 1
Exemplar pick-and-place assembly tool modes.

| | Throughput | Overlay | Yield |
|---|---|---|---|
| Mode 1 | Quarter-checkerboard assembly | Sub-1 μm (3σ) | Full- |
| | | | replace |
| Mode 2 | Quarter-checkerboard assembly | Sub-100 nm (3σ) | Full- |
| | | | replace |
| Mode 3 | Quarter-checkerboard assembly | Sub-50 nm (3σ) | Full- |
| | | | replace |
| Mode 4 | One-eighth-checkerboard (one- | Sub-50 nm (3σ) | Full- |
| | eighth of the fields on the source | | replace |
| | substrate are assembled in parallel | | |
| | in which the fields are arranged in | | |
| | the form of a checkboard pattern | | |
| | that contains one-eighth of the | | |
| | fields on the source substrate | | |
| | and/or the product substrate) | | |
| | assembly | | |
| Mode 5 | 9 field assembly | Sub-50 nm (3σ) | Full- |
| | | | replace |
| Mode 6 | 4 field assembly | Sub-50 nm (3σ) | Full- |
| | | | replace |
| Mode 7 | Field-by-field assembly | Sub-50 nm (3σ) | Full- |
| | | | replace |

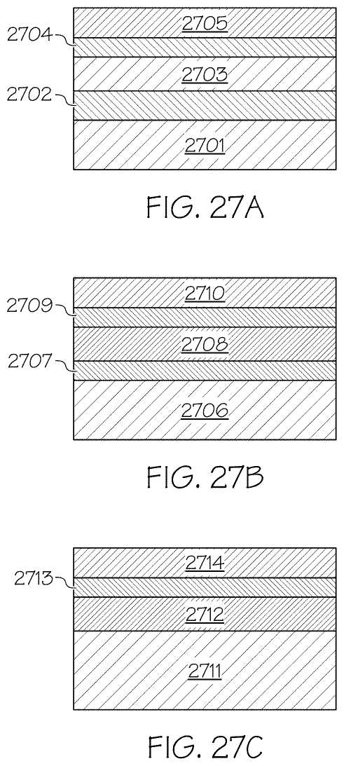

Referring now to FIGS. 27A-27C, FIGS. 27A-27C illustrate exemplary source substrate types in accordance with an embodiment of the present invention.

Referring to FIG. 27A, FIG. 27A illustrates the “source substrate type 1” which consists of a layer of bulk silicon 2701, a layer of buried oxide 2702 (corresponding to the sacrificial layer for assembly) residing on bulk silicon 2701, a layer of silicon (Si) 2703 residing on the layer of buried oxide 2702, a layer of buried oxide 2704 (for device function) residing on the layer of silicon 2703, and a silicon layer 2705 for devices residing on the layer of buried oxide 2704.

FIG. 27B illustrates the “source substrate type 2” which consists of a layer of bulk silicon 2706, a layer of heavily doped p-type material (p++) to create a buried sacrificial layer 2707, a layer of very lightly doped n-type material (n−) 2708 residing on layer 2707, a layer 2709 of heavily doped p-type material (p++) for device function residing on layer 2708, and a silicon layer 2710 for devices residing on the layer 2709.

FIG. 27C illustrates the “source substrate type 3” which consists of a layer of bulk silicon 2711 that is heavily doped (p++), a layer of very lightly doped n-type material (n−) 2712 residing on layer 2711, a layer 2713 of heavily doped p-type material (p++) for device function residing on layer 2712, and a silicon layer 2714 for devices residing on layer 2713.

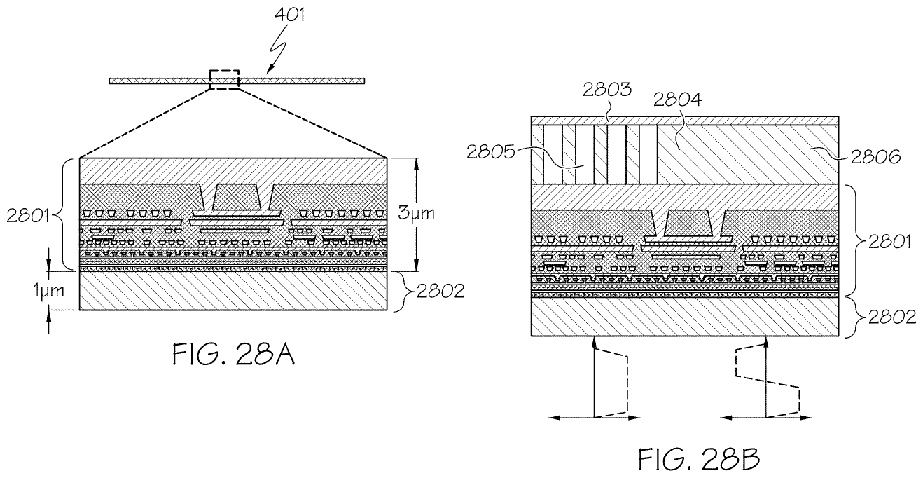

FIGS. 28A-28B illustrate an exemplary field 401 with an exemplary multi-layer encapsulation in accordance with an embodiment of the present invention.

As shown in FIG. 28A, FIG. 28A illustrates an expanded version of the cross-section of field 401 which includes a device stack 2801 residing on crystalline silicon 2802. In one embodiment, width of field 401 is approximately 30 mm. In one embodiment, the width of device stack 2801 is approximately 3 μm. In one embodiment, the width of crystalline silicon 2802 is approximately 1 μm

FIG. 28B illustrates field 401 with a multi-layer encapsulation which includes a thin chemical protectant layer 2083 (e.g., chemical vapor deposition of carbon) as well as a structural stability layer 2804 (e.g., chemical vapor deposition of silicon dioxide).

Furthermore, as shown in FIG. 28B, the encapsulation layer in region 1 2805 only need to match compliance with the thin underlying silicon layer and can thus have a low effective stiffness. It is noted that the patterning for region 1 2805 can be performed in the same manner (e.g., lithography) as used to create access holes to the buried sacrificial layers.

Additionally, as shown in FIG. 28B, a stiffer encapsulation layer (region 2 2806) may be required to compensate for the greater bending tendency.

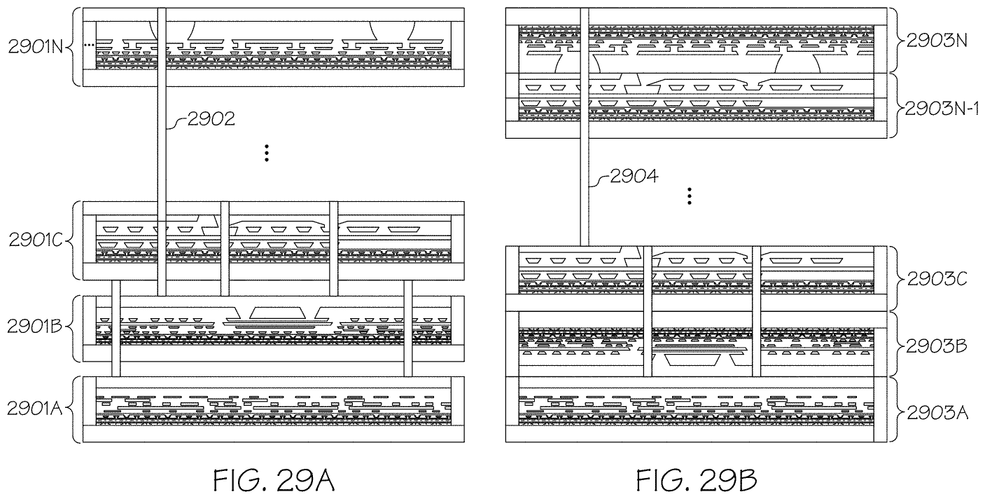

FIGS. 29A-29B illustrate an exemplary face-to-back (F2B) and face-to-face (F2F) device stacks in accordance with an embodiment of the present invention.

As shown in FIG. 29A, a generic F2B stack includes device layers 2901A-2901N (2901A identified as “Device Layer 1,” 2901B identified as “Device Layer 2,” 2901C identified as “Device Layer 3” and 2901N identified as “Device Layer N,” as shown in FIG. 29A), where such device layers are connected via vertical electrical connections 2902 (through silicon via (TSV)) in a face-to-back manner. Device layers 2901A-2901N may collectively or individually be referred to as device layers 2901 or device layer 2901, respectively.

As shown in FIG. 29B, a generic F2F stack includes device layers 2903A-2903N (2903A identified as “Device Layer 1,” 2903B identified as “Device Layer 2,” 2903C identified as “Device Layer 3,” 2903N—1 identified as “Device Layer N—1,” and 2903N identified as “Device Layer N,” as shown in FIG. 29B), where such device layers are connected via vertical electrical connections 2904 (through silicon via (TSV)) in a face-to-face manner. Device layers 2903A-2903N may collectively or individually be referred to as device layers 2903 or device layer 2903, respectively.

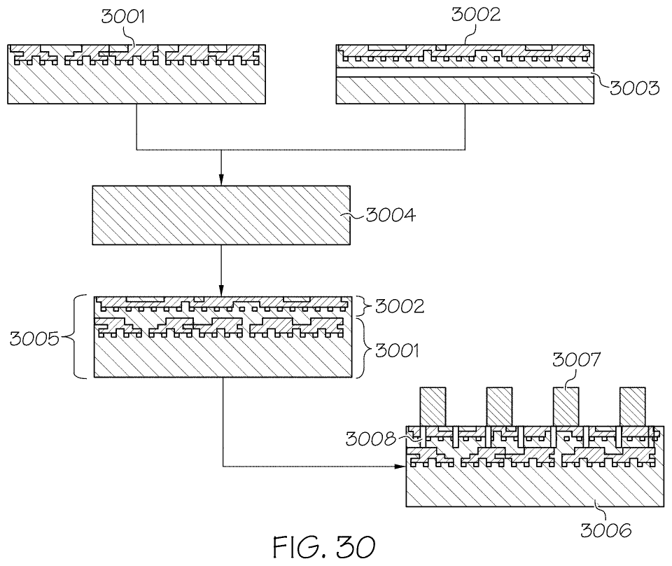

FIG. 30 illustrates an exemplary assembly of a static random access memory (SRAM) on a logic field in accordance with an embodiment of the present invention.

As shown in FIG. 30, logic field 3001 and SRAM field 3002 with a sacrificial layer 3003 are assembled via F2B using an n-MASC equipment 3004 forming an assembled product 3005 that consists of SRAM 3002 residing on logic field 3001.

Afterwards, TSV formation and package connections are performed forming device 3006 that includes connections 3007 to the package and TSVs 3008.

Referring now to FIG. 31, FIG. 31 illustrates an exemplary assembly of multiple stacked static random access memory (SRAM) on a logic field in accordance with an embodiment of the present invention.

As shown in FIG. 31, device 3006 now includes multiple SRAM 3101 stacked on logic field 3001. A further discussion regarding stacking SRAM is provided below.

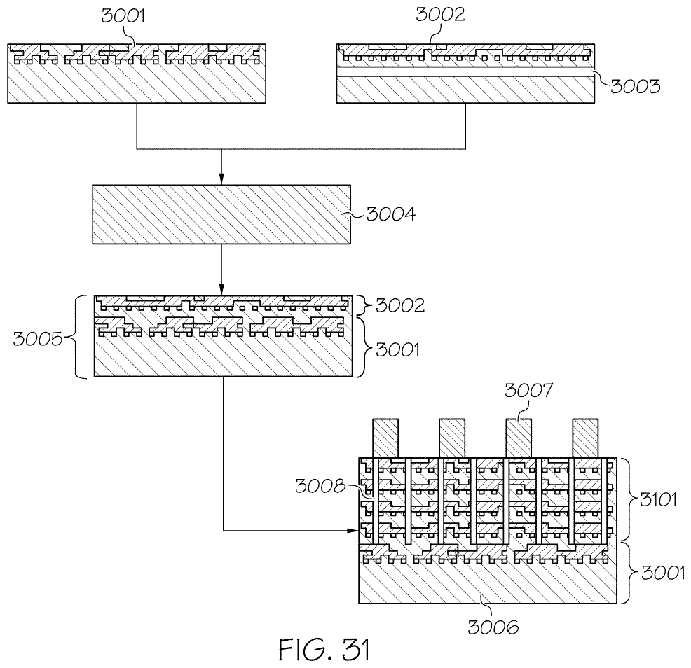

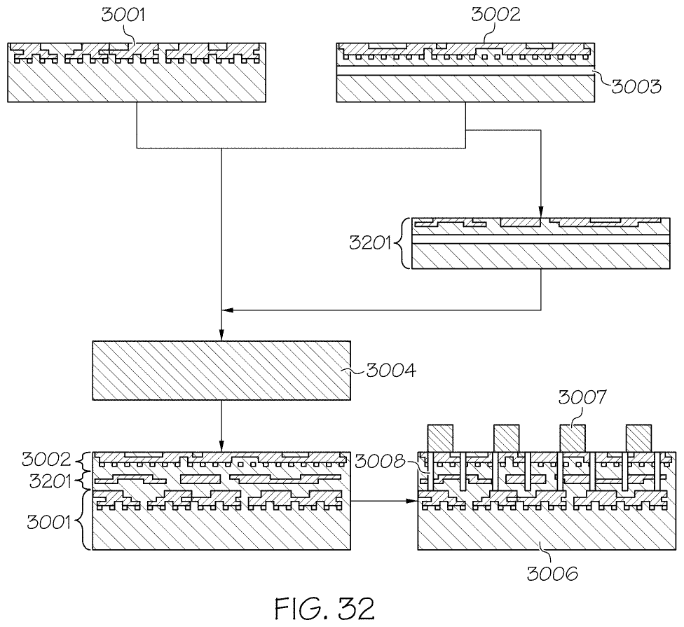

Referring now to FIG. 32, FIG. 32 illustrates an exemplary assembly of static random access memory (SRAM) on a logic field with an error-correcting interposer in the middle in accordance with an embodiment of the present invention.

As shown in FIG. 32, an interposer field 3201 is used to determine the good bitcells of logic field 3001 and SRAM field 3002 and fabricate custom error-correcting procedures, such as electrical connectivity, heat dissipation, etc. The interposer field 3201 may then reside between the logic field 3001 and SRAM field 3002 after being assembled (F2B) by n-MASC equipment 3004.

The following discussion is based on FIGS. 27A-27C, 28A-28B, 29A-29B and 30-32.

In one embodiment, source substrate 103 contains a buried sacrificial layer 2702, 2707. In one embodiment, sacrificial layer 2702, 2707 is silicon oxide. In one embodiment, the starting substrate for the sacrificial-layer-containing source substrate consists of a low-doped n-type layer (shortened to N−) 2708, 2712 and a high-doped p-type layer (shortened to P++) 2709, 2713. The high-doped p-type layer 2709, 2713 can be first converted to porous silicon (using silicon anodization, for instance), and subsequently oxidized to create a buried sacrificial layer of silicon oxide. The low-doped n-type layer 2708, 2712 remains unaffected during anodization and limits the anodization to only the high-doped layer. In one embodiment, the layers with low-n-type and high-p-type doping could be created using epitaxial growth. In one embodiment, the bulk silicon itself is highly p doped (e.g., layer 2711).

In one embodiment, source substrate 103 consists of background devices on a carrier substrate. The carrier substrate could be bulk silicon, glass substrate, tape frame, etc., depending on the process used for creation of the background devices and the desired device orientation. In one embodiment, the carrier substrate is transparent. In one embodiment, the carrier substrates are attached to the background fields using a UV-release adhesive. In one embodiment, the carrier substrates are attached to the background fields using a sublimating polymer. In one embodiment, back-grinding is performed using the MACE process.

In one embodiment, the background fields are attached to the carrier substrate using a light-to-heat conversion (LTHC) adhesive layer. In one embodiment, after pickup (by one or more TCs 111), fields 401 could be cleaned on TC 111 itself (for instance) using oxygen plasma, etchant vapor (for instance, vapor HF), and/or etchant liquid.

In one embodiment, distortion of thin fields 401 due to residual stresses is controlled using a structural encapsulation layer of a thickness and material such that the rigidity of the encapsulation layer is close to or equal to the rigidity of the underlying field 401. In one embodiment, the encapsulation layer consists of a chemical encapsulation layer 2803 (to protect against chemical damage) along with a structural encapsulation layer 2804 (to prevent distortion due to residual stresses). In one embodiment, structural encapsulation layer 2804 is patterned to counter varying distortion tendencies across the area of field 401. In one embodiment, residual distortion in the encapsulated fields is sensed using wavefront-based methods, laser-based raster scan methods, capacitive methods, etc.

In one embodiment, for face-to-back assembly, the encapsulation layer on picked fields 401 is not removed prior to bonding. In one embodiment, a residual-stress-compensating structural encapsulation layer is included in the device itself. In one embodiment, metal interconnects run through structural encapsulation layer 2804.

In one embodiment, the encapsulation layer includes compliant elements to prevent field distortion due to embedded particles. In one embodiment, the compliant elements are in the form of the compliant pins of a compliant pin chuck. In one embodiment, the encapsulation layer includes a compliant polymer layer to prevent field distortion due to embedded particles.

In one embodiment, the encapsulation layer contains a scratch resistant layer, made for instance using, a diamond-like layer or hard coatings, such as aluminum oxide.

In one embodiment, the encapsulation layer consists of the following three layers—carbon, silicon oxide, carbon (with the silicon oxide sandwiched between the two carbon layers).

In one embodiment, the pattering of the encapsulation layer is conducted using nanoimprint lithography, photolithography, e-beam lithography, etc. In one embodiment, the patterning of the encapsulation layer is conducted using the same lithography process that is used for creation of field access holes.

In one embodiment, fields 401 contain nanowire-forests at the bonding interface to facilitate electrical connection. In one embodiment, the nanowire-forests incorporate copper nanowires.

In one embodiment, through silicon vias (TSVs) 2902, 2904, formed post-bonding to electrically connect bonded fields 401, have a multi-shell structure that could include a metal connection (for instance, in the center of the TSV), along with a low-k dielectric in the form of an anulus around the metal connection.

In one embodiment, assembled fields 401 on product substrate 105 consist of memory layers (e.g., 3002) and logic layers (e.g., 3001). In one embodiment, fields 401 on product substrate 105 contain interposers (e.g., interposer field 3201) that could be used to create electrical connectivity, heat dissipation, etc.

In one embodiment, for face-to-back assembly, field-contacting pins on the transfer chucks have a cross-sectional area that is larger than the size of the optional access holes in fields 401.

In one embodiment, starting substrates with sacrificial layers are attached to a carrier substrate with an adhesive, and the sacrificial layer stripped off, such that source substrate 103 consists of fields 401 on a carrier substrate.

Fields 401 on an incoming background source substrate could be first transferred to an intermediate substrate 801, and subsequently transferred using TC 111 to a second intermediate substrate 801, which is then finally flipped onto and hybrid bonded to product substrate 105. The incoming background singulated fields could be on a transparent carrier (for instance, glass, quartz, sapphire, and/or polymer). The first intermediate substrate 801 could be a transparent substrate (for instance, glass, quartz, sapphire, and/or polymer). The second intermediate substrate 801 could be a transparent substrate (for instance, glass, quartz, sapphire, and/or polymer) or a non-transparent substrate (in visible spectrum), for instance, silicon. The adhesive that attaches fields 401 to the carrier substrate in source substrate 103 could be UV-releasable, thermally releasable, etc. The adhesive used to attach fields 401 to the first intermediate substrate 801 in source substrate 103 could be UV-releasable, thermally releasable, etc. In one embodiment, fields 401 from source substrate 103 are released after flipping and attachment onto the first intermediate substrate 801 by UV exposure of the UV-release adhesive on the source substrate side.

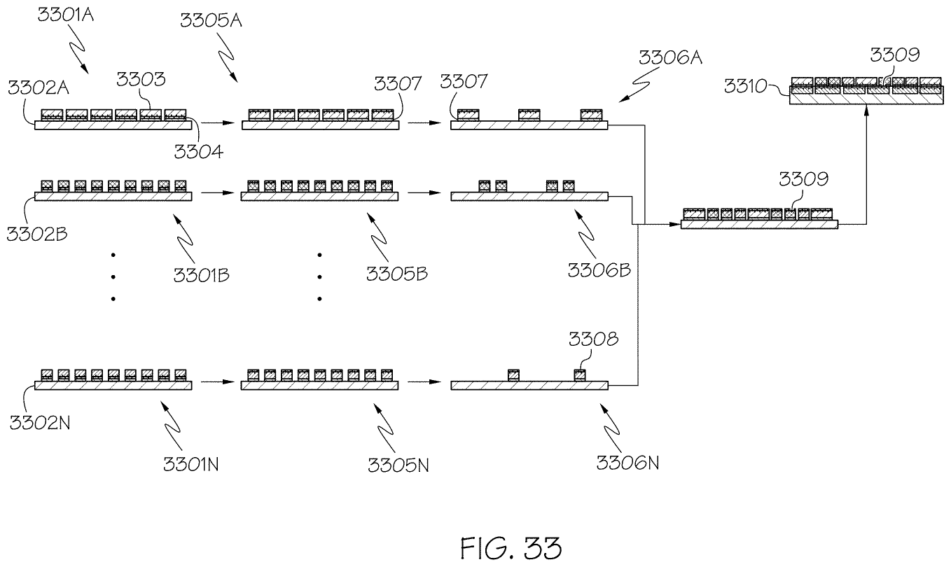

FIG. 33 illustrates an exemplary sequence for pick-and-place assembly in accordance with an embodiment of the present invention.

Referring to FIG. 33, a series of pre-flip source wafers 3301A-3301N (it is noted that the term “wafer” and “substrate” are used interchangeably herein) (3301A identified as “pre-flip source wafer 1,” 3301B identified as “pre-flip source wafer 2,” and 3301N identified as “pre-flip source wafer N”) reside on carrier substrates 3302A-3302N, respectively. Pre-flip source wafers 3301A-3301N may collectively or individually be referred to as pre-flip source wafers 3301 or pre-flip source wafer 3301, respectively. Carrier substrates 3302A-3302N may collectively or individually be referred to as carrier substrates 3302 or carrier substrate 3302, respectively.

Furthermore, as shown in FIG. 33, the metal structures (dies) 3303 face towards the adhesive 3304.

In one embodiment, wafers 3301 are flipped with temporary bonding and the pre-flip carriers 3302 are detached, such as by using a transfer chuck 111, thereby forming source wafers 3305A-3305N (3305A identified as “source wafer 1,” 3305B identified as “source wafer 2,” and 3305N identified as “source wafer N”) as shown in FIG. 33. Source wafers 3305A-3305N may collectively or individually be referred to as source wafers 3305 or source wafer 3305, respectively.

Next, there may be a collective die transfer to an intermediate wafer 3306A-3306N (3306A identified as “intermediate wafer 1,” 3306B identified as “intermediate wafer 2,” and 3306N identified as “intermediate wafer N”) while potentially adjusting the pitch in the X and/or Y directions using TC 111 as shown in FIG. 33. Intermediate wafers 3306A-3306N may collectively or individually be referred to as intermediate wafers 3306 or intermediate wafer 3306, respectively. In one embodiment, the thickness of adhesive 3304 can be adjusted per die 3303 to compensate for height mismatches as shown via element 3307. Furthermore, FIG. 33 illustrates an exemplary adhesive island 3308, in which a single die 3303 is adhesively joined to intermediate wafer 3306.

Furthermore, as shown in FIG. 33, there may next be a collective transfer to the transfer wafer 3309 from all the intermediate wafers 3306 using TC 111. In one embodiment, overlay may be corrected during this step. Furthermore, in one embodiment, during such a step, die grid pitch could be adjusted in the X and/or Y directions.

Additionally, as shown in FIG. 33, transfer wafer 3309 is bonded (e.g., hybrid bonded) to product wafer 3310.

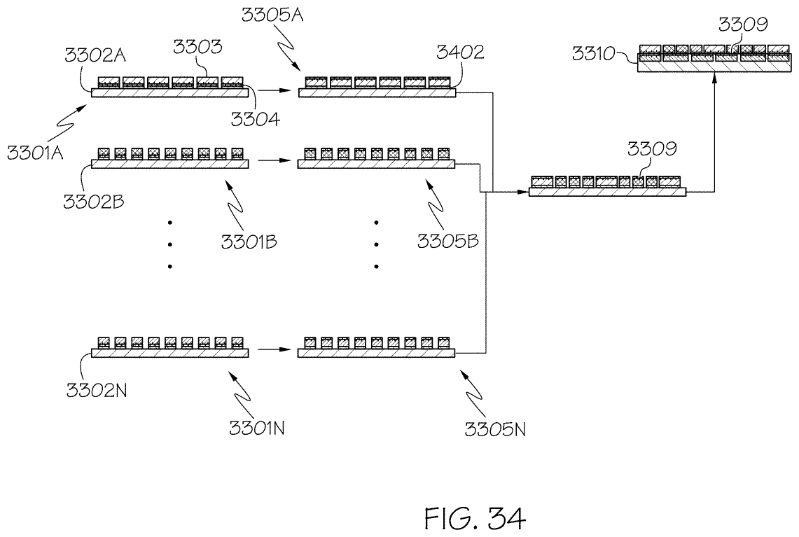

Referring now to FIG. 34, FIG. 34 illustrates an alternative exemplary sequence for pick-and-place assembly in accordance with an embodiment of the present invention.

As shown in FIG. 34, in comparison to FIG. 33, there is a collective transfer to transfer wafer 3309 using TC 111 without the use of intermediate wafers 3306. Furthermore, as shown in FIG. 34, an exemplary adhesive island 3401 may exist on source wafer 3305, in which a single die 3303 is adhesively joined to source wafer 3305. Additionally, it is noted that the thickness of adhesive 3304 can be adjusted per field 401 to compensate for field mismatches as shown via element 3402.

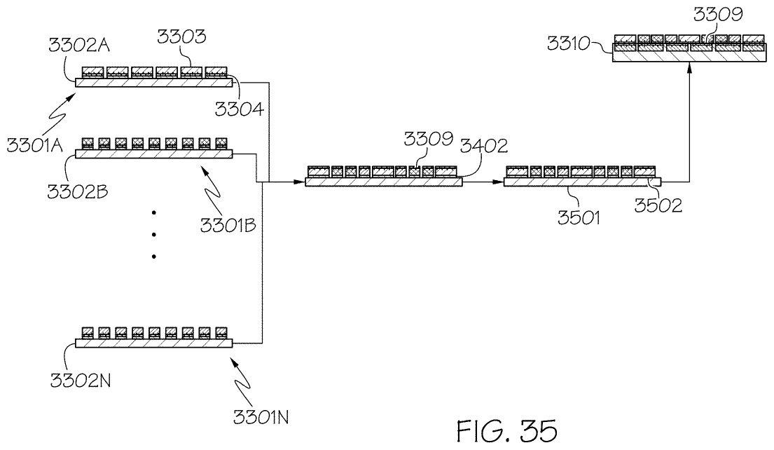

Referring now to FIG. 35, FIG. 35 illustrates a further alternative exemplary sequence for pick-and-place assembly in accordance with an embodiment of the present invention.

As shown in FIG. 35 in comparison to FIGS. 33 and 34, the pre-flip source wafers 3301 are not flipped and there is no utilization of intermediate wafers 3306. Instead, there is a collective transfer to the transfer wafer 3309 from all the pre-flip source wafers 3301 using TC 111. In one embodiment, overlay may be corrected during this step. Furthermore, in one embodiment, during such a step, die grid pitch could be adjusted in the X and/or Y directions

After the transfer, transfer wafer 3309 is flipped with temporary bonding and carrier substrates 3302 are detached, such as by using a transfer chuck 111, thereby forming structure 3501.

Furthermore, as shown in FIG. 35, an exemplary adhesive island 3502 may exist on transfer wafer 3309, in which a single die 3303 is adhesively joined to transfer wafer 3309.

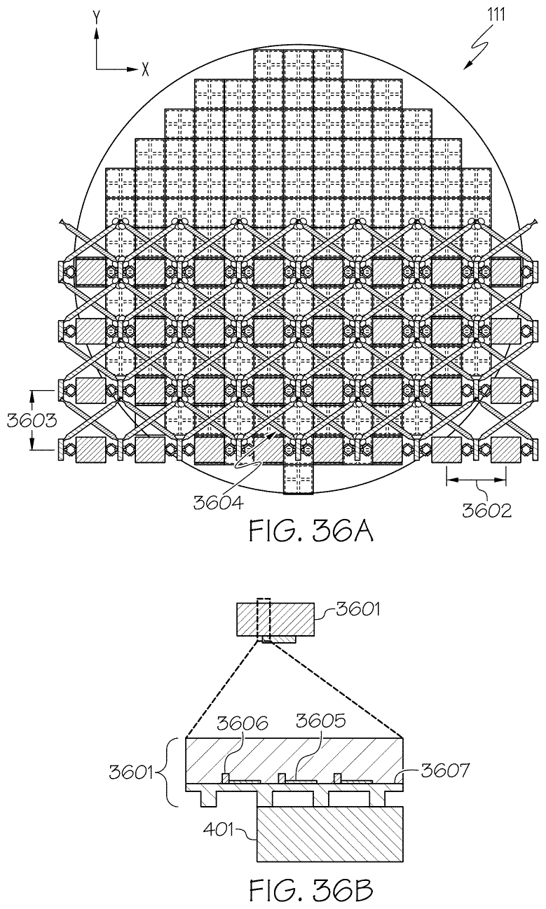

Referring now to FIGS. 36A-36B, FIGS. 36A-36B illustrate an exemplary transfer chuck 111 in accordance with an embodiment of the present invention.

As shown in FIG. 36A, transfer chuck 111 may consist of multiple mini-TCs 3601.

Furthermore, FIG. 36A illustrates the locations 3602 for an exemplary force application to reconfigure the TC X grid. Additionally, FIG. 36A illustrates the locations 3603 for an exemplary force application to reconfigure the TC Y grid.

Furthermore, FIG. 36A illustrates the Y reconfiguring array 3604. The X reconfiguring array (not shown in FIG. 36A) could be fabricated separately and overlaid on top of Y reconfiguring array 3604.

In one embodiment, TC 111 includes a full reconfigurable array of mini-TCs 3601 that is 300 mm×300 mm. An expanded version of the cross-section of mini-TC 3601 is shown in FIG. 36B.

As shown in FIG. 36B, mini-TC 3601 includes an electrode 3605 and a custom thin film transistor (TFT) backplane 3606. Additionally, as shown in FIG. 36B, a layer of dielectric 3607 between mini-TC 3601 and field 401 may be utilized, in which dielectric 3607 may optionally be leaky to create a Johnsen-Rahbek (J-R)-type chucking effect.

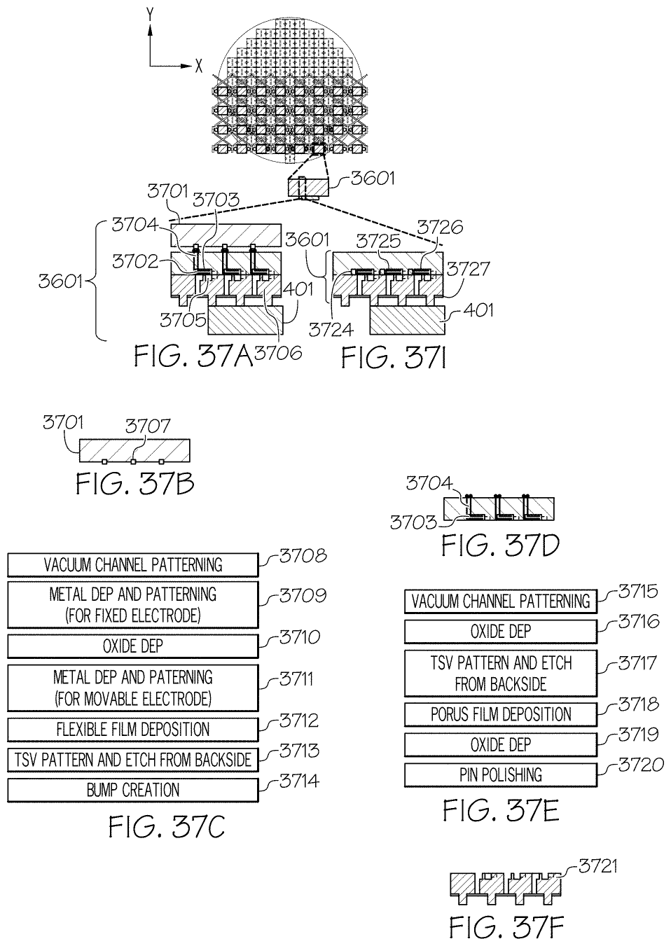

FIGS. 37A-37O illustrate an alternative exemplary transfer chuck in accordance with an embodiment of the present invention.

Referring to FIG. 37A, FIG. 37A illustrates an expanded version of the cross-section of mini-TC 3601. As shown in FIG. 37A, “option 1” is to reuse the thin film transistor (TFT) backplane 3701 from a mini-LCD display. For example, mini-TC 3601 would include the reused TFT backplane 3701. Furthermore, the space 3702 between electrodes 3703 is maintained at atmospheric pressure using an in-plane grid of channels 3704.

Additionally, FIG. 37A illustrates a vacuum inlet 3705 in which the vacuum is source using an in-plane grid of vacuum channels (not shown in FIG. 37A). Furthermore, FIG. 37A illustrates a vacuum outlet 3706 to field 401.

As shown in FIG. 37B, the structure of FIG. 37B includes a reused TFT backplane 3701 along with transistor leads 3707.

Referring now to FIG. 37C, FIG. 37C includes the process steps for reusing TFT backplane 3701 from a mini-LCD display which include vacuum channel patterning 3708, metal deposition and patterning 3709 (for fixed electrode), oxide deposition 3710, metal deposition and patterning 3711 (for moveable electrode), flexible film deposition 3712, TSV pattern and etch from backside 3713 and bump creation 3714 resulting in the structure shown in FIG. 37D.

As shown in FIG. 37D, the structure includes electrodes 3703 and channels 3704.

Referring now to FIG. 37E, the process steps for reusing TFT backplane 3701 from a mini-LCD display further include vacuum channel patterning 3715, oxide deposition 3716, TSV pattern and etch from the backside 3717, porous film deposition 3718, oxide deposition 3719 and pin polishing 3720 resulting in structure 3721 shown in FIG. 37F.

Referring now to FIG. 37G, the structures shown in FIGS. 37B, 37D and 37F are bonded together by performing the process steps of bump bonding, fusion bonding and oxide release using vHF (vapor phase hydrofluoric acid) (see element 3722) resulting in structure 3723 shown in FIG. 37H.

Referring now to FIG. 37I, FIG. 37I illustrates an expanded version of the cross-section of mini-TC 3601. As shown in FIG. 37I, “option 2” is to use a custom backplane 3724 at the TFT foundry. Mini-TC 3601 further includes moving electrodes 3725 and fixed electrodes 3726. Furthermore, as shown in FIG. 37I, there is an optional porous filter membrane 3727 to filter particles in the airstream from reaching the TC-field interface.

Referring now to FIG. 37J, FIG. 37J includes the process steps for using a custom backplane 3724 at the TFT foundry, which includes TFT patterning 3728, vacuum channel patterning 3729, metal deposition and patterning 3730 (for fixed electrode 3727), oxide deposition 3731, metal deposition and patterning 3732 (for movable electrode 3725) and flexible film deposition 3733 resulting in the structure shown in FIG. 37K.

As shown in FIG. 37K, the structure includes the custom backplane 3724 as well as moveable and fixed electrodes 3725, 3726.

Referring now to FIG. 37L, FIG. 37L includes the additional process steps for using a custom backplane 3724 at the TFT foundry, which includes vacuum channel patterning 3734, oxide deposition 3735, TSV pattern and etch from the backside 3736, porous film deposition 3737, oxide deposition 3738 and pin polishing 3739 resulting in structure 3740 shown in FIG. 37M.

Referring now to FIG. 37N, the structures shown in FIGS. 37K and 37M are bonded together by performing the process steps of bump bonding, fusion bonding and oxide release using vHF (vapor phase hydrofluoric acid) (see element 3741) resulting in structure 3742 shown in FIG. 37O.

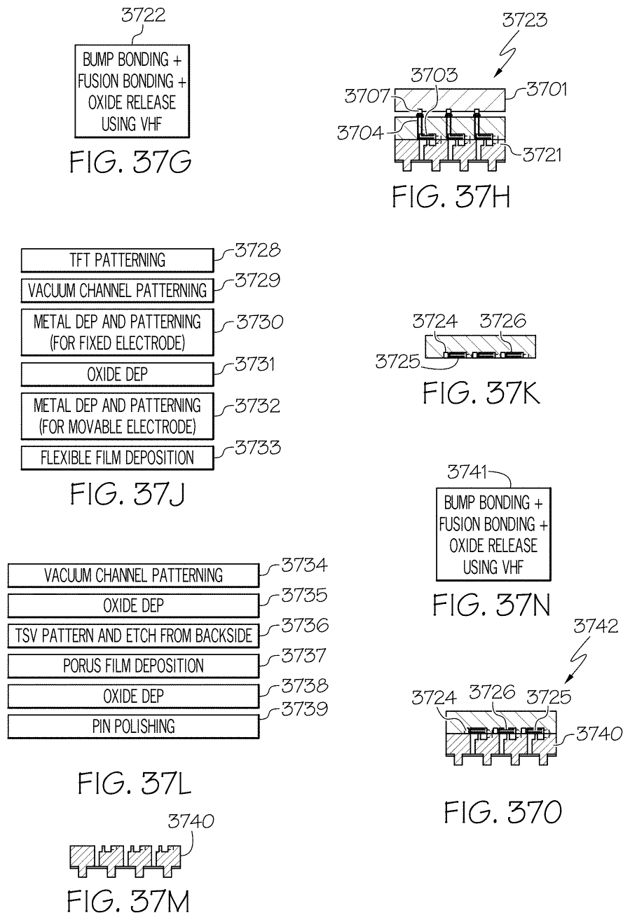

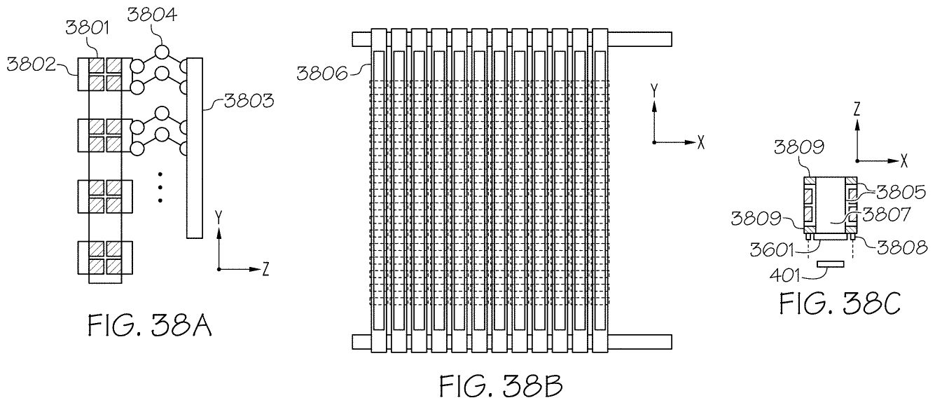

Referring now to FIGS. 38A-38C, FIGS. 38A-38C illustrate an exemplary reconfiguring transfer chuck (TC) 111 in accordance with an embodiment of the present invention.

FIG. 38A illustrates the X-Z plane cross-sectional view of TC 111 in which optical electromagnetic actuators 3801 are depicted. Furthermore, TC 111 includes sliders 3802 as well as an optional flexure system 3803 that constrains sliders 3802 in θₓ and θ_{y}. Furthermore, TC 111 includes optional frictionless pivots 3804 between flexure system 3803 and optical electromagnetic actuators 3801.

In one embodiment, δ_{y}, δ_{z}, θ_{z}, θₓ are controllable. In one embodiment, TC 111 includes an optional flexure bearing with an optional frictionless rotary bearing.

FIG. 38B illustrates a top view of TC 111.

FIG. 38C illustrates an expanded view of a portion of the top view of TC 111.

As shown in FIGS. 38B and 38C, there is an optional pressure and/or vacuum 3805 to guide and/or fix slider 3802 onto the linear rail 3806. Furthermore, FIG. 38C illustrates an optionally transparent core port 3807 of slider 3802 to allow metrology. Additionally, FIG. 38C illustrates an optional encoder sensor 3808. FIG. 38C further illustrates optional permanent magnets/voice coils 3809.

A further discussion regarding FIGS. 33-35, 36A-3B, 37A-37O and 38A-38C is provided below.

Please find below a listing of the definitions of terms discussed herein.
SiP—System-in-package where separately manufactured die are integrated into a higher-level assembly.
Field—Individual die, or a small cluster of die collocated in the SiP.
SPP—SiP Pitch on Product-wafer (SPP) including SPPₓ and SPP_{y}.
Transfer chuck—A system that is used to transfer fields and/or dies from one substrate to another, while maintaining thermo-mechanical stability of said fields and/or dies.

In one embodiment, singulated fields on source substrate 103 (obtained after backgrinding) are first transferred to an intermediate substrate 801 using a transfer chuck 111, and subsequently transferred to a transfer substrate 3309. In one embodiment, during transfer from source substrate 103 to intermediate substrate(s) 801, fields 401 are displaced in the X and/or Y axes, such that field pitch matches the grid pitch on product substrate 105 along the X and/or Y axes. In one embodiment, during transfer from the intermediate substrate(s) 801 to transfer substrate(s) 3309, fields 401 are displaced in the X and/or Y axes, such that field pitch matches the grid pitch on product substrate 105 along the X and/or Y axes. In one embodiment, during the transfer from intermediate substrate(s) 801 to transfer substrate(s) 3309, predicted overlay error of fields on product substrate 105 is compensated fully or partially by actuators (thermal, mechanical) on TC 111 and/or a transfer substrate chuck. In one embodiment, fields 401 are transferred from transfer substrate 3309 to product substrate 105 in a whole-substrate manner. In one embodiment, transfer substrate 3309 is detached from the temporarily bonded fields using heating (with a thermal release adhesive) or UV exposure (with a transparent or perforated substrate and UV curable adhesive). In one embodiment, transfer substrate 3309 is detached from fields 401 after temporary bonding onto product substrate 105 (with the bonding performed using room temperature hybrid bonding, for instance). After detachment of transfer substrate 3309, residual adhesive and/or UV-curable planarizing material are cleaned off using an oxidizing wet clean, O₂ plasma ashing, etc. The clean could be performed after temporary bonding between oxide surfaces and prior to permanent bonding, where permanent bonding is performed using thermal curing of hybrid bonded surfaces.

One or more of the source/intermediate/transfer substrates 103/801/3309 could be composed of a glass substrate, a glass substate in roll form, aluminum, aluminum in roll form, aluminum in foil form, polymers, polymers in roll form, stainless steel, and/or stainless steel in roll form. In one embodiment, one or more of the source/intermediate/transfer substrates 103/801/3309 have through-substrate perforations that act as light guides.

In one embodiment, intermediate and transfer substrates 801, 3309 are composed of a transparent substrate (e.g., silicon oxide, fused silica, glass, etc.), a non-transparent substrate (e.g., silicon), and/or a partially transparent substrate (e.g., silicon with perforations). Silicon substrates with perforations could be fabricated using deep etch processes, such as deep reactive-ion etching (DRIE), metal assisted chemical etching (MACE), etc.

In FIG. 33, during field transfer from the one or more source wafers 3305 to the one or more intermediate wafers 3306, the pitch of the fields 401 could be changed using ATC 1101 along only a single axis (one of X or Y). Fields 401 could subsequently be transferred to a second set of intermediate wafers (not shown in FIG. 33), where the field pitch is changed along the orthogonal direction to the prior step.

In one embodiment, TC 111 is reconfigurable, and contains optical elements (to focus light from and onto light source 2402 and light sensors on MM 108) attached to every single or a group of actuation units. In one embodiment, the TC contains one or more light sources attached to every single or a group of actuation units 1007. In one embodiment, optical elements and light sources 2402 associated with a single actuation unit 1007 can themselves be displaced in the X, Y, and/or Z axes relative to actuation unit 1007. The actuation could be performed using magnetic, electromagnetic (for instance, voice coils), thermal, piezoelectric, and/or pneumatic actuation modalities.

In one embodiment, an assembly of turn mirrors and a single or multiple light source(s) 2402 are used to project light for metrology onto TC 111. In one embodiment, the turn mirrors are composed of mirrors with reflectivity that starts at a predetermined amount and gradually increases and/or decreases as one proceeds along the light path from light source(s) 2402. In one embodiment, the turn mirrors are composed of a transparent substrate coated with patterned films of a reflective material, with varying pattern pitch to match the reflectivity requirement at a particular location.

In one embodiment, a laser-based method could be used to ablate and/or evaporate plugging material 1201. The laser could be used to heat the portion of TC 111 immediately surrounding plugging material 1201. In one embodiment, the laser operates in the ultraviolet frequency. In one embodiment, the laser has a wavelength of 257 nm. In one embodiment, the laser is a continuous wave laser, pulsed laser or an ultrashort pulse laser. In one embodiment, a wet clean is used to etch plugging material 1201. The cleaning material could be dispensed only near the locations where plugging material 1201 is located.

In one embodiment, plugging material 1201 is a transient material. In one embodiment, plugging material 1201 is end-capped polyoxymethylene.

In one embodiment, two or more TCs 111 are used, where one of the TCs 111 is used for pick-and-place assembly, and rest of the TCs 111 are cleaned and returned to their default state for vacuum switching. In one embodiment, TCs 111 are attached to an indexing mechanism. In one embodiment, TCs 111 are attached to a mechanism that flips their orientation as well as indexes them for cleaning.

In one embodiment, a thermally stable optical plate is used as the reference to measure registration errors of fields on the source substrate(s) 103, intermediate substrate(s) 801, transfer substrate(s) 3309 and/or product substrates 105. In one embodiment, the optical plate is custom made for measuring registration for different dies. In another embodiment, the optical plate is composed of a dense array of alignment marks that remains the same for new kinds of dies.

In one embodiment, the adhesive(s) 3304 used to attach fields 401 to the source substrate(s) 103, intermediate substrate(s) 801, transfer substrate(s) 3309, and/or product substrate(s) 105, could be composed of two or more layers. The layers could be UV-curable adhesive, nano-particle inks, thermally-curable adhesive, pressure-sensitive adhesive, and/or transient materials. In one embodiment, the nano-particle inks absorb radiation in a narrow wavelength range. In one embodiment, the nano-particle inks absorb radiation in a narrow wavelength range, at which one or more of the substrates and chucks in the n-MASC system show minimal or zero absorption. In one embodiment, one of the components of adhesive 3304 is a transient material that turns into a gas upon heating. The heating could be produced using radiative (for instance, using a laser), convective or conductive heat transfer. In one embodiment, the transient material contains polyoxymethylene. In one embodiment, adhesive 3304 is dispensed onto the source substrate(s) 103, intermediate substrate(s) 801, transfer substrate(s) 3309, and/or product substrate(s) 105 in adhesive islands (e.g., adhesive islands 3308, 3401, 3502). The adhesive islands (e.g., adhesive islands 3308, 3401, 3502) could vary in size from less than 10 μm across to 300 mm across.

In one embodiment, the source substrate(s) 103, intermediate substrate(s) 801, transfer substrate(s) 3309, and/or product substrate(s) 105 contain a fixed and dense grid of alignment marks. The grid of alignment marks could be used as a fixed and stable reference to measure the misalignment of fields 401 picked on TC 111, for instance.

In one embodiment, adhesive 3304 dispensed onto source substrate(s) 103, intermediate substrate(s) 801, transfer substrate(s) 3309, and/or product substrate(s) 105 is performed outside of the n-MASC tool.

In one embodiment, a stock of one or more buffer source substrates of each type (needed by product substrate 105) are maintained in a stocker unit in the n-MASC tool. If the current stock of buffer substrates are all partially populated, and do not contain all the dies needed at the correct locations to produce the required field layout on product substrate 105, a new buffer substrate can be added for the specific field type, until a preset limiting number of buffer substrates is reached, at which point, die-by-die or low-number-of-die pick-and-place is implemented using one or the already existing buffer substrates in the inventory.

In one embodiment, one or more of the encapsulation layers used during n-MASC contain conductive elements. In one embodiment, the conductive elements are connected to a potential source to create electrostatic attraction between a transfer chuck 111 and field 401 on which the encapsulation layer lies. In one embodiment, one or more of the encapsulation layers are on the opposite face of field 401 as the device structures.

In one embodiment, one or more mini-TCs 3601 are used to pick-and-place one or more dies 901. Mini-TCs 3601 rest on rails 3806 and could be actuated using electromagnetic attraction and/or repulsion between rails 3806 and sliders 3802. An exemplary system is shown in FIGS. 38A-38C. Rails 3806 and/or sliders 3802 (onto which mini-TCs 3601 are attached) could have embedded electromagnets to create controlled motion in the X, Y, Z, θₓ, θ_{y}, and/or θ_{z} axes. In one embodiment, an orthogonal system of rails is utilized: One or more Y rails rest and are guided on an orthogonal pair of X rails. One or more sliders 3802 could be guided on the Y rails. Sliders 3802 could be constrained in the X, Y, Z, Oₓ, θ_{y}, and/or θ_{z} axes by providing air-based cushions and/or magnetic cushions. Sliders 3802 and/or rails 3806 could contain holes and/or perforations to source vacuum and/or pressure to create the cushioning effect. In one embodiment, sliders 3802 and/or rails 3806 could contain a porous ceramic (e.g., porous SiC) to source pressure and/or vacuum. In one embodiment, flexible coverings are utilized to cover the pressure and/or vacuum emanating out of the holes and/or perforations in sliders 3802 and/or rails 3806. In one embodiment, a horizontal air curtain is created across the face of mini-TCs 3601 and/or the substrate from which transfer is being implemented. In one embodiment, the air curtain is used to reduce particle contamination. In one embodiment, only pressure is dispensed in two opposing direction (for instance towards the top and bottom of sliders 3802 simultaneously), to create counteracting cushions, for slider constraining. In one embodiment, a combination of magnetic cushioning and air-based cushioning is utilized to constrain sliders 3802. The Y rails could be constrained onto the X rails using a similar mechanism as employed for sliders 3802. In one embodiment, vacuum preloading is utilized to constrain one or more of sliders 3802 and/or the Y rails. In one embodiment, flexures placed either in a plane parallel to TC 111, and/or in a plane orthogonal to TC 111 and could be utilized to constrain mini-TCs 3601 in the X, Y, Z, Oₓ, θ_{y}, and/or θ_{z} axes. In one embodiment, an out-of-plane pantograph mechanism is utilized to provide said containing. In one embodiment, a scissor mechanism is utilized per Y rail for said constraining. In one embodiment, cables (for electrical and pneumatic connectivity of sliders 3802 and/or mini-TCs 3601) are supported by slider constraining flexures.

In one embodiment, the TC reconfiguration could be feedback controlled. Global precision could be achieved using an encoder plate. In one embodiment, the encoder plate is used only at the start of the assembly of a particular source wafer set. The encoder plate could be loaded onto the source wafer chuck 102, TC 111 reconfigured, and then could be removed. Each mini-TC 3601 could reference the globally precise encoder plate. Real-time feedback could be implemented by incorporating the encoder plate in source wafer chuck 102 or potentially MM 108.

In one embodiment, mini-TCs 3601 rest on pucks that slide on an electromagnetic plate that is able to control the motion of said pucks in the X, Y, Z, θₓ, θ_{y}, and/or θ_{z} axes. Mini-TCs 3601 could face upwards and dies 901 and/or fields 401 to be picked-and-placed face downwards (such that the process of pickup separates the dies and/or fields from the substrate in a downward direction).

In one embodiment, mini-TCs 3601 rest on a 300 mm or larger chucking surface. In one embodiment, mini-TCs 3601 are attached to the chucking surface using vacuum, electromagnetic forces, and/or chemical adhesion. During pick-and-place assembly, mini-TCs 3601 could be picked up from the chucking surface using a mini-TC picker mechanism and expanded or contracted in the X and/or Y axes to match the SPPₓ or SPP_{y} of product substrate 105 prior to placement on the intermediate wafer(s) 801, transfer wafer(s) 3309 or product wafer(s) 105. The expansion could be performed in either one step or two steps. In the one step expansion case, the picker mechanism could contain flexure mechanisms, for instance, based on scissor mechanisms that can be expanded independently in both the X and Y directions. In the two-step expansion case, the picker mechanism first expands the pitch of all mini-TCs 3601 in one direction. Subsequently, the mechanism is rotated by 90 degrees, or a separate mechanism is utilized which is arranged in an orthogonal direction to the first mechanism, to expand the pitch of mini-TCs 3601 in the orthogonal direction. The picker mechanism could expand the pitch of mini-TCs 3601 using rail-type systems described above, or scissor-type mechanisms, or combinations of the above.

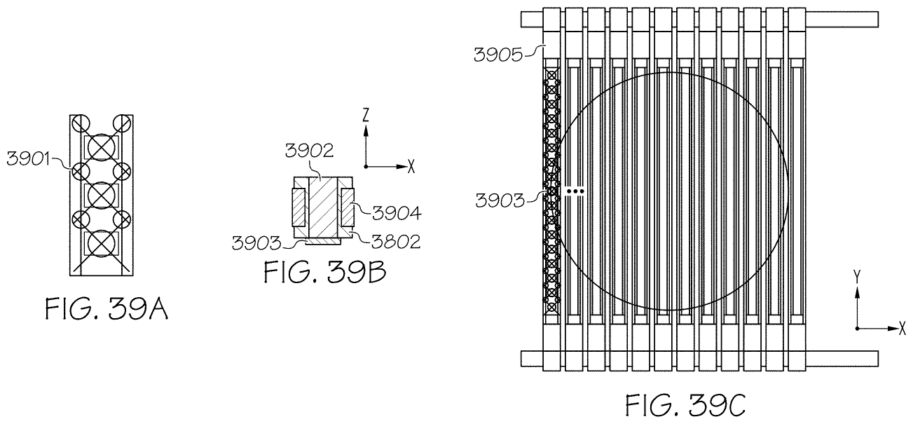

Referring now to FIGS. 39A-39C, FIGS. 39A-39C illustrate an exemplary transfer chuck 111 showing an array of adaptive chucking modules (ACMs) that are movable with respect to one another using a variable pitch mechanism (VPM) in accordance with an embodiment of the present invention.

As shown in FIG. 39A, TC 111 includes a flexure-based pivot 3901. A cross-sectional view of TC 111 is provided in FIG. 39B, which depicts an optional transparent window 3902, an ACM 3903 attached to slider 3802 as well as an optional air bearing 3904.

Furthermore, a top view of TC 111 is provided in FIG. 39C, which depicts voice coil actuators 3905 and a fixed central ACM 3903.

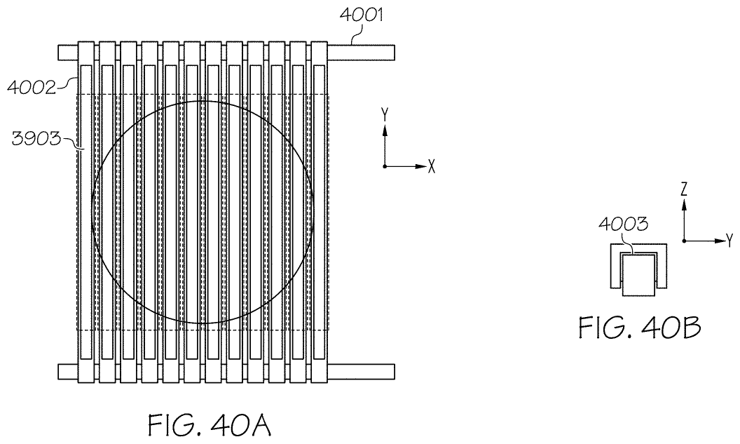

FIGS. 40A-40B illustrate an alternative exemplary transfer chuck 111 showing an array of elongated adaptive chucking modules 3903 (ACMs) that are movable with respect to one another using a variable pitch mechanism (VPM) in accordance with an embodiment of the present invention.

Referring to FIG. 40A, FIG. 40A illustrates the top view of transfer chuck 111 which depicts the X rail 4001 and Y rail 4002 as well as an elongated ACM 3903 fixed to Y rail 4002. In one embodiment, the width of Y rail 4002 is approximately 15 mm.

An expanded view of a cross-section of Y rail 4002 is depicted in FIG. 40B. As shown in FIG. 40B, the ends of Y rails 4002 are supported on X rails 4001 using air bearings 4003. In one embodiment, the ends of Y rails 4002 are fabricated from porous silicon carbide. In another embodiment, the ends of Y rails 4002 are fabricated from metal with holes to create air bearings 4003. In one embodiment, actuation along the X direction could be provided using an electromagnetic actuator system.

FIG. 41 illustrates a further alternative exemplary transfer chuck 111 showing an array of elongated adaptive chucking modules 3903 (ACMs) that are movable with respect to one another using a variable pitch mechanism (VPM) in accordance with an embodiment of the present invention.

As shown in FIG. 41, transfer chuck 111 includes an X direction flexure 4101.

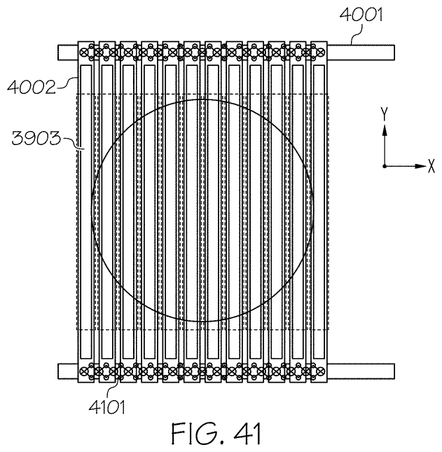

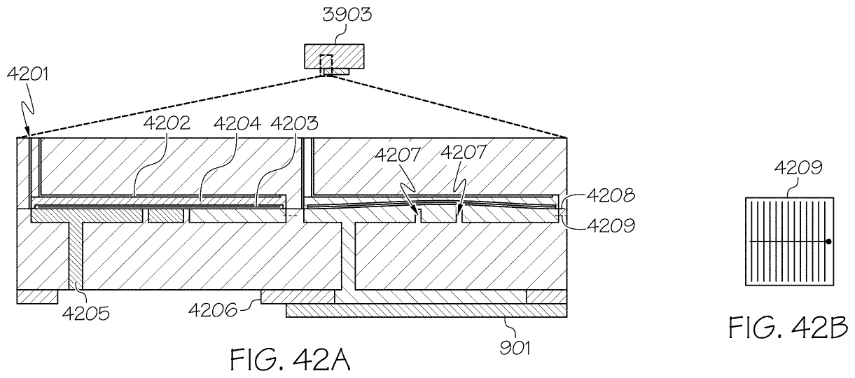

FIGS. 42A-42B illustrate an exemplary adaptive chucking module (ACM) 3903 in accordance with an embedment of the present invention.

Referring to FIG. 42A, FIG. 42A illustrates a cross-section of the bottom portion of ACM 3903. In particular, FIG. 42A illustrates exemplary connections 4201 to the switch, a fixed electrode 4202, a moving electrode 4203 as well as a 5 μm gap 4204 between such electrodes 4202, 4203. Furthermore, FIG. 42A illustrates a location 4205 at atmosphere and an ACM pin 4206 on die 901. Additionally, FIG. 42A illustrates a pin pitch of about 100 μm. Furthermore, FIG. 42A illustrates a dual seal 4207, a polysilicon membrane 4208 and a vacuum inlet 4209.

A top view of ACM 3903 showing the routing of vacuum inlet 4209 is depicted in FIG. 42B.

A further discussion regarding FIGS. 39A-39C, 40A-40B, 41 and 42A-42B is provided below.

In one embodiment, transfer chuck 111 could be composed of an array of adaptive chucking modules (ACMs) 3903, each of which can be used to pick and place one or more fields 401 from one or more of the source/intermediate/product substrates 103/801/105. In one embodiment, ACMs 3903 are composed of an array of valve units. In one embodiment, an electrostatic actuation mechanism is utilized to actuate the valves. In one embodiment, a seal 4207 consisting of one or more chambers is utilized to isolate vacuum inlet 4209 from the outlet. In one embodiment, the air volume contained inside seal 4207 consisting of one or more chambers is used to cushion the impact of membrane 4208 as it closes the valve.

ACMs 3903 could be moved with respect to each other using a variable pitch mechanism. The variable pitch mechanism could be composed of flexure bearings, air bearings, and electromagnetic bearings as well as pneumatic, electromagnetic actuators. In one embodiment, ACMs 3903 are mounted on planar motors that provide actuation along 6 axes. Some exemplary designs are shown in FIGS. 39A-39C, 40A-40B and 41.

In one embodiment, ACMs 3903 include a mechanism for theta actuation of ACMs 3903 with respect to the variable pitch mechanism (VPM). In one embodiment, the theta actuation mechanism is flexure-based. In one embodiment, the theta-actuating flexures are actuated using thermal actuators that induce a thermal expansion in the flexure arms. In one embodiment, the spacing between picked fields in TC 111 (or equivalently the pitch of ACMs 3903) is increased to accommodate a greater length of flexures, for the thermal actuation to produce a larger theta displacement.

In one embodiment, one or more imagers 1401 are used to detect errors in field pick-and-place by ACMs 3903. In one embodiment, imagers 1401 are visible light imagers or IR imagers. In one embodiment, imagers 1401 observe a single ACM 3903 per imager or multiple ACMs 3903 per imager. The image stream from imagers 1401 could be used by automated fault detection algorithms to flag errors in the pick-and-place process. The fault detection algorithms could be based on artificial neural networks (ANNs), convolutional neural networks (CNNs), etc.

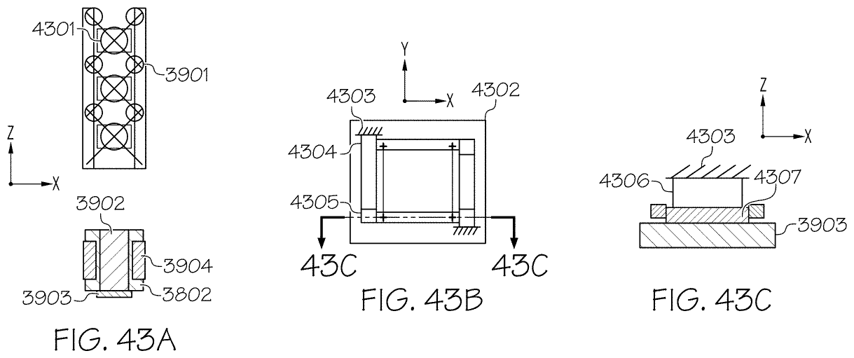

FIGS. 43A-43C illustrate an additional exemplary transfer chuck 111 showing an array of adaptive chucking modules 3903 (ACMs) that are movable with respect to one another using a variable pitch mechanism (VPM) in accordance with an embodiment of the present invention.

Referring to FIG. 43A, transfer chuck 111 includes a scissor-based mechanism 4301 for Y expansion/contraction of ACMs 3903.

FIG. 43B is an expanded view of the cross-section of scissor-based mechanism 4301. As shown in FIG. 43B, FIG. 43B illustrates the fixed points 4303 on VPM 4302. Furthermore, VPM 4302 includes an actuation arm 4304 coated with light-to-heat conversion material (e.g., light-absorbing nanoparticle links, light-to-heat conversion release coating (LTHC) layers, etc.). Additionally, VPM 4302 includes a heat insulating connector 4305

FIG. 43C illustrates another expanded view of the cross-section of scissor-based mechanism 4301. As shown in FIG. 43C, FIG. 43C illustrates an optional cantilever flexures 4306 that permit motion in the X, Y and θ axes but permit minimal motion in the Z-plane.

FIG. 43C further illustrates an optional heat insulating frame 4307 connected to ACM 3903 using optional heat insulating adhesives.

Referring to FIGS. 43A-43C, in one embodiment, ACMs 3903 are connected to VPM 4302 using a mechanism that can actuate one or more of the X, Y, and θ axes. In one embodiment, the range of the X or Y displacement is at least 100 nm, while the range of 0 is at least 10 microradians. In one embodiment, the actuation mechanism is connected to fixed points 4303 of VPM 4302 as well as ACM 3903. In one embodiment, the connection of the above mechanism with fixed points 4303 of VPM 4302 as well as ACM 3903 is created using heat insulating materials. In one embodiment, the heat insulating connectors also have low overall thermal expansion (less than 25 nm or even less than 10 nm). This low overall thermal expansion could be achieved by using connector material with low coefficient of thermal expansion (CTE) or using thin (micrometer-scale) connector or a combination of low CTE and thin connector. These connector materials could include heat insulating adhesives, polymer connector with low overall thermal expansion, fused silica, or stainless steel. In one embodiment, actuation arms 4304 are coated with light-to-heat conversion materials (e.g., light-absorbing nanoparticle inks, LTHC layers). In one embodiment, the heating of actuation arms 4304 is performed by irradiating actuation arms 4304 using one or more of the following: scanning light sources, digital micromirror array, an array of LEDs, and an array of micro-LEDs. In one embodiment, a heat sink is used to maintain a stable reference temperature for actuation arms 4304. The heat sink could consist of fluid flow (air, for instance) across actuation arms 4304, and/or embedded fluidic microchannels. In one embodiment, variable pitch mechanism 4302 possesses a motion range of at least one millimeter.

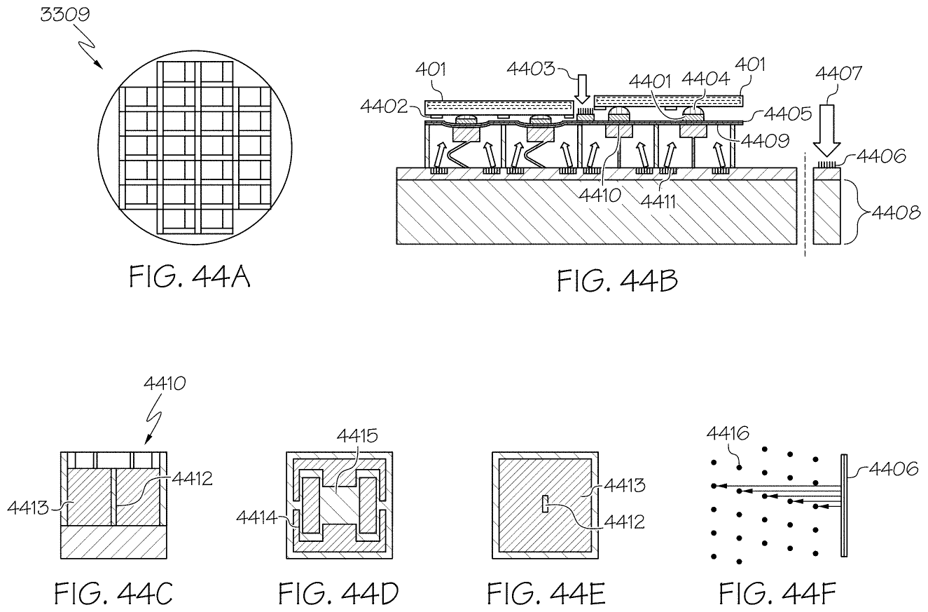

Referring now to FIGS. 44A-44F, FIGS. 44A-44F illustrate an exemplary transfer substrate 3309 in accordance with an embodiment of the present invention.

As shown in FIG. 44A, FIG. 44A illustrates a transfer substrate 3309. FIG. 44B illustrates an expanded view of a cross-section of transfer substrate 3309. FIG. 44B illustrates optional mesas 4401 (areas on transfer substrate 3309 where substrate 3309 has not been etched away) for capillary pinning of the adhesive. In one embodiment, mesas 4401 are made using a polymer and patterned, such as via photolithography. In one embodiment, mesas 4401 are transparent to UV light (e.g., for example, a photoresist material). In one embodiment, the material of mesas 4401 is index matched to the waveguide layer. The refractive index of the mesa material could be tuned to allow only a portion of light in the waveguide to leak through mesa 4401 and into the adhesive (for UV curing, for instance).

Furthermore, as shown in FIG. 44B, a small amount of source substrate adhesive 4402 could optionally be left on the underside of fields 401 after pickup from source substrate 103.

Furthermore, FIG. 44B illustrates two exemplary adjacent fields 401. In one embodiment, fields 401 have their active side facing upwards (away from transfer substrate 3309). Height variations of fields 401 could be compensated for by z-compliant flexures, adhesive drop volume adjustment and cantilevering of fields 401 near the edges as shown by element 4403.

Additionally, FIG. 44B illustrates a UV-curable adhesive 4404.

Furthermore, FIG. 44B illustrates optional waveguide layers 4405. Waveguide layers 4405 may be at the top of the z-flexure structures and/or below them. In one embodiment, waveguide layers 4405 are made using SiO₂, silicon nitride and/or a UV-transmissive polymer (e.g., acrylic).

Furthermore, FIG. 44B depicts in-coupling gratings 4406 for coupling in light (e.g., UV 4407) into lateral waveguide structures 4405. These could be located near the periphery of transfer substrate 3309 and/or the kerf region between fields 401. These could optionally be patterned using Jet and Flash Imprint Lithography (J-FIL) on imprint resist.

Additionally, FIG. 44B illustrates a bulk portion 4408 of transfer substrate 3309 (e.g., approximately 775 μm thick bulk silicon). This could optionally be perforated using an etching technique, such as Catalyst Influenced Chemical Etching (CICE) or Deep Reactive-Ion Etching (DRIE), to allow UV exposure of adhesive 4404 from the underside of transfer substrate 3309.

Furthermore, FIG. 44B illustrates an optional encapsulation layer 4409 for the z-compliant structures 4410. In one embodiment, encapsulation layer 4409 separates the internal structures of z-compliant structures 4410 from the picked fields 401. In one embodiment, the z compliance of encapsulation layer 4409 is changed by changing its thickness. In one embodiment, encapsulation layer 4409 is made using silicon, polysilicon, silicon oxide, a polymer and/or a metal (e.g., chrome).

Additionally, FIG. 44B illustrates optional out-coupling gratings 4411.

Referring now to FIG. 44C, FIG. 44C is an expanded view of z-compliant structures 4410. As shown in FIG. 44C, z-compliant structures 4410 includes a flexure stem 4412. In one embodiment, flexure stem 4412 is designed to buckle whenever the force on the field above exceeds a particular value. Furthermore, FIG. 44C illustrates recesses 4413 in z-compliant structures 4410, which could be filled using optional sacrificial materials (e.g., silicon oxide, porous carbon, polyvinyl alcohol (PVA), etc.) which could at the end of fabrication be removed using a suitable etchant.

FIG. 44D is an expanded view of the top portion of z-compliant structure 4410. As shown in FIG. 44D, secondary flexures 4414 allow flexing of a central pad 4415 in the z-direction while preventing substantial motion in the XY plane. In one embodiment, mesas 4401 and adhesives 4404 could optionally sit above central pad 4415.

FIG. 44E is an expanded view of the central portion of z-compliant structure 4410. As shown in FIG. 44E, flexure stem layer 4412 could be made in silicon (for instance) and bonded to the rest of the compliant layers using a suitable bonding technique (e.g., covalent bonding).

Furthermore, FIG. 44F is an expanded view of the top view of in-coupling grating 4406 (for UV light, for instance). Additionally, FIG. 44F illustrates the top view of the cross-section near the adhesive drops 4416 showing drop staggering to allow UV radiation coupled into waveguide layers 4405 to reach the maximum amount of drops prior to getting absorbed or scattered.

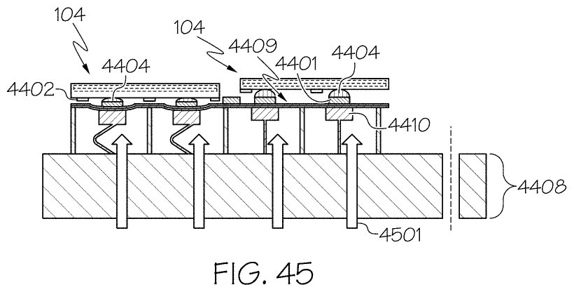

FIG. 45 illustrates an alternative exemplary transfer substrate 3309 in accordance with an embodiment of the present invention.

Referring to FIG. 45, FIG. 45 illustrates optional mesas 4401 for capillary pinning of adhesive 4404. In one embodiment, mesas 4401 are made using a polymer and patterned using photolithography. In one embodiment, mesas 4401 are transparent to IR light 4501. Optionally, mesas 4401 could be embedded with nanoparticles that selectively absorb light (e.g., infrared light) at as specific wavelength. These could be used to locally heat and cure the two-part adhesive 4404.

FIG. 45 further illustrates optional two-part adhesive 4404 (similar to adhesive shown in FIG. 44B except that it is cured via IR radiation). In one embodiment, adhesive 4404 is stored separately and dispensed together just prior to the field attachment step (using inkjetting, for instance). In one embodiment, adhesive 4404 could optionally be embedded with nanoparticles that selectively absorb light (e.g., infrared light 4501) at a specific wavelength. These could be used to locally heat and cure the two-part adhesive 4404.

Referring to FIGS. 44A-44F and 45, transfer substrates 3309 are intermediate substrates 801 onto which fields 401 are assembled temporarily, immediately prior (in the integration sequence) to hybrid bonding onto product substrate 105. Fields 401 are generally transferred from a transfer substrate 3309 to product substrate 105 in a whole-substrate manner.

In one embodiment, transfer substrate 3309 contains embedded structures, that are selectively compliant in the Z-direction while being stiff in the X and Y directions. Exemplary structures are shown in FIGS. 44A-44F and 45. Such structures could be assembled by bonding together multiple 2D-fabricated layers (using techniques, such as laser machining, photolithography, etching, etc.). Recesses 4413 in the embedded structures could be filled with a sacrificial material, such as SiO₂, polyvinyl alcohol (PVA) which is water soluble, porous carbon, etc. The filling layer could be used to support internal structures against collapse and damage as well as support any subsequent layers that could be grown on top of the already fabricated layers. The filling layers could, at the end of entire fabrication process, be etched away using a suitable etchant (for instance, HF for SiO₂, water for PVA, etc.). The filling layers and the internal structures could be coated with an encapsulation layer 4409 composed of SiO₂, spin-on-glass (SOG), metal, polymer, silicon, and/or polysilicon. In one embodiment, encapsulation layer 4409 is capped with a metal layer that helps with the internal reflection of light in the light guiding layer.

In one embodiment, the in-plane distortion of transfer substrates 3309 is controlled using thermal actuation (e.g., peltier coolers, infrared radiation-based localized heating sources), and mechanical actuation techniques. In one embodiment, thermal actuation is utilized to draw out any excess heat generated during adhesive curing using UV radiation, for instance. Optionally, high-heat-conductivity adhesives could be used to facilitate the heat transfer process.

In one embodiment, transfer substrate 3309 is custom made for each new SiP. In one embodiment, encapsulation layer 4409, mesa layer 4401 and in-coupling grating layer 4406 are custom patterned for each SiP.

In one embodiment, to prevent interference of the transfer-substrate-facing surface of TC 111 with pre-existing fields 401 on transfer substrate 3309 (when placing fields 401 that have been picked up by TC 111 onto transfer substrate 3309), a short plasma strip step could be used to reduce the thickness of encapsulation layer 4409 on the pre-existing fields 401. The plasma could be an atmospheric pressure plasma.

In one embodiment, to prevent interference of the transfer/source/intermediate-substrate-facing surface of TC 111 with pre-existing fields 401 on the transfer/source/intermediate substrate 3309/103/801 (when placing fields 401 that have been picked up by TC 111 onto the transfer/source/intermediate substrates 3309/103/801), a repulsive force could be created between pre-existing fields 41 on the transfer/source/intermediate substrate 3309/103/801 and the transfer/source/intermediate-substrate-facing surface of TC 111. The force could be created by forcing air out of ACMs 3903 (that are in TC 111) at the pre-existing field locations, to create a thin cushion of air that separates the pre-existing fields 401 from the substrate-facing surface of TC 111. Alternatively, the force could be created by charging the substrate-facing surface of TC 111 and TC-facing surface of the pre-existing fields 401 with similar polarity charges, to create an electrostatic repulsion between the surfaces. In one embodiment, the compliance of the z flexure structures 4412 (also referred to as “flexure stems”) inside the transfer/source/intermediate substrates 3309/103/801 could be changed to assist in creation of the TC-to-field gap during the placement step.

In one embodiment, one or more of the mesa layers 4401, waveguide layers 4405, encapsulation layers 4409 and z-compliant structures 4410 in transfer substrate 3309 are made using materials that have a high thermal conductivity (for instance metals, silicon, high thermal conductivity composite polymers that contain high thermal conductivity fillers), to allow vertical and lateral transport of heat away from fields 401 and towards the bulk of the transfer/source/intermediate substrate 3309/103/801 and transfer chuck 111.

In one embodiment, the thickness of mesa structures 4401 is increased to increase the local X, Y compliance of the transfer/source/intermediate substrate 3309/103/801. In one embodiment, the volume of the adhesive drops 4416 is increased to increase the pinned height of adhesive 4404, to increase the effective local X, Y compliance of the transfer/source/intermediate substrate 3309/103/801.

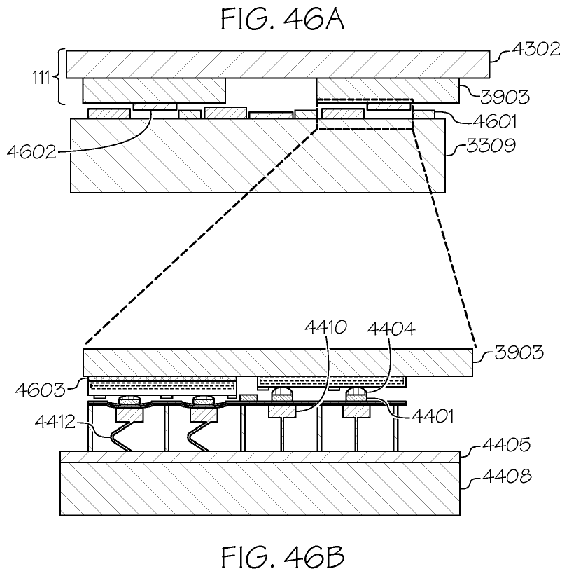

FIGS. 46A-46B illustrate a exemplary interference prevention method (during field assembly onto transfer substrate 3309) in accordance with an embodiment of the present invention.

Referring to FIG. 46A, FIG. 46A illustrates an exemplary field 4601 that is already assembled on transfer substrate 3309. The shown field 401 has a larger thickness (for instance) compared to field 401 being assembled. In the absence of an interference prevention method, this would come in the way of ACM 3903 as it tries to assemble field 401 onto transfer substrate 3309.

Furthermore, FIG. 46A illustrates a field 4602 being currently assembled onto transfer substrate 3309.

FIG. 46B is an expanded view of a portion of transfer substrate 3309. As shown in FIG. 46B, local air pressure and/or electrostatic repulsion 4603 created by ACM 3903 (at the location of an already-assembled field 4601) to prevent interference of the field with the TC/ACM 111/3903 during assembly.

Furthermore, as shown in FIG. 46B, flexure structures 4412 in transfer substrate 3309 facilitate interference mitigation.

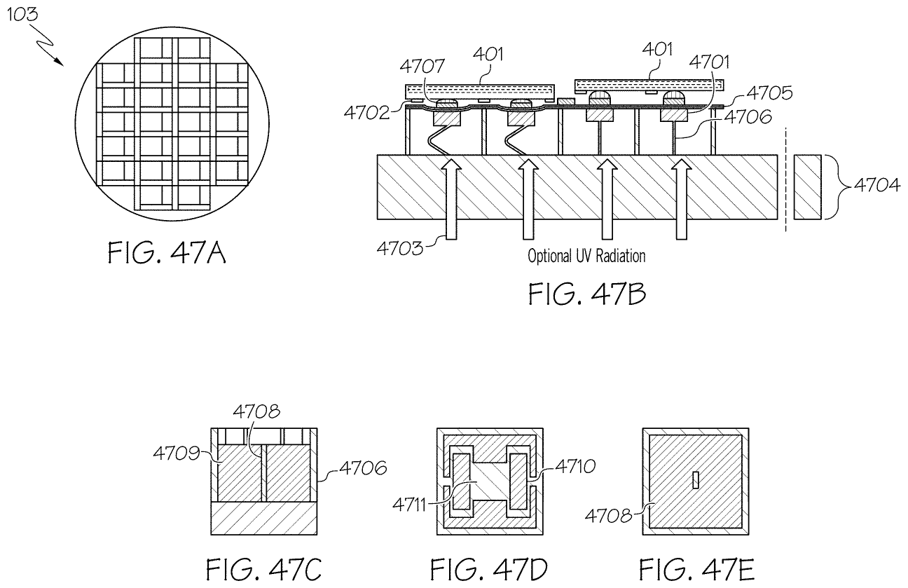

Referring now to FIGS. 47A-47E, FIGS. 47A-47E illustrate an exemplary source substrate 103 in accordance with an embodiment of the present invention.

As shown in FIG. 47A, FIG. 47A illustrates a source substrate 103. FIG. 47B illustrates an expanded view of a cross-section of source substrate 103. FIG. 47B illustrates optional mesas 4701 (areas on source substrate 103 where substrate 103 has not been etched away) for capillary pinning of the adhesive. In one embodiment, mesas 4701 are made using a polymer and patterned, such as via photolithography. In one embodiment, mesas 4701 are transparent to IR light. In one embodiment, mesas 4701 could be embedded with nanoparticles that selectively absorb light (e.g., infrared light) at a specific wavelength. These could be used to locally heat and cure the two-part adhesive.

Furthermore, as shown in FIG. 47B, a small amount of source substrate adhesive 4702 could optionally be left on the underside of fields 401 after pickup from source substrate 103.

Furthermore, FIG. 47B illustrates two exemplary adjacent fields 401. In one embodiment, fields 401 have their active side facing upwards (away from source substrate 103). Height variations of fields 401 could be compensated for by z-compliant flexures, adhesive drop volume adjustment and cantilevering of fields 401 near the edges.

Additionally, FIG. 47B illustrates optional UV radiation 4703 for transient material activation.

Furthermore, FIG. 47B illustrates a bulk portion 4704 of source substrate 103 (e.g., approximately 775 μm thick bulk silicon or a silicon layer with perforations made using a suitable etch technique).

Furthermore, FIG. 47B illustrates an optional encapsulation layer 4705 for the z-compliant structures 4706. In one embodiment, encapsulation layer 4705 separates the internal structures of z-compliant structures 4706 from the picked fields 401. In one embodiment, the z compliance of encapsulation layer 4705 is changed by changing its thickness. In one embodiment, encapsulation layer 4705 is made using silicon, polysilicon, silicon oxide, a polymer and/or a metal (e.g., chrome).

Additionally, FIG. 47B illustrates optional transient material (adhesive) 4707. In one embodiment, transient material 4707 is inkjetted on top of mesa layer 4701. A phase transition could be induced using heat, for example, or UV radiation Optionally, transient material 4707 could be embedded with nanoparticles that selectively absorb light (e.g., infrared light) at a specific wavelength. These could be used to locally heat the material.

Referring now to FIG. 47C, FIG. 47C is an expanded view of z-compliant structures 4706. As shown in FIG. 47C, z-compliant structures 4706 includes a flexure stem 4708. In one embodiment, flexure stem 4708 is designed to buckle whenever the force on the field above exceeds a particular value. Furthermore, FIG. 47C illustrates recesses 4709 in z-compliant structures 4706, which could be filled using optional sacrificial materials (e.g., silicon oxide, porous carbon, polyvinyl alcohol (PVA), etc.) which could at the end of fabrication be removed using a suitable etchant.

FIG. 47D is an expanded view of the top portion of z-compliant structure 4706. As shown in FIG. 47D, secondary flexures 4710 allow flexing of a central pad 4711 in the z-direction while preventing substantial motion in the XY plane. In one embodiment, mesas 4701 and adhesives 4707 could optionally sit above central pad 4711.

FIG. 47E is an expanded view of the central portion of z-compliant structure 4706. As shown in FIG. 47E, flexure stem layer 4708 could be made in silicon (for instance) and bonded to the rest of the compliant layers using a suitable bonding technique (e.g., covalent bonding).

In one embodiment, source substrate 103 could be composed of fields 401 attached to a transparent carrier substrate (for instance, glass, fused silica, sapphire), or a tape frame carrier membrane, using an adhesive (e.g., adhesive 4707). The adhesive could be a continuous film, a continuous film the thickness of which varies to compensate for the thickness variation in fields 401, or separated into islands the X/Y extents and thicknesses of which vary to account for the different X/Y extents and thicknesses of fields 401. In one embodiment, such a source substrate 103 is fabricated by starting with fields 401 on a substrate with a sacrificial layer, for instance, silicon-on-oxide (SOI), silicon-on-sapphire (SOS), flipping and adhering to a suitable carrier substrate in a whole-substrate manner, and detaching the bulk of the starting substrate using a suitable etchant. In one embodiment, the starting substrate consists of fields 401 fabricated on a silicon layer that lies on top of a sacrificial silicon-germanium (SiGe) layer. Such SiGe layers could be grown using epitaxial deposition techniques. The etching of the sacrificial silicon-germanium layer could be performed using wet etching, plasma etching, atomic layer etching and hybrid etching methods. In one embodiment, an etchant composed of vapor HF, vapor H₂O₂, and vapor acetic acid is used.

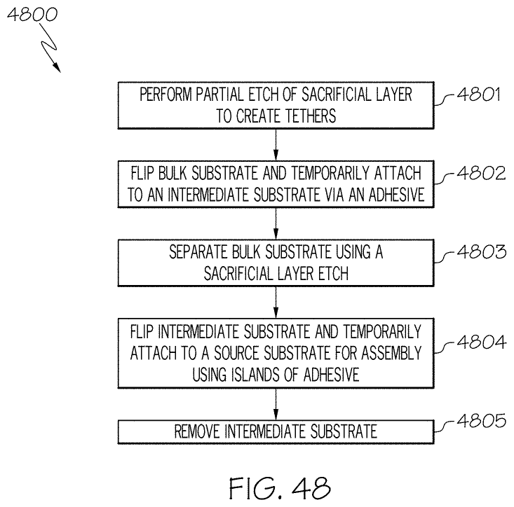

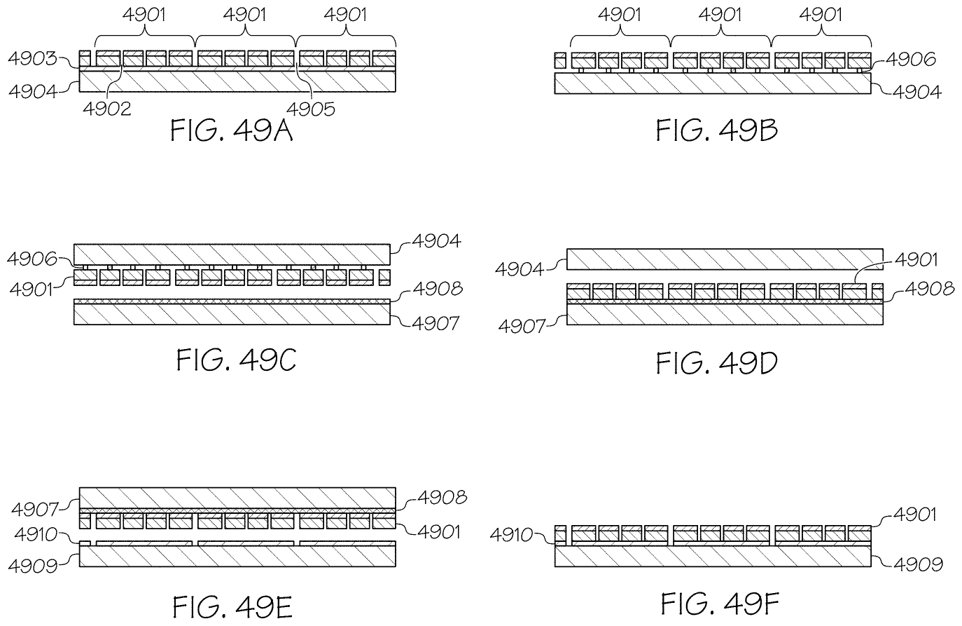

FIG. 48 is a flowchart of a method 4800 for creating source substrates for assembly from substrates with sacrificial layers in accordance with an embodiment of the present invention. FIGS. 49A-49F depict the cross-sectional views for creating source substrates for assembly from substrates with sacrificial layers using the steps described in FIG. 48 in accordance with an embodiment of the present invention.

Referring to FIG. 48, in conjunction with FIGS. 49A-49F, in step 4801, a partial etch of sacrificial layer 4903 is performed to create tethers as shown in FIGS. 49A-49B. FIG. 49A illustrates singulated fields 4901 with active layers at the top. Furthermore, FIG. 49A illustrates access holes 4902 for sacrificial layer etchants as well as sacrificial layer 4903 on bulk substrate 4904. Additionally, FIG. 49A illustrates field kerf 4905.

As discussed above, in step 4801, a partial etch of sacrificial layer 4903 is performed to create tethers 4906 as shown in FIG. 49B.

In step 4802, bulk substrate 4904 is flipped and temporarily attached to an intermediate substrate 4907 via an adhesive 4908 as shown in FIG. 49C. In one embodiment, intermediate substrate 4907 is made using silicon, silicon carbide, silicon oxide, fused silica, sapphire, polymer film and/or tape frame.

In step 4803, bulk substrate 4904 is separated using a sacrificial layer etch as shown in FIG. 49D. In one embodiment, bulk substrate 4904 (also referred to as the “carrier substrate”) is attached at all times to a carrier substrate chuck. The carrier substrate chuck could optionally be sacrificial-etchant-resistant, made, for instance using polytetrafluoroethylene (PTFE) and/or sapphire.

In step 4804, intermediate substrate 4907 is flipped and temporarily attached to a source substrate 4909 (e.g., source substrate 103) for assembly using islands of adhesive 4910 as shown in FIG. 49E. In one embodiment, source substrate 4909 is fabricated using silicon, silicon carbide, silicon oxide, fused silica, sapphire, polymer film and/or tape frame.

In step 4805, intermediate substrate 4907 (along with adhesive 4908) is removed, such as via an etching technique, as shown in FIG. 49F thereby leaving a source substrate 4909 with fields 4901.

A further discussion regarding method 4800 is provided below.

In one embodiment, fields 401, 4901 contain access holes distributed throughout the area of field 401, 4901. The etchant for the sacrificial layer (e.g., sacrificial layer 4903) could be sourced through access holes 4902 in addition to sourcing from the edges of fields 401, 4901 (during tether formation etch and bulk substrate separation). In one embodiment, the XY pitch for access hole 4902 is 20 μm. In one embodiment, a silicon layer above sacrificial layer 4903 is ˜300 nm thick. In one embodiment, sacrificial layer 4903 (for instance, SiGe or SOI) is ˜0.5 μm thick if a vapor etchant is used or ˜5 μm thick if a wet etchant is used with the values chosen to allow for sufficient lateral transport of the sacrificial layer etchant.

In one embodiment, the thickness of mesa structures 4401 (shown in FIG. 45) is increased to increase the local X, Y compliance of source substrate 103, 4909. In one embodiment, the volume of the adhesive drops 4416 (see FIG. 44F) is increased, to increase the pinned height of adhesive 4404, to increase the effective local X, Y compliance of source substrate 103, 4909.

In one embodiment, the thickness of fields 401, 4901, as they are lying active-side-down, during back-grinding or during the source wafer creation process shown in FIGS. 47A-47E (on the intermediate carrier substrate), could be modulated using one or more of the subtractive methods (for instance, inkjet-based planarizing), and additive methods (for instance, adding material to the backside using an inkjet, chemical vapor deposition, spin-coating, etc.). In one embodiment, the carrier substrate 4904, which could be made from silicon, silicon oxide, sapphire, fused silica, etc. is polished to be highly flat, and used as a reference for fields 401, 4901 attached to the substrate. Field heights on carrier substrate 4904 could be measured using a suitable topography measurement technique by measuring the change in topography between kerf 4905 and the edge of each field 401, 4901. In one embodiment, air-gage-based thickness measurement methods are used to measure the thickness of fields 401, 4901.

The adhesives described herein could be used to attach fields 401, 4901 to the source, intermediate, transfer, and carrier substrates 103, 801, 3309, 4904, as well as transfer chucks (TCs) 111. The adhesives could be composed of UV-release adhesive, thermal-release adhesive, light-to-heat-conversion (LTHC) coatings, liquid-crystal-based (LC) adhesives, UV-phase-switching LC-based adhesives, etc.

In one embodiment, the adhesive layer is composed of one or more layers of a first light-absorbing layer and a layer of transient material(s). The light absorbing layer could be a purely polymeric layer (for instance, LTHC coatings manufactured by 3M®), or a composite of polymer and nanoparticles that are optimized for light absorption. In one embodiment, fields 401, 4901 could be coated on their underside and/or their entirety using an adhesive coating (for instance, VALMat) that sticks to the transient material.

In one embodiment, adhesive drops 4416 are dispensed at a suitable distance away from the edges of a field 401, 4901, so that the cantilevered field (near the edges of field 401, 4901) bends to accommodate any residual height disparity between adjacent fields 401, 4901 during hybrid bonding. Such a bending would not necessarily lead to any significant overlay errors if the thickness of fields 401, 4901 is small.

In one embodiment, a light-to-heat-conversion (LTHC) layer is used to locally heat, and/or vaporize, the adhesive. The LTHC layer could be composed of one or more of the resonant absorber layers. In one embodiment, the LTHC contains embedded nanoparticles that are designed to absorb radiation in a narrow wavelength range, ideally at a wavelength at which one or more of the TCs 111, source substrates 103, transfer substrates 3309 show minimal or zero light absorption. In one embodiment, the adhesive is composed of polyimide. In one embodiment, the adhesive is composed of polyimide-LTHC-based release layers.

In one embodiment, the nanoparticles used for light absorption in the LTHC layer are made using gold, silicon, ruthenium, noble metals, titanium, and/or tungsten. In one embodiment, the size of the nanoparticles is increased to increase their melting point (for instance, the melting point of gold nanoparticles drops as the size of the nanoparticles decreases).

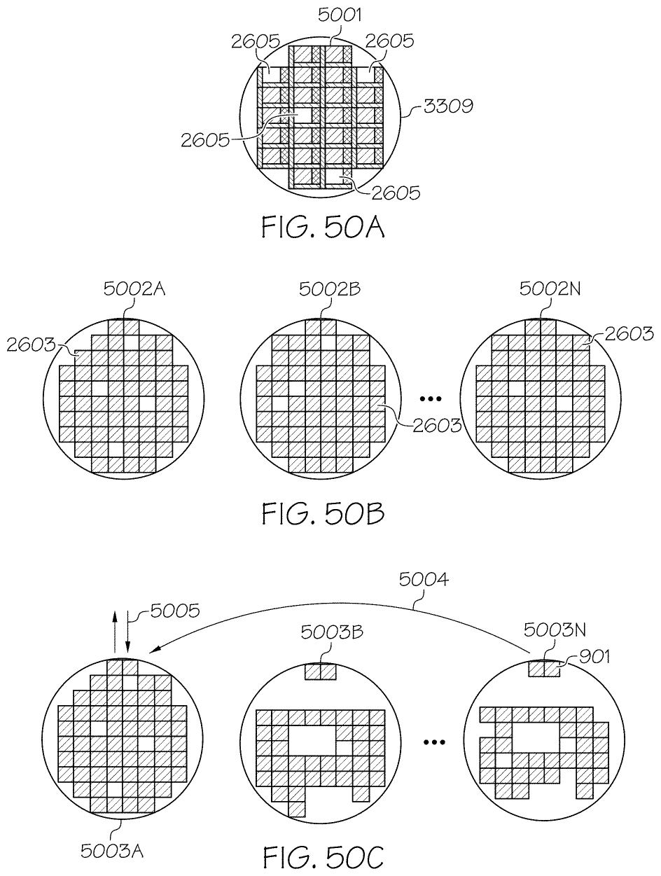

FIGS. 50A-50C illustrates an exemplary yield management flow in accordance with an embodiment of the present invention.

Referring now to FIG. 50A, FIG. 50A illustrates an exemplary SIP 5001 on a transfer substrate 3309 showing 4 exemplar known bad dies (KBDs) 2605 that need to be replaced with known good dies (KGDs) 2603 from the buffer substrates.

Referring to FIG. 50B, FIG. 50B illustrates known good dies (KGDs) 2603 on various active buffer substrates 5002A-5002N, where N is a positive integer number (5002A identified as “Active Buffer Substrate 1,” 5002B identified as “Active Buffer Substrate 2” and 5002N identified as “Active Buffer Substrate N”). Active buffer substrates 5002A-5002N may collectively or individually be referred to as active buffer substrates 5002 or active buffer substrate 5002, respectively.

At any point in time, there are N (N is a positive integer number) active buffer substrates 5002 that are maintained. In one embodiment, these are, at all points of time, maintained to be at a low level of depletion so that the KBD replacement step for any given transfer wafer 3309 can be completed in at most one or two pick and place steps.

FIG. 50C illustrates a series of inactive buffer substrates 5003A-5003N, where N is a positive integer number (5003A identified as “Inactive Buffer Substrate 1,” 5003B identified as “Inactive Buffer Substrate 2” and 5003N identified as “Inactive Buffer Substrate N”). Inactive buffer substrates 5003A-5003N may collectively or individually be referred to as inactive buffer substrates 5003 or inactive buffer substrate 5003, respectively.

As shown in FIG. 50C, dies 901 from the most depleted inactive buffer substrate 5003 (e.g., inactive buffer substrate 5003N) are assembled in a die-by-die manner, using one or more die-by-die transfer chucks to the least depleted inactive buffer substrate 5003 (e.g., inactive buffer substrate 5003A) as shown by arrow 5004 in FIG. 50C.

Furthermore, as shown in FIGS. 50B and 50C, the least depleted inactive buffer substrate 5003 (e.g., inactive buffer substrate 5003A) can be sent to the active set of buffer substrates 5002 once one of the active buffer substrates 5002 reaches a pre-specified threshold level of depletion as shown by arrows 5005.

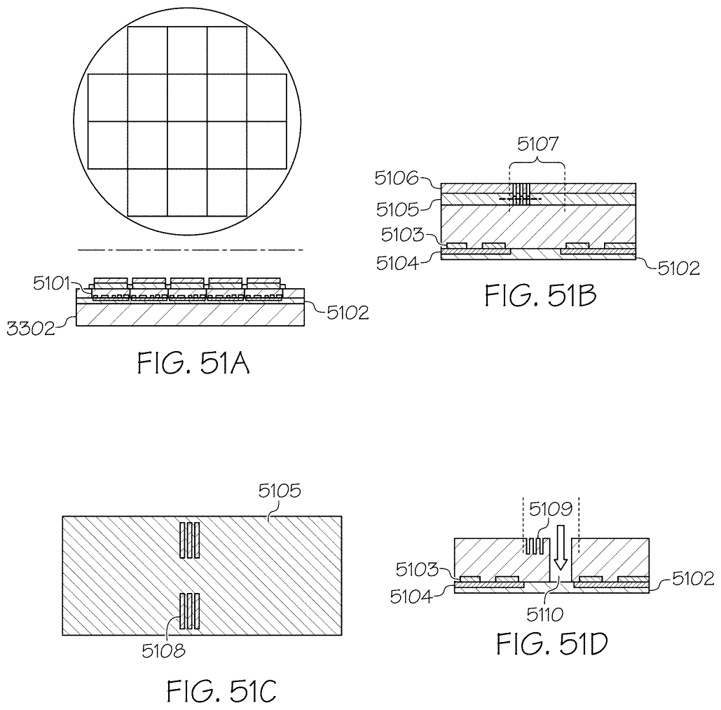

FIGS. 51A-51D illustrates an exemplary method for dicing and alignment mark creation in accordance with an embodiment of the present invention.

FIG. 51A illustrates un-diced fields 5101, with the device layers facing towards adhesive 5102 on carrier substrate 3302.

Furthermore, FIG. 51B is an expanded view of the layers above carrier substrate 3302 shown in FIG. 51A. As shown in FIG. 51B, FIG. 51B illustrates device structures 5103 residing on encapsulation layer 5104. Furthermore, FIG. 51B illustrates adhesive layer 5102, which could optionally be an etch stop. Additionally, FIG. 51B illustrates a layer 5105 to create a metal break. Furthermore, FIG. 51B illustrates an optional catalyst 5106 for creation of alignment marks using CICE. Additionally, FIG. 51B illustrates kerf region 5107, where an expanded view of kerf region 5107 is shown in FIG. 51C.

As shown in FIG. 51C, kerf region 5107 includes alignment marks 5108.

Furthermore, plasma etching for field dicing is shown in FIG. 51D. As shown in FIG. 51D, alignment marks 5109 are created using CICE. As further shown in FIG. 51D, diced edge 5110 is created using plasma etching.

In one embodiment, alignment marks 5108, 5109 are created in the fields during singulation.

In one embodiment, alignment marks 5108, 5109 are created on the backside of the fields. For example, photolithography (PL) or nanoimprint lithography (NIL) may be used for patterning of marks 5108, 5109. In another example, deep reactive ion etching (DRIE) may be used for dry etching of marks 5108, 5109. In a further example, CICE may be used for etching of marks 5108, 5109. Marks 5108, 5109 could be placed below the circuit patterns or near kerf region 5107 away from the circuit regions. In one embodiment, marks 5108, 5109 could be etched all the way through the thickness of the fields or partially.

The singulation of the fields could be performed using a separate set of pattering and etching techniques (compared to the alignment mark creation step). Photolithography (PL) or nanoimprint lithography (NIL) could be used for the patterning. Dry etching (e.g., DRIE) may be used for etching. Furthermore, wet etching (e.g., CICE) may be used for etching. Alternatively, singulation could be performed using a laser-based method, such as laser cutting, or stealth dicing.

Referring now to FIG. 52A, FIG. 52A illustrates registering picked fields 401 on TC 111 to a stable reference grid in accordance with an embodiment of the present invention. In particular, FIG. 52A illustrates upward-looking microscopes 5201 for registering picked fields 401 with respect to a stable reference grid and/or with respect to TC 111.

FIG. 52A further illustrates that microscopes coupled optionally reside on a separate VPM 5202, which could be calibrated against a stable reference grid.

Referring now to FIG. 52B, FIG. 52B illustrates registering the position of ACMs 3903 with respect to a stable reference grid 5203 (e.g., stable grid plate) in accordance with an embodiment of the present invention.

As shown in FIG. 52B, an integrated light source and sensor pair 5204A-5204B, 5204C-5204D is used for sending the displacement of ACM 3903 with respect to stable reference grid 5203 (e.g., stable grid plate). Integrated light source and sensor 5204A-5204D may collectively or individually be referred to as integrated light sources and sensors 5204 or integrated light source and sensor 5204, respectively.

Referring to FIGS. 52A-52B, in one embodiment, upward facing microscopes 5201 are used to measure the positions of fields 401 with respect to a global grid or the alignment with respect to TC 111 at the alignment mark locations on fields 401 as they are picked up onto TC 111. In one embodiment, upward facing microscopes 5201 are placed on a reconfigurable VPM, such as VPM 5202. In one embodiment, the position of upward facing microscopes 5201 could be measured with respect to a stable 2D grid and grid encoders attached to microscopes 5201. The position of microscopes 5201 on the VPM, such as VPM 5202, could be calibrated once, intermittently, or actively observed during every pick-and-place step. Alternatively, the position of upward facing microscopes 5201 could be measured using moiré-based metrology, where a set of moiré marks are placed on microscopes 5201, and another set of moiré marks are placed on a stable reference substrate, and a moiré microscope is used to observe the relative position of the corresponding set of marks on upward facing microscopes 5201 and the reference substrate. In one embodiment, a source substrate 103 is used to assemble multiple transfer substrates 3309 so that the VPM, such as VPM 5202, for upward looking microscopes 5201 has to reconfigure only once a new source substrate is loaded.

In one embodiment, fields 401 from a source substrate 103 that have been picked up by TC 111 are sampled at a limited set of locations, using upward-looking microscopes 5201, to measure the position of those fields 401 with respect to a stable reference grid 5203, and/or with respect to TC 111. The position of the rest of the picked fields 401 on TC 111 could be extrapolated using a suitable position extrapolation technique.

The alignment marks on fields 401 could be observed from the bottom-side of TC 111, from above TC 111 directly, or from above TC 111 with the alignment signal sourced through in-coupling gratings 4406 (that are used to send in UV light for adhesive curing). Interference of the alignment signal with circuit elements on fields 401 (for instance) could be filtered out using computational methods or by designing the position of the alignment marks such that they avoid interfering structures.

In one embodiment, the position of ACMs 3903 on the VPM, such as VPM 4302, could be observed directly with respect to a stable 2D grid. Compact grid encoders could be integrated onto ACMs 3903 and be used to look at the 2D grid plate to measure the displacement of the ACMs 3903 in real-time during assembly.

In one embodiment, transfer substrate 3309 contains a grid of alignment marks. The grid of alignment marks could be patterned on the mesas (e.g., mesa 4401) in transfer substrate 3309, using optionally the same technique that is used for fabricating the mesas (e.g., mesa 4401) (for instance, i-line lithography). In one embodiment, the incoming fields 401 are aligned to the grid of alignment marks on transfer substrate 3309. The field position errors coming in from the optional upward facing microscopes 5201, and from the alignment microscopes for measuring the alignment between transfer substrate 3309 and fields 401, could be corrected for by the set of thermal actuators on the transfer substrate chuck.

In one embodiment, the zero-layers for all fields 401 are fabricated on the same lithography tool (this includes different kinds of fields, and not simply different fields of the same kind).

In one embodiment, the field-facing surface of TC 111 is polished to be highly flat so as to act as a reference flat for fields 401 that are picked and placed. In one embodiment, the surface of TC 111 is actively modulated in the z-direction to achieve a flat or a desired non-flat profile.

In one embodiment, product wafer chuck 104 contains actuators to flatten the surface of product wafer 105 prior to hybrid bonding. Sensing of the topography on product wafer 105 could be performed using laser-based methods, air gages, etc. Actuation of the wafer chuck could be performed using piezoelectric actuators, thermal actuators, and/or electromagnetic actuators.

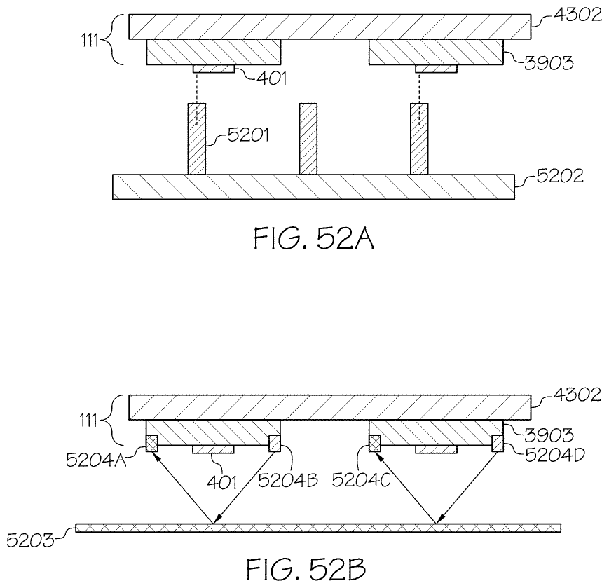

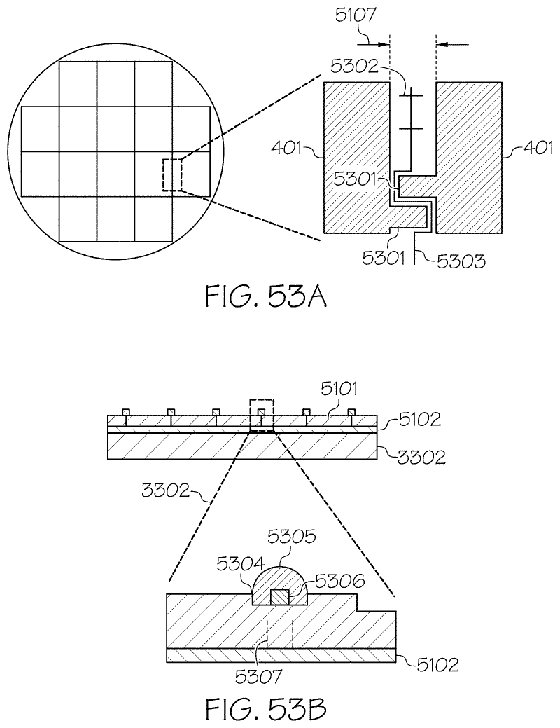

Referring now to FIGS. 53A-53B, FIGS. 53A-53B illustrate an exemplary approach for Metal-Assisted Catalytic Etching (MACE)-based dicing using an inkjetted catalyst in accordance with an embodiment of the present invention.

As shown in FIG. 53A, kerf region 5107 includes alignment marks 5301 as well as optional diced edge stabilizing structures 5302 and a diced edge 5303.

FIG. 53B is an expanded view of the layer above adhesive layer 5102. As shown in FIG. 53B, there is an optional shallow etched recess 5304 to improve etchant containment, a meniscus-contained etchant drop 5305, and an inkjetted catalyst 5306. Furthermore, FIG. 53B illustrates that the cut thickness 5307 could optionally be sub-micrometer scale.

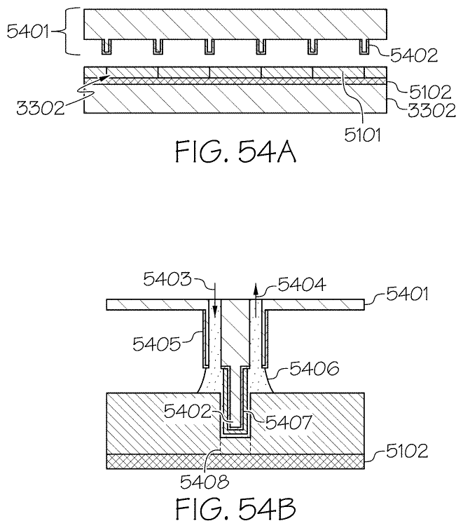

Referring now to FIGS. 54A-54B, FIGS. 54A-54B illustrate an alternative exemplary approach for MACE-based dicing using an inkjetted catalyst in accordance with an embodiment of the present invention.

As shown in FIG. 54A, a knife-edge dicer frame 5401 with catalyst-coated knife-edges 5402 is used to dice fields 401. An expanded view of such a process is shown in FIG. 54B.

As shown in FIG. 54B, knife-edge dicer frame (e.g., silicon) may include an etchant inlet 5403 and an etchant outlet 5404. Furthermore, as shown in FIG. 54B, there is an optional protective layer 5405 (e.g., carbon) for dicer frame 5401. Additionally, as shown in FIG. 54B, there is a meniscus-contained etchant drop 5406 and a catalyst film 5407, where the cut thickness 5408 could optionally be sub-micrometer scale.

The following discussion is based on FIGS. 53A-53B and 54A-54B.

MACE could be used to dice substrates into fields 401.

In one embodiment, the diced edges are straight. In another embodiment, the diced edges could have one or more curved or angled elements (such as 90° corners, etc.).

In one embodiment, the MACE catalyst is dispensed onto the un-diced substrates (e.g., un-diced fields 5101) using one or more inkjets. In one embodiment, the catalyst is gold. After dicing, the catalyst could be removed using an etchant (for instance, aqua regia for a gold catalyst).

In another embodiment, a knife-edge dicer frame 5401 is used to etch into the substrate (e.g., substrate 3302). In one embodiment, the knife-edge 5402 is coated with a MACE catalyst. In one embodiment, knife-edge 5402 is coated with a protective layer (a carbon layer, for instance). In one embodiment, knife-edge 5402 has intermittent stabilizing structures.

In one embodiment, MACE etchant covers the entire substrate (e.g., substrate 3302). In one embodiment, MACE etchants are dispensed using an inkjet near the kerf region 5107 of fields 401. In one embodiment, the MACE etchant is contained near kerf region 5107 using a recess that has been etched prior to dicing. In one embodiment, the MACE etchant is contained near kerf region 5107 using surface tension.

In one embodiment, the MACE etchant is circulated to prevent etch stagnation. In one embodiment, etchant circulation is implemented within the neighborhood of kerf region 5107.

In one embodiment, fields 401 are coated with a protective layer to protect against chemical damage during dicing and catalyst removal.

In one embodiment, knife-edge dicer frame 5401 has flexure mechanisms to provide compliance along the Z axis. In one embodiment, knife-edge dicer frame 5401 has flexure mechanisms to provide compliance along the Z axis for each field 401.

In one embodiment, the dicing edge has a cross-section that is optimized to reduce dishing and etch stagnation tendencies. In one embodiment, the dicing edge has a trapezoidal cross-section at the etch region. The trapezoidal cross-section could be created using crystallographic etching (KOH-based etching, for instance).

In one embodiment, the dicing edges have orthogonal structures to provide mechanical support.

In one embodiment, etch-based dicing techniques (e.g., MACE-based dicing) are used to create non-straight field edges. In one embodiment, etch-based dicing techniques (e.g., MACE-based dicing) are used to singulated fields 401 such that alignment marks 5301 on kerf region 5107 are retained after dicing.

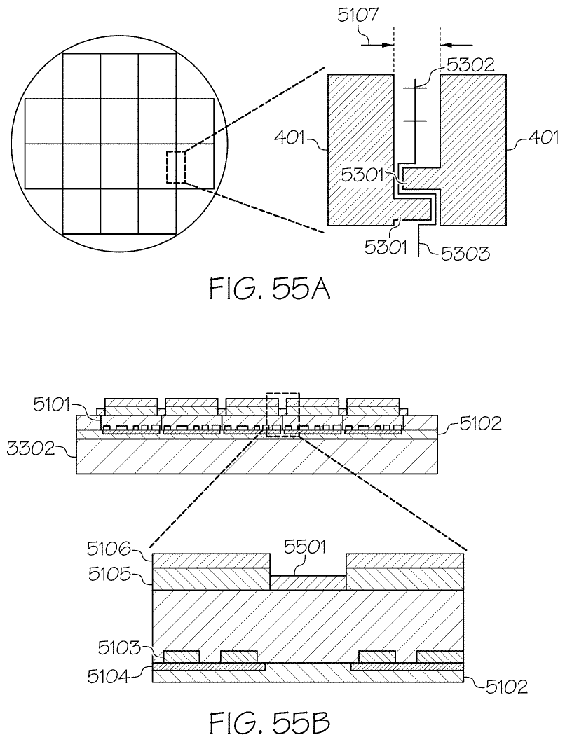

Referring now to FIGS. 55A-55B, FIGS. 55A-55B illustrate an exemplary method for substrate dicing post back-grinding in accordance with an embodiment of the present invention.

As shown in FIG. 55A, kerf region 5107 (e.g., 40 μm wide) includes full-sized alignment marks 5301 (e.g., 38 μm wide) as well as optional diced edge stabilizing structures 5302 and a diced boundary/edge 5303 (e.g., 1 μm).

FIG. 55B is an expanded view of the layer above adhesive layer 5102. As shown in FIG. 55B, there is a catalyst 5501 at the dicing boundary.

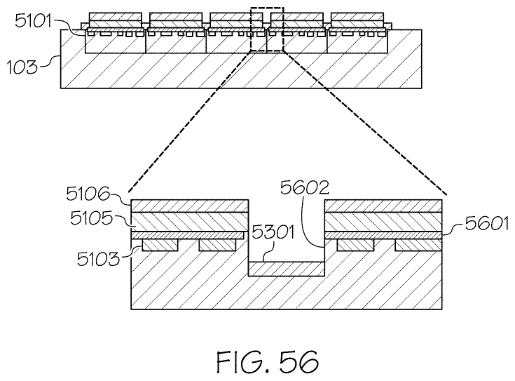

Referring now to FIGS. 56, FIG. 56 illustrates an exemplary method for creating dice cuts in source substrate 103 prior to back-grinding in accordance with an embodiment of the present invention.

In particular, FIG. 56 is an expanded view of the layer above adhesive layer 5102. As shown in FIG. 56, there is an encapsulation layer 5601 above device structures 5103 as well as a catalyst 5501 at the dicing boundary, which is now located below device structures 5103 as opposed to being located on the same level as layer 5105 to create a metal break as shown in FIG. 55B.

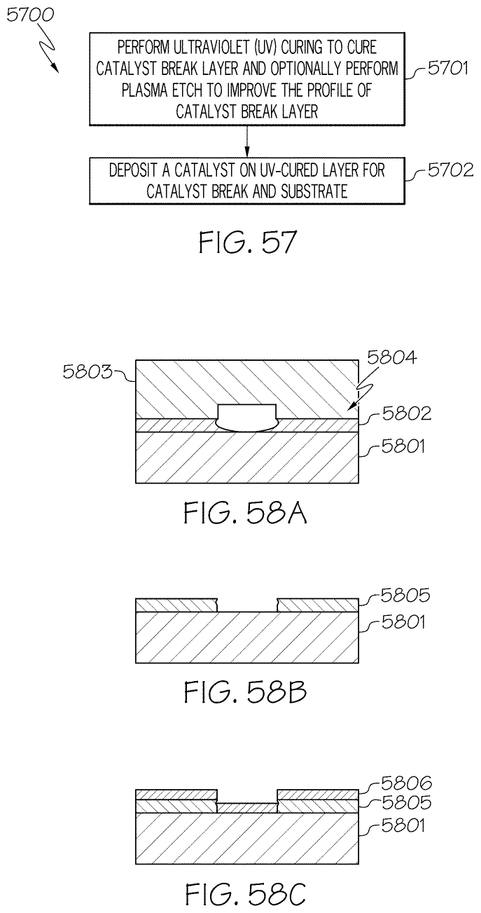

Referring now to FIG. 57, FIG. 57 is a flowchart of a method 5700 for creating a metal break for substrate dicing using metal assisted chemical etching in accordance with an embodiment of the present invention. FIGS. 58A-58C depict the cross-section views for creating a metal break for substrate dicing using metal assisted chemical etching using the steps described in FIG. 57 in accordance with an embodiment of the present invention.

Referring to FIG. 57, in conjunction with FIGS. 58A-58C, in step 5701, ultraviolet (UV) curing is performed to cure the catalyst break layer 5802 as shown in FIGS. 58A-58B. As shown in FIG. 58A, a UV-curable layer for catalyst break 5802 resides on top of substrate 5801 to be diced. Furthermore, as shown in FIG. 58A, the template with mesas 5803, such as mesa 5804, resides on catalyst break layer 5802. Upon performing UV curing, catalyst break layer 5802 is cured resulting in layer 5805 as shown in FIG. 58B.

Furthermore, in step 5701, an optional plasma etch may be performed to improve the profile of catalyst break layer 5802 resulting in the removal of template 5803 as shown in FIG. 58B.

In step 5702, a catalyst 5806 is deposited on UV-cured layer for catalyst break 5805 and substrate 5801 as shown in FIG. 58C.

The following discusses FIGS. 55A-55B, 56, 57 and 58A-58C.

In one embodiment, the dicing process is performed from the front side of source substrate 103 or the back side. In one embodiment, the process is performed from the front side of source substrate 103 that has been bonded to a carrier substrate 3302 or the back side of source substrate 103 with the front side bonded to carrier substrate 3302. In one embodiment, the process is performed on back-grounded substrates attached to carrier substrate 3302.

In one embodiment, the etch process for the silicon-containing regions of the device stack is CICE. In one embodiment, the etch process for the silicon components of the device stack is a silicon electrochemical etch. In one embodiment, the etch process for the non-silicon-containing regions of the device stack (e.g., silicon oxide, metals, non-silicon substrates such as germanium, gallium arsenide, silicon carbide) is a physical etch process, such as a deep reactive ion etching (DRIE) or a wet etch process (e.g., an etch that uses an etchant containing hydrofluoric acid in liquid or vapor form).

In one embodiment, the unetched parts of the device stack, such as metal lines that might remain unetched after exposure to an HF etch (for instance), are etched at the end using a more aggressive cleaning etch, such as using aqua regia, nitric acid, etc. In one embodiment, the unetched parts of the device stack that contain copper are etched using ferric chloride, cupric chloride, alkaline etchants, a mixture of hydrogen peroxide and sulphuric acid, chromic-sulphuric acid, sodium chlorate, citric acid, ammonium persulphate, etc. In one embodiment, the etchant for the unetched parts of the device stack is suitably diluted so that it has reduced or no activity for the device encapsulation layer, oxide layers, and other functional device layers. In one embodiment, the etchant is removed post-etch using a spray of dilutant (for instance, water).

In one embodiment, the device layers inside a field 401 are protected during the etching process using an encapsulation layer, such as encapsulation layer 5601. In one embodiment, the encapsulation layer, such as encapsulation layer 5601, is composed of a noble metal, a non-noble metal, a non-metal, and/or a polymer. In one embodiment the encapsulation layer, such as encapsulation layer 5601, is composed of CVD carbon. In one embodiment, the encapsulation layer, such as encapsulation layer 5601, is composed of parylene, a fluoropolymer (for instance, PTFE), and/or carbon (CVD deposited or spin-coated, for instance). In one embodiment, the encapsulation layer, such as encapsulation layer 5601, is electrically insulating. In one embodiment, the encapsulation layer, such as encapsulation layer 5601, contains silicon oxide.

In one embodiment, the encapsulation layer, such as encapsulation layer 5601, is patterned using photolithography or nanoimprint lithography. In one embodiment, the encapsulation layer, such as encapsulation layer 5601, is deposited using inkjetting. In one embodiment, the encapsulation layer, such as encapsulation layer 5601, is patterned using the discontinuous film created by fluidic pinning by a patterned template.

In one embodiment, the etchant for the chemical dicing process (using MACE, for instance) is dispensed only near the regions to be etched (using an inkjet, for instance) or be held in a chamber so as to cover the entire substrate including the regions to be etched. In one embodiment, an inkjet is used for etchant dispensing, and all the wetted regions of the inkjet are coated with an etchant-inert layer (e.g., a fluoropolymer, such as PTFE, parylene, etc.).

For MACE-based dicing, in one embodiment, the etch catalyst, such as catalyst 5106, is composed of a noble metal, a non-noble metal, a non-metal, a polymer, and/or a ceramic. In one embodiment, the catalyst, such as catalyst 5106, is composed of Au, Ag, Ru, Pt, Pd, C, Ta, W, Cu, Al, and/or Ni. In one embodiment, the catalyst, such as catalyst 5106, is a bilayer of gold and silver, with silver lying beneath and encapsulated by the gold. In one embodiment, the etch catalyst, such as catalyst 5106, is dispensed as nanoparticle ink using inkjets. In one embodiment, the etch catalyst, such as catalyst 5106, is electroplated. In one embodiment, the etch catalyst, such as catalyst 5106, is deposited using a physical vapor deposition technique, such as sputtering, electron beam deposition, etc. In one embodiment, the etchant is deposited using a technique that produces sidewalls with a line edge roughness (LER) below 10 nm (1σ, or 3σ), for instance, using a physical vapor deposition technique (e.g., e-beam, focused ion beam, sputtering), electroplating, and/or electroless plating. In one embodiment, the catalyst, such as catalyst 5106, contains a thin film of silicon oxide underneath to improve etch uniformity. In one embodiment, the thickness of the silicon oxide film is between 10 nm and 100 nm. In one embodiment, the etch rate of the catalyst, such as catalyst 5106, is controlled by temperature, pH of the etchant solution (using a buffer solution, for instance HF and NH4OH, or NH4F), plasma treatment of the etchant, alloying the catalyst with a material (e.g., carbon) that has lower activity for MACE using combinatorial sputtering.

In one embodiment, the catalyst, such as catalyst 5106, is dispensed on top of a discontinuous polymer film that is created by fluidic pinning (of a UV-curable polymer) by a patterned template, and subsequent UV exposure (of the UV-curable polymer). In one embodiment, the catalyst, such as catalyst 5106, contains a break at the edge between the polymer and the substrate, such as substrate 3302. In one embodiment, plasma-based cleaning is used to clean the edges of the polymer to create an improved metal break.

In one embodiment, MACE-based dicing is stopped in a timed manner, or in case an adhesive film, such as adhesive film 5102, is available (in case the substrate is attached to a carrier substrate), the adhesive film is used as an etch stop. In one embodiment, the adhesive film, such as adhesive film 5102, is coated with an etchant resistant material, such as carbon.

Once dicing is complete, the catalyst, such as catalyst 5106, is removed using a suitable etchant, such as aqua region (or an etchant containing potassium iodide, cyanides, etc.) for gold, or an atomic layer etching process, or in the specific case when partial dicing is performed prior to back-griding, the back-grinding process could also dispose of the catalyst by grinding it off.

In one embodiment, the geometry of the diced edge along a straight edge of a field 401 is composed of curved and/or angled components. In one embodiment, alignment marks, such as marks 5301, are contained in curved portions of diced edge 5303. In one embodiment, diced edge 5303 contains support structures, such as structures 5302, to prevent wandering. Such a support structure may be present on the external or internal portions of diced edge 5303. The alignment marks, such as marks 5301, contain recesses to accommodate the support structures, such as structures 5302. In one embodiment, image processing techniques are utilized to filter out any loss of alignment signal due to the recesses in the alignment marks, such as marks 5301. The recesses created in the alignment marks, such as marks 5301, could be filled-in post-dicing using a suitable material deposition technique, such as CVD (of silicon, silicon oxide, etc.), ALD, etc.

In one embodiment, the catalyst film, such as catalyst 5106, deposited on the metal break layer 5105, is used to create electrostatic attraction between the dies and transfer chuck 111.

High aspect ratio, porosity-free, taper-free semiconductor nanostructures can be made using CICE. CICE is also described as Metal Assisted Chemical Etch (MACE). For CICE of silicon, catalysts that comprise one or more of the following: (in alloy form, if necessary) Au, Pt, Pd, Ag, Ru, Ir, W, Cu, TiN, Ti, Graphene, carbon, etc. catalyze the reduction of H₂O₂ and inject the resulting electronic holes into silicon thereby changing the oxidation state of silicon. In one embodiment, HF selectively etches this silicon, and the catalyst sinks into the etched region to continue the local redox reaction, thereby producing silicon nanostructures in areas without the catalyst. The characteristics of the resulting silicon nanostructures are highly dependent on the balance of reaction rates, charge transfer, etchant mass transfer and movement of the catalyst. In one embodiment, the substrate for CICE consists of one or more of the following: a single crystal bulk silicon wafer, a layer of polysilicon deposited on a substrate, a layer of amorphous silicon deposited on a substrate, an SOI (silicon on insulator) wafer, silicon-on-glass, silicon-on-sapphire, epitaxial silicon on a substrate, alternating layers of semiconductor materials of varying doping levels and dopants, highly doped silicon and lightly doped silicon, undoped silicon and doped silicon or germanium, silicon and SiₓGe₁₋ₓ, differently doped silicon and/or SiₓGe₁₋ₓ, differently doped silicon and/or Ge, or Si and Ge.

In one embodiment, the collapse of CICE-etched nanostructures is delayed or eliminated by using “collapse-avoiding caps” or “collapse-avoiding features” on the tips of the nanostructures. In one embodiment, the collapse-avoiding caps prevent collapse by electrostatic repulsion between the nanostructures.

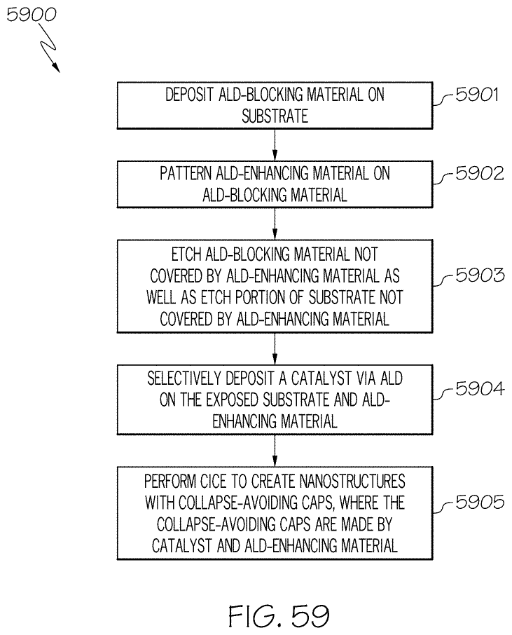

FIG. 59 is a flowchart of a method 5900 for patterning a catalyst using selective atomic layer deposition (ALD), such that the catalyst is part of “collapse-avoiding caps,” in accordance with an embodiment of the present invention. In this process, the catalyst does not grow on one part of the pattern mask. ALD chemistries are listed in Table 2:

TABLE 2
Precursors for atomic layer deposition (ALD).

| | | | | Substrate |
|---|---|---|---|---|
| Catalyst | | | | for |
| material | Precursors A | Gas B | ALD chemistry | deposition |
| Platinum | Trimethyl(methylcyclo-pentadienyl) | Oxygen | Plasma- | SiO2, Si |
| | platinum(IV) | | enhanced, | with native |
| | | | Thermal - | oxide |
| | | | combustion | |
| | | | chemistry | |
| Palladium | Pd(hfac)₂ | Formalin, | Thermal - | |
| | | H2 | hydrogen | |
| | | | reduction | |
| | | | chemistry | |
| Gold | trimethylphosphinotrimethylgold(III) | Oxygen | Plasma | |
| TiN | Tetrakis(diethylamido) titanium(IV), | NH₃ | Plasma- | |
| | Tetrakis(dimethylamido) | | enhanced, | |
| | titanium(IV), Titanium tetrachloride, | | Thermal | |
| | Titanium(IV) isopropoxide | | | |
| TaN | Tris(diethylamido)(tert-butylamido) | Hydrogen, | Plasma- | |
| | tantalum(V) | NH₃ | enhanced, | |
| | | | Thermal | |
| Ru | Bis(ethylcyclopentadienyl) | NH₃, O₂ | Plasma, | |
| | ruthenium(II) | | Thermal - | |
| | | | combustion | |
| | | | chemistry | |
| Ir | Ir(acac)₃ | O₂ | Thermal - | |
| | | | combustion | |
| | | | chemistry | |
| Ag | Ag(fod)(PEt₃) | Hydrogen | Plasma- | |
| | | | enhanced | |
| Cu | (Cu(thd)₂); | Methanol, | Thermal - | |
| | Copper beta-diketonate: Cu(II) | ethanol, | hydrogen | |
| | 1,1,1,5,5,5- | formalin | reduction | |
| | hexafluoroacetylacetonate | | chemistry | |
| | (Cu(hfac)₂) | | | |
| Co | Co(MeCp)₂ | H₂ or NH₃ | Plasma- | |
| | | | enhanced | |
| | Bis(N-tert butyl, N′- | H₂O | Thermal | |
| | ethylpropionamidinato) cobalt (II) | | | |
| W | Bis(tert-butylamido) | Si₂H₆ | Thermal - | |
| | bis(dimethylamino) tungsten(VI), | | fluorosilane | |
| | WF6 | | elimination | |
| | | | chemistry | |

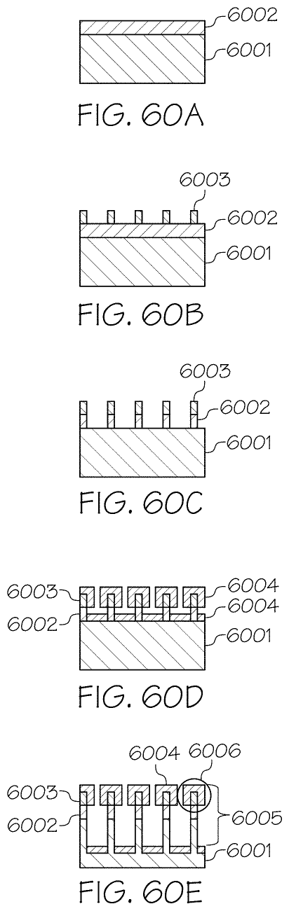

As stated above, FIG. 59 is a flowchart of a method 5900 for patterning a catalyst using selective atomic layer deposition (ALD), such that the catalyst is part of “collapse-avoiding caps,” in accordance with an embodiment of the present invention. FIGS. 60A-60E depict the cross-section views for patterning a catalyst using selective atomic layer deposition (ALD), such that the catalyst is part of “collapse-avoiding caps,” using the steps described in FIG. 59 in accordance with an embodiment of the present invention.

In one embodiment, the catalyst is patterned using one or more of the following: nanoimprint lithography, photolithography, focused ion beam milling, electron beam lithography, laser interference lithography, nanosphere lithography, block copolymer lithography, and directed self-assembly. In another embodiment, the CICE patterning includes using thermally stable carbon, etching into this carbon using NIL (nanoimprint lithography) resist, photoresist, etc., and stripping any polymer resists prior to catalyst deposition using metal break.

Referring to FIG. 59, in conjunction with FIGS. 60A-60E, in step 5901, ALD-blocking material 6002 is deposited on substrate 6001 as shown in FIG. 60A.

In step 5902, ALD-enhancing material 6003 is patterned on ALD-blocking material 6002 as shown in FIG. 60B.

In step 5903, ALD-blocking material 6002 not covered by ALD-enhancing material 6003 as well as a portion of substrate 6001 not covered by ALD-enhancing material 6003 are etched as shown in FIG. 60C.

In step 5904, a catalyst 6004 is selectively deposited via ALD on the exposed substrate 6001 and ALD-enhancing material 6003 as shown in FIG. 60D.

In step 5905, CICE is performed to create nanostructures 6005 with collapse-avoiding caps 6006, where collapse-avoiding caps 6006 are made by catalyst 6004 and ALD-enhancing material 6003.

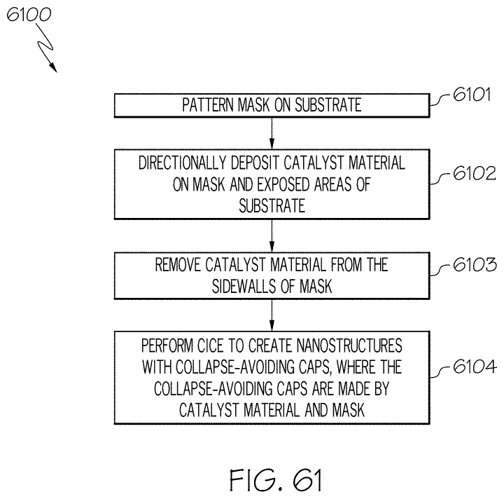

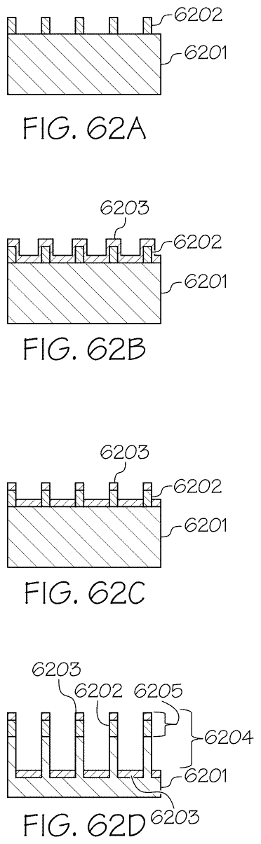

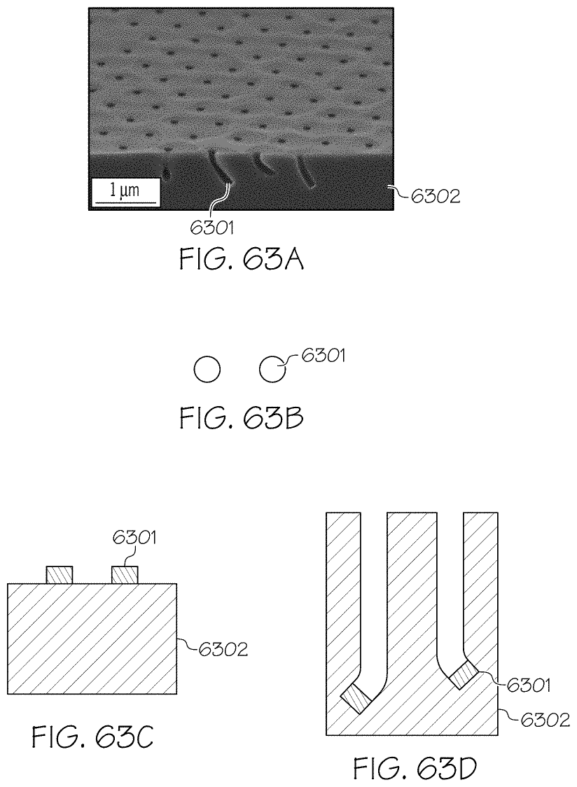

Referring now to FIG. 61, FIG. 61 is a flowchart of a method 6100 for creating collapse-avoiding caps as well as catalyst patterning by directional deposition and atomic layer etching of the catalyst in accordance with an embodiment of the present invention. FIGS. 62A-62D depict the cross-section views for creating collapse-avoiding caps as well as catalyst patterning by directional deposition and atomic layer etching of the catalyst using the steps described in FIG. 61 in accordance with an embodiment of the present invention.

Referring to FIG. 61, in conjunction with FIGS. 62A-62D, in step 6101, mask 6202 is patterned on substrate 6201 as shown in FIG. 62A.

In step 6102, catalyst material 6203 is directionally deposited on mask 6202 and the exposed areas of substrate 6201 (i.e., those areas of substrate 6201 not covered by mask 6202) as shown in FIG. 62B. In one embodiment, directional deposition of catalyst material 6203 is performed using thermal evaporation, electron-beam evaporation, physical vapor deposition, etc. In one embodiment, catalyst material 6203 is Ru.

In step 6103, catalyst material 6203 is removed from the sidewalls of mask 6202, such as via dry etching, as shown in FIG. 62C. In one embodiment, the etching of catalyst material 6203, such as Ru, is used to remove thinner metal deposited on the sidewalls of mask 6202.

In step 6104, CICE is performed to create nanostructures 6204 with collapse-avoiding caps 6205, where collapse-avoiding caps 6205 are made by catalyst material 6203 and mask 6202.

During the CICE process, isolated metal catalysts may wander and create non-vertical undesired etch paths. Discontinuous catalyst features tend to wander during the CICE process and cause defects. CICE of holes with isolated catalysts may wander due to van der Waals forces on the catalyst as well as stochastic variations in forces applied due to local etchant concentration or etch rate variations, as shown in FIGS. 63A-63B.

FIGS. 63A-63D illustrate wandering of isolated catalysts during CICE in accordance with an embodiment of the present invention.

Referring to FIGS. 63A-63D, FIG. 63A illustrates the isolated catalyst 6301 wandering into substrate 6302. FIG. 63B illustrates the top view of isolated catalyst 6301. FIG. 63C illustrates the cross-section view of isolated catalyst 6301. Furthermore, FIG. 63D illustrates the catalyst center-etch rate stochastic variations.

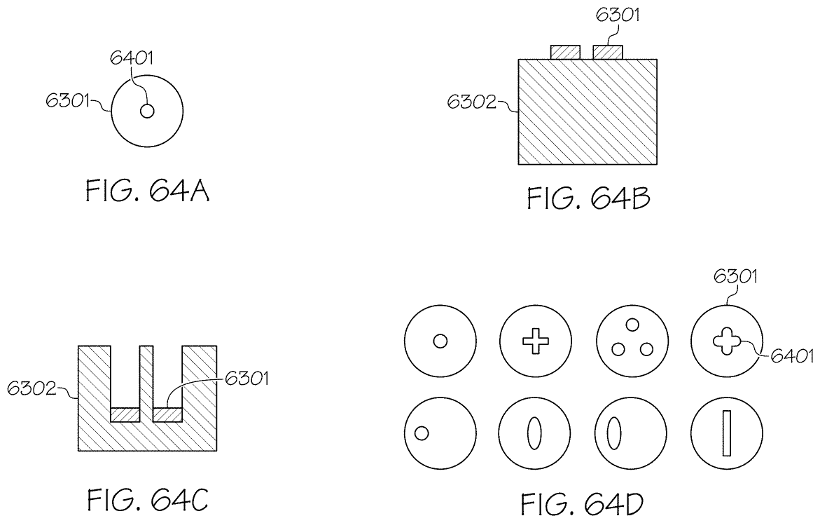

To prevent wandering of catalysts, such as catalyst 6301, stabilizing patterns can be inserted in the isolated catalysts—thereby providing a supporting structure to the catalyst during CICE. These stabilizing patterns can be predetermined holes of different cross-sections, that are patterned in the isolated catalyst structures. The supporting structures can be removed after CICE to achieve vertical wander-free CICE. FIGS. 64A-64D show exemplary geometries for the stabilizing patterns or supporting structures (referred to herein as “catalyst buttresses”), which may be holes of different cross-sections, in accordance with an embodiment of the present invention.

Referring to FIG. 64A, FIG. 64A illustrates a top view of catalyst 6301 containing a stabilizing pattern 6401. FIG. 64B illustrates the cross-section view of catalyst 6301 containing a stabilizing pattern 6401. FIG. 64C illustrates the cross-section view of catalyst 6301, where stabilizing pattern 6401 is removed after CICE is performed. Furthermore, FIG. 64D illustrates various stabilizing patterns 6401 to be inserted in catalyst 6301.

In one embodiment, patterning and fabrication of the catalyst buttress designs shown in FIG. 64D is performed using photolithography, imprint lithography, e-beam lithography, EUV lithography, self-aligned patterning, spacer patterning, etc.

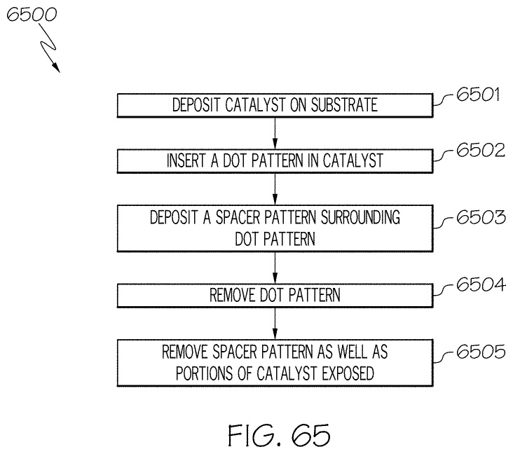

FIG. 65 is a flowchart of a method 6500 for making isolated catalyst dots with circular catalyst buttresses with Ru as the catalyst in accordance with an embodiment of the present invention. FIGS. 66A-66E depict the cross-section views for making isolated catalyst dots with circular catalyst buttresses with Ru as the catalyst using the steps described in FIG. 65 in accordance with an embodiment of the present invention. FIGS. 67A-67E depict the top views for making isolated catalyst dots with circular catalyst buttresses with Ru as the catalyst using the steps described in FIG. 65 in accordance with an embodiment of the present invention.

Referring to FIG. 65, in conjunction with FIGS. 66A-66E and FIGS. 67A-67E, in step 6501, catalyst 6301 is deposited on a substrate 6601 as shown in FIGS. 66A and 67A. In one embodiment, the material of catalyst 6301 is Ru.

In step 6502, a dot pattern 6602 is inserted in catalyst 6301, such as via photolithography, imprint lithography, e-beam lithography, EUV lithography, self-aligned patterning, spacer patterning, etc. as shown in FIGS. 66B and 67B. In one embodiment, dot pattern 6602 is oxide material.

In step 6503, a spacer pattern 6603 is deposited surrounding dot pattern 6602 as shown in FIGS. 66C and 67C.

In step 6504, dot pattern 6602 is removed, such as via various types of etching techniques as shown in FIGS. 66D and 67D. In one embodiment, dot pattern 6602 is oxide material, which is removed via etching. In one embodiment, the etchant used for etching includes one or more of the following: fluoride species, oxidants, alcohols and protic, aprotic, polar and non-polar solvents. In one embodiment, the etchant includes two or more of the following: fluoride species containing chemicals HF or NH₄F, oxidants H₂O₂, KMnO₄, or dissolved oxygen, alcohols ethanol, isopropyl alcohol, or ethylene glycol, protic, aprotic, polar and non-polar solvents, such as DI water or dimethyl sulfoxide (DMSO).

In step 6505, spacer pattern 6603 as well as portions of catalyst 6301 exposed (i.e., portions of catalyst 6301 that are not covered by spacer pattern 6603) are removed via etching, such as via various etching techniques (e.g., dry etching), thereby creating isolated dots as shown in FIGS. 66E and 67E.

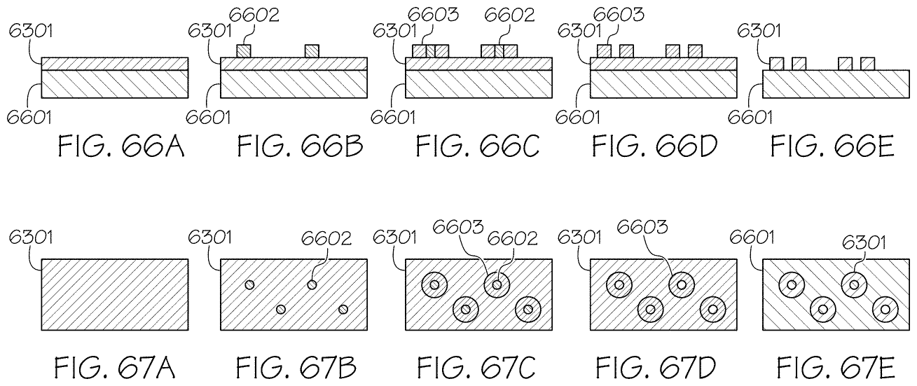

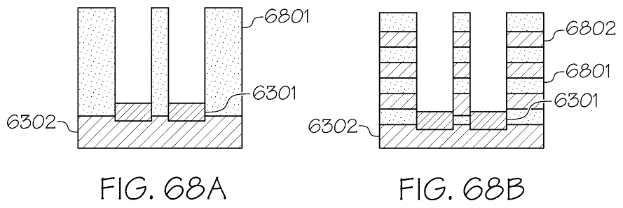

In one embodiment, the silicon nanostructures after CICE are porous. Porosity in silicon (Si) enhances etchant diffusion and may further prevent wandering of isolated catalysts 6301. In another embodiment, the silicon nanostructures are made using silicon superlattice etch to create alternating layers of porous and non-porous silicon nanostructures for exemplary applications in 3D NAND Flash, as shown in FIGS. 68A-68B.

FIG. 68A illustrates a catalyst 6301 along with nanostructures composed of porous silicon 6801 in accordance with an embodiment of the present invention. FIG. 68B illustrates a catalyst 6301 along with nanostructures composed of alternating layers of porous silicon 6801 and non-porous silicon 6802 in accordance with an embodiment of the present invention.

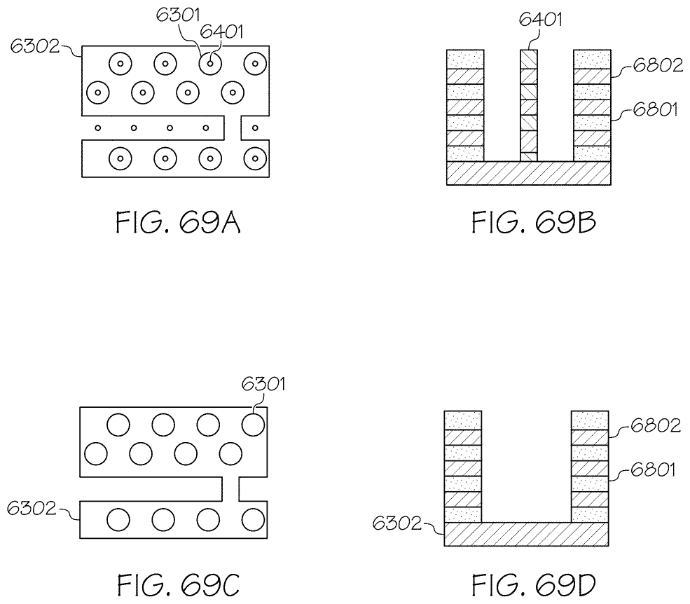

FIGS. 69A-69D illustrate removing silicon buttresses (“stabilizing patterns”) (“catalyst buttresses”) after CICE with isolated catalysts 6301 having buttresses, such as buttresses 6401, to prevent wandering in accordance with an embodiment of the present invention. In one embodiment, the buttress, such as buttress 6401, collapses due to capillary and adhesion forces. Patterning of an etch mask and anisotropic plasma etch of silicon is used to remove the collapsed silicon buttresses, such as buttresses 6401.

Referring to FIG. 69A, FIG. 69A illustrates a top view of several catalysts 6301 with a buttress design 6401 (e.g., silicon buttress). FIG. 69B illustrates a cross-section view of a catalyst 6301 with a buttress design 6401 (e.g., silicon buttress). The buttress design 6401 (e.g., silicon pillar) is then removed resulting in the structure shown in FIGS. 69C and 69D. FIG. 69C illustrates a top view of the resulting structure after the removal of buttress design 6401. FIG. 69D illustrates a cross-section view of the resulting structure after the removal of buttress design 6401.

In one embodiment, shown in FIGS. 70A-70C, the collapsed pillars (collapsed buttresses 6401, such as silicon buttresses) are designed to deterministically collapse in a certain direction, such as by placement of the buttress pattern towards one side of the etch, in accordance with an embodiment of the present invention. The collapsed buttress structure, such as buttress 6401, is removed using a plasma etch, with an etch mask whose geometry is biased to expose the collapsed region.

Referring to FIG. 70A, FIG. 70A illustrates a collapsed silicon buttress 6401, in which it is designed to deterministically collapse in a certain direction, such as towards one side of the etch. FIG. 70B illustrates the placement of an etch mask 7001 and FIG. 70C illustrates the removal of the collapsed silicon buttress 6401 with etch mask 7001, whose geometry is biased to expose the collapsed region.

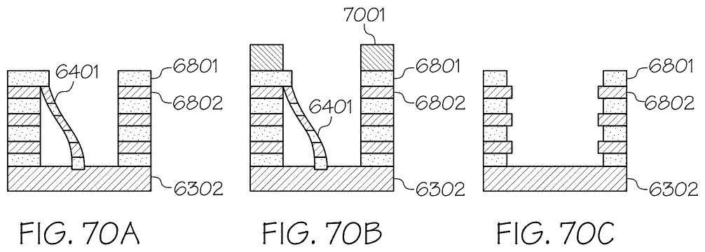

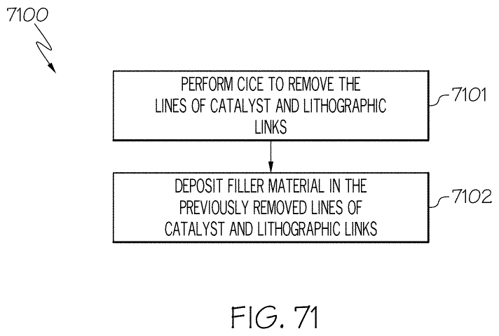

Similar to etching of holes with CICE, etching of lines and spaces requires long isolated lines of catalysts, which tends to wander during the CICE process. In one embodiment, lithographic links between the lines and spaces are used to connect the isolated catalyst lines. The dimensions and locations of the lithographic links are designed to ensure minimum disruption to the final device requirements. Deposition of filler material using methods, such as CVD, ALD, physical vapor deposition (PVD), etc. are used to fill the gaps etched by CICE in the areas with lithographic links. In one embodiment, the lithographic links are orthogonal to the direction of the desired lines and spaces etch, and ALD of low-k dielectric materials, such as silicon oxide are used to fill the gaps, as discussed below in connection with FIGS. 71, 72 and 73A-73C.

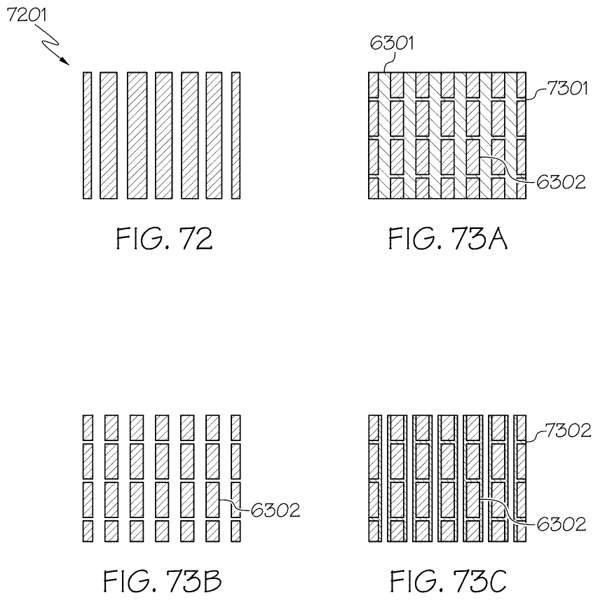

FIG. 71 is a flowchart of a method 7100 for fabricating line/space patterns with lithographic links using CICE in accordance with an embodiment of the present invention. FIG. 72 illustrates a top view of the desired line/space pattern using the steps described in FIG. 71 in accordance with an embodiment of the present invention. FIGS. 73A-73C depict the cross-section views for fabricating line/space patterns with lithographic links using CICE using the steps described in FIG. 71 in accordance with an embodiment of the present invention.

Referring to FIG. 72, FIG. 72 illustrates a top view of the desired line/space pattern 7201. Referring to FIG. 73A, FIG. 73A illustrates long isolated lines of catalysts 6301 with lithographic links 7301 to connect isolated catalyst lines 6301 which surround areas of substrate 6302.

Referring now to FIG. 71, in conjunction with FIGS. 73A-73C, in step 7101, CICE is performed to remove the lines of catalyst 6301 and lithographic links 7301 as shown in FIG. 73B.

In step 7102, filler material 7302 is deposited, such as via CVD, PVD, etc., in the previously removed lines of catalyst 6301 and lithographic links 7301 as shown in FIG. 73C.

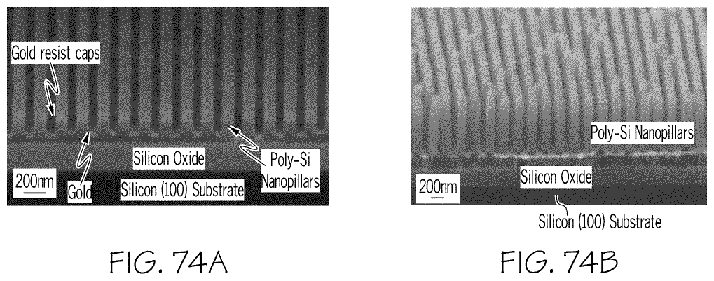

Fabrication of high aspect ratio structures in polysilicon using CICE enables applications, such as stack capacitors in DRAM. FIGS. 74A-74B show an exemplary polysilicon nanowire array fabricated using CICE with gold as a catalyst in accordance with an embodiment of the present invention.

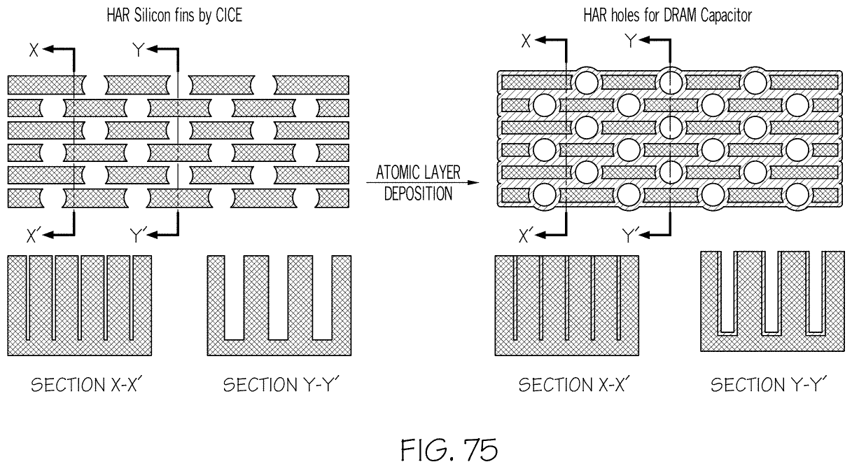

As isolated catalysts, such as isolated catalysts 6301, suffer from wandering, CICE to create high aspect ratio holes is challenging. In one embodiment, the etched nanostructures can be used to change the tone of the features—from pillars to holes, using atomic layer deposition (ALD) to partially fill gaps between the pillars. FIG. 75 shows an exemplary geometry that converts silicon fins to holes using ALD of silicon oxide in accordance with an embodiment of the present invention. In one embodiment, the silicon fin areas are used to create transistors, and the hole areas are used to create capacitors to DRAM devices.

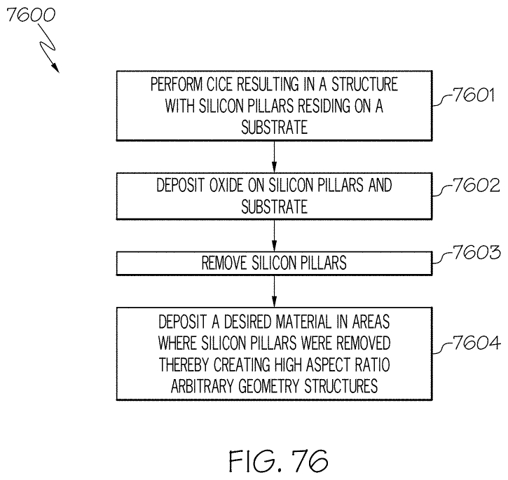

The tone-reversal process with CICE can be further expanded to include arbitrary materials, where polysilicon or silicon structures are made with CICE, and the gaps between the structures are filled with structural material. In one embodiment, the material is an insulator. In one embodiment, the structural material is carbon, amorphous carbon, silicon dioxide, silicon nitride, metal oxide, tin oxide, and/or indium tin oxide. In one embodiment, the deposited material is one or more of the following: SiO₂, TiO₂, Al₂O₃, Pd, Pt, W, TiN, TaN, Cu, SiNx, SnOx, ZnOx, etc. The silicon is selectively removed to create the inverse tone of the structures in the structural material. In one embodiment, the etched polysilicon and/or silicon structures are removed using: selective wet etchants (e.g., KOH, TMAH, EDP), dry etchants (e.g., XeF2 vapor), plasma etching (e.g., Cl₂, SF₆, BCl₃, etc. species in plasma. Optionally, desired material can be deposited in the areas where silicon was removed, thereby creating high aspect ratio arbitrary geometry structures in any material. Alternatively, the structural material could be a conductor, and the desired material could be an insulator, depending on the application requirements. FIGS. 76, 77A-77D and 78A-78D discuss the process for tone-reversal using CICE.

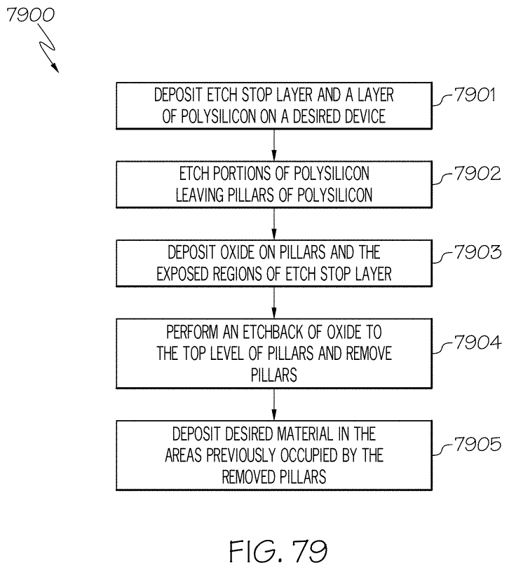

In one embodiment, the etch stop layer is selected such that it does not get etched in the CICE process as discussed in FIGS. 79, 80A-80D and 81A-81F. In another embodiment, the etch stop layer is removed during the tone-reversal process as discussed in FIGS. 82, 83A-83D and 84A-84G. The etch stop layer thickness is optimized to reduce the possibility of undercut as discussed in FIGS. 82, 83A-83D and 84A-84G. The thickness of the etch stop layer thickness can range from 1 nm-100 nm. In one embodiment, the etch stop material includes carbon, Cr, chromium oxide, aluminum oxide, silicon nitride, silicon oxide, ruthenium, etc. or any combination thereof. In one embodiment, the etch stop layer etch is optimized to be anisotropic and selective, such as removal of a carbon layer using oxygen plasma etch, chemical etch with ozone, etc.

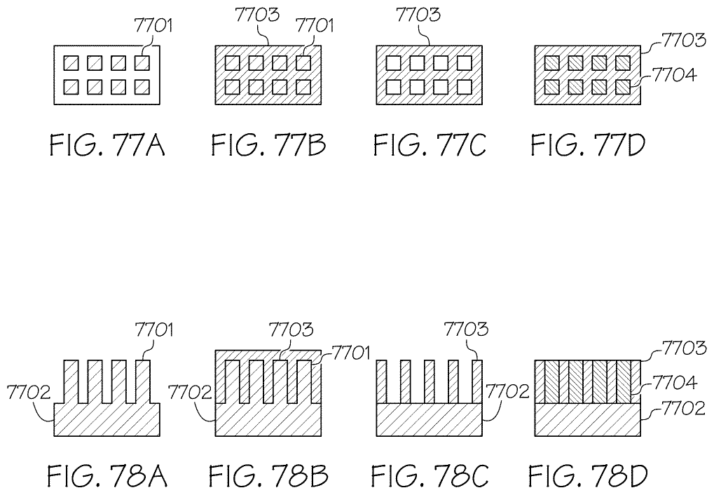

Referring now to FIG. 76, FIG. 76 is a flowchart of a method 7600 for the tone-reversal process with CICE in accordance with an embodiment of the present invention. FIGS. 77A-77D depict the top views for the tone-reversal process with CICE using the steps described in FIG. 76 in accordance with an embodiment of the present invention. FIGS. 78A-78D depict the cross-section views for the tone-reversal process with CICE using the steps described in FIG. 76 in accordance with an embodiment of the present invention.

Referring to FIG. 76, in conjunction with FIGS. 77A-77D and 78A-78D, in step 7601, CICE is performed resulting in a structure with silicon pillars 7701 residing on a substrate 7702 as shown in FIGS. 77A and 78A.

In step 7602, a deposition of oxide 7703 on silicon pillars 7701 and substrate 7702 is performed as shown in FIGS. 77B and 78B.

In step 7603, silicon pillars 7701 are removed (i.e., etched) using various etching techniques, such as CICE, as shown in FIGS. 77C and 78C.

In step 7604, a desired material 7704 is deposited, such as via CVD, PVD, ALD, etc., in areas where silicon pillars 7701 were removed thereby creating high aspect ratio arbitrary geometry structures as shown in FIGS. 77D and 78D.

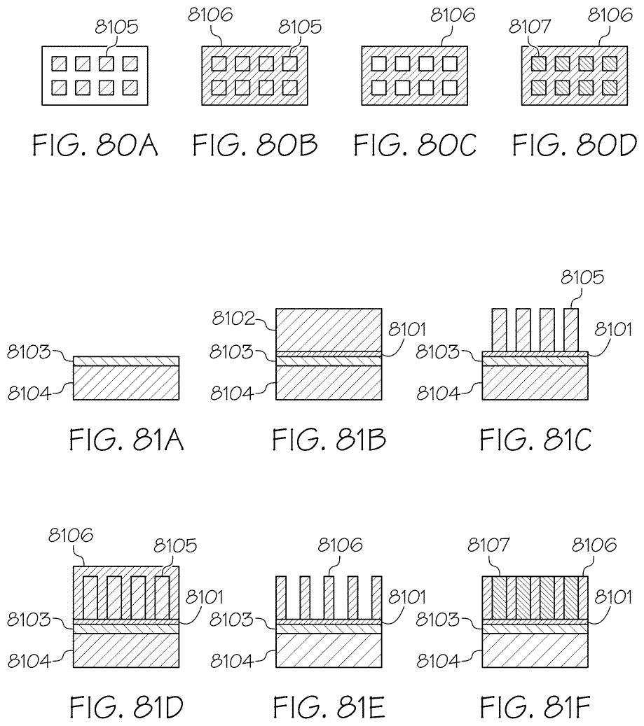

Referring now to FIG. 79, FIG. 79 is a flowchart of a method 7900 for performing the tone-reversal process with CICE of polysilicon which includes the catalyst removal using a selective chemical etch in accordance with an embodiment of the present invention. FIGS. 80A-80D depict the top views for performing the tone-reversal process with CICE of polysilicon which includes the catalyst removal using a selective chemical etch using the steps described in FIG. 79 in accordance with an embodiment of the present invention. FIGS. 81A-81F depict the cross-section views for performing the tone-reversal process with CICE of polysilicon which includes the catalyst removal using a selective chemical etch using the steps described in FIG. 79 in accordance with an embodiment of the present invention.

Referring to FIG. 79, in conjunction with FIGS. 80A-80D and 81A-81F, in step 7901, an etch stop layer 8101 and a layer of polysilicon 8102 are deposited on a desired device, such as a device that includes a layer of desired material 8103 residing on a substrate 8104, as shown in FIGS. 81A-81B.

In step 7902, CICE is performed to etch portions of polysilicon 8102 leaving pillars 8105 of polysilicon as shown in FIGS. 80A and 81C.

In step 7903, a deposition of oxide 8106 on pillars 8105 and the exposed regions of etch stop layer 8101 (i.e., those regions not covered by pillars 8105 of polysilicon) is performed as shown in FIGS. 80B and 81D.

In step 7904, an etchback of oxide 8106 to the top level of pillars 8105 as well as the removal of pillars 8105, such as via various etching techniques (e.g., ALE), is performed as shown in FIGS. 80C and 81E.

In step 7905, desired material 8107 is then deposited, such as via CVD, PVD, ALD, etc., in the areas previously occupied by the removed pillars 8105 as shown in FIGS. 80D and 81F.

Referring now to FIG. 82, FIG. 82 is a flowchart of a method 8200 for performing the tone-reversal process with CICE of polysilicon which includes the catalyst removal using a selective chemical etch and where the etch stop layer is removed in the final device in accordance with an embodiment of the present invention. FIGS. 83A-83D depict the top views for performing the tone-reversal process with CICE of polysilicon which includes the catalyst removal using a selective chemical etch and where the etch stop layer is removed in the final device using the steps described in FIG. 82 in accordance with an embodiment of the present invention. FIGS. 84A-84G depict the cross-section views for performing the tone-reversal process with CICE of polysilicon which includes the catalyst removal using a selective chemical etch and where the etch stop layer is removed in the final device using the steps described in FIG. 82 in accordance with an embodiment of the present invention.

Referring to FIG. 82, in conjunction with FIGS. 83A-83D and 84A-84G, in step 8201, an etch stop layer 8401 and a layer of polysilicon 8402 are deposited on a desired device, such as a device that includes a layer of desired material 8403 residing on a substrate 8404, as shown in FIGS. 84A-84B.

In step 8202, CICE is performed to etch portions of polysilicon 8402 leaving pillars 8405 of polysilicon as shown in FIGS. 83A and 84C.

In step 8203, exposed portions of etch stop layer 8401 (i.e., those portions of etch stop layer 8401 that are not covered by pillars 8405) are removed (i.e., etched), using various etching techniques, such as via ALE, as shown in FIG. 84D.

In step 8204, a deposition of oxide 8406 on pillars 8405 and the exposed regions of the desired device, such as material 8403 (i.e., those regions not covered by etch stop layer 8401), is performed as shown in FIGS. 83B and 84E.

In step 8205, an etchback of oxide 8406 to the top level of pillars 8405 as well as the removal of pillars 8405 and etch stop layer 8401, such as via various etching techniques (e.g., ALE), is performed as shown in FIGS. 83C and 84F.

In step 8206, desired material 8407 is then deposited, such as via CVD, PVD, ALD, etc., in the areas previously occupied by the removed pillars 8405 and the removed etch stop layer 8401 as shown in FIGS. 83D and 84G.

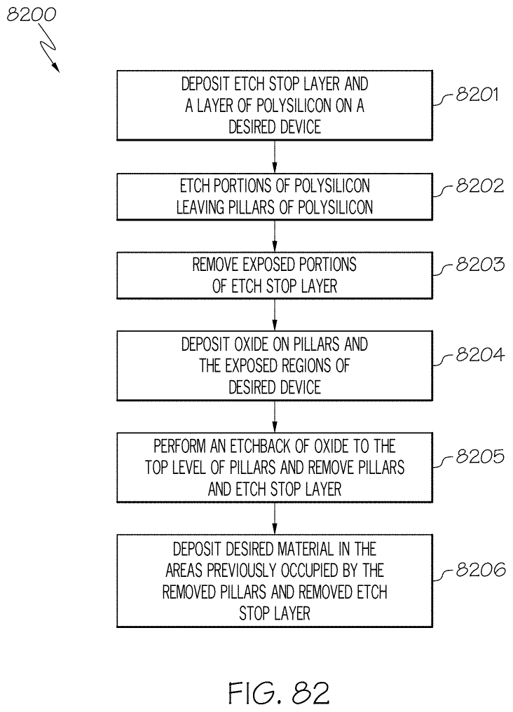

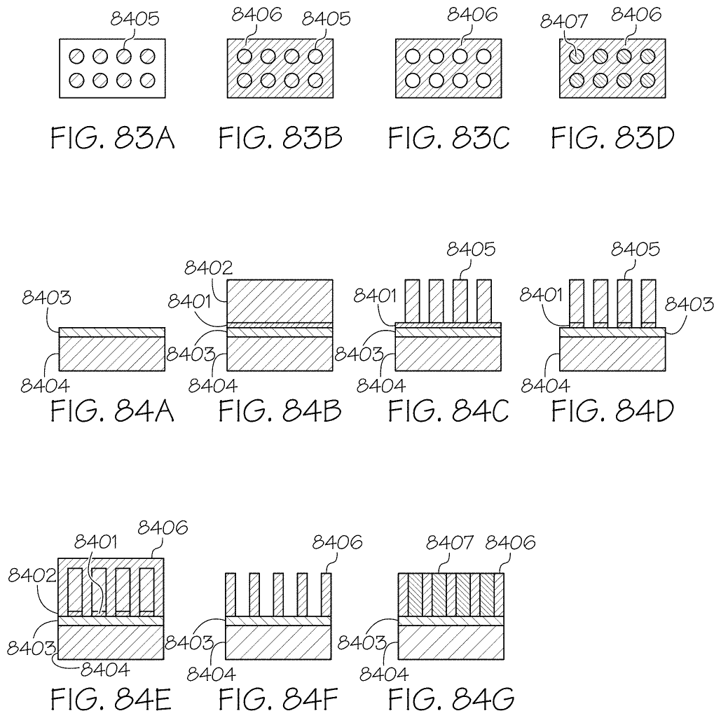

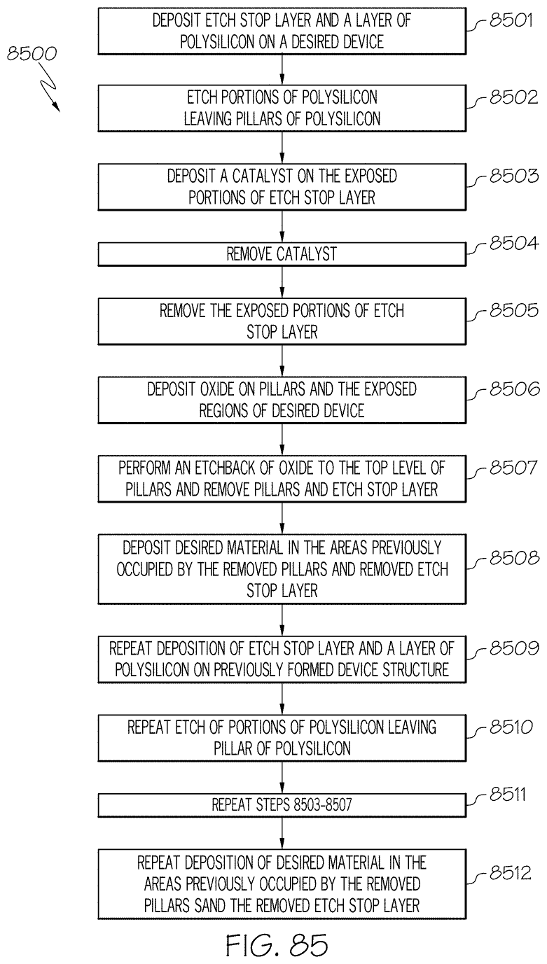

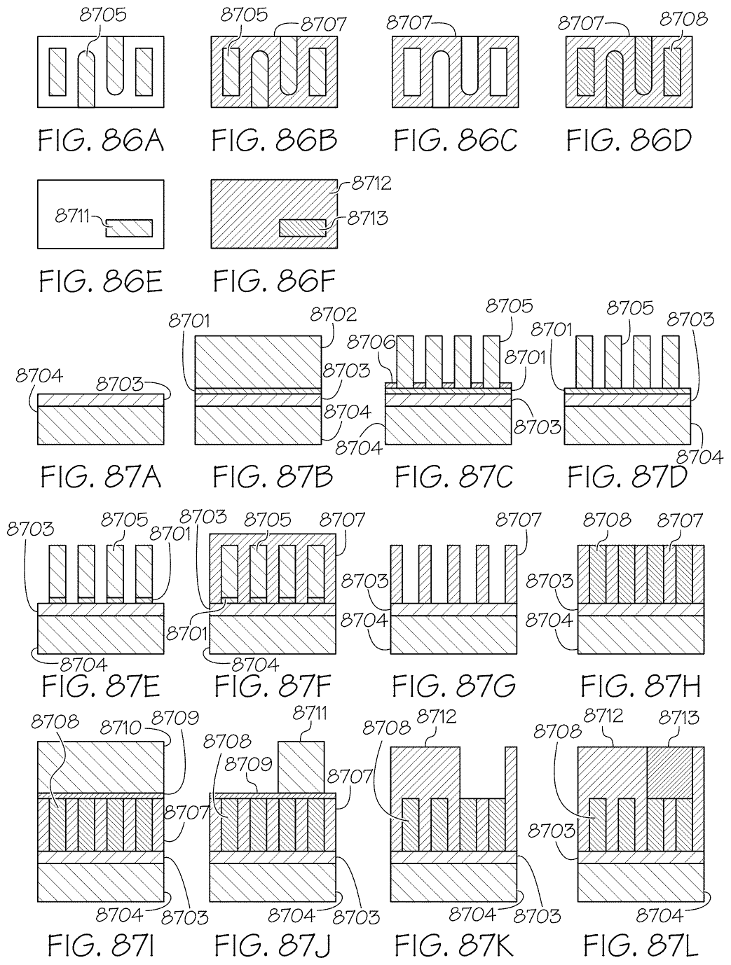

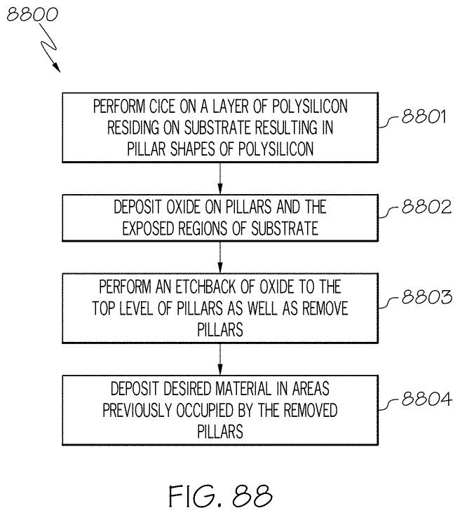

Referring now to FIG. 85, FIG. 85 is a flowchart of a method 8500 for fabricating metal interconnects and vias using a tone-reversal process with CICE of polysilicon in accordance with an embodiment of the present invention. FIGS. 86A-86F depict the top views for fabricating metal interconnects and vias using a tone-reversal process with CICE of polysilicon using the steps described in FIG. 85 in accordance with an embodiment of the present invention. FIGS. 87A-87L depict the cross-section views for fabricating metal interconnects and vias using a tone-reversal process with CICE of polysilicon using the steps described in FIG. 85 in accordance with an embodiment of the present invention.

Referring to FIG. 85, in conjunction with FIGS. 86A-86F and 87A-87L, in step 8501, an etch stop layer 8701 and a layer of polysilicon 8702 are deposited on a desired device, such as a device that includes a layer of desired material 8703 residing on a substrate 8704, as shown in FIGS. 87A-87B.

In step 8502, portions of polysilicon 8702 are etched, such as via CICE, leaving pillars 8705 of polysilicon as shown in FIGS. 86A and 87C.

In step 8503, a catalyst (e.g., Ru) 8706 is deposited on the exposed portions of etch stop layer 8701 (i.e., those portions of etch stop layer 8701 that are not covered by pillars 8705), such as via ALD, CVD, PVD, electroplating or thermal evaporation, as shown in FIGS. 86A and 87C.

In step 8504, catalyst 8706 is removed, such as via various etching techniques (e.g., dry etch, wet etch), as shown in FIG. 87D.

In step 8505, the exposed portions of etch stop layer 8701 (i.e., those portions of etch stop layer 8701 that are not covered by pillars 8705) are removed, such as via an etching technique (e.g., ALE), as shown in FIG. 87E.

In step 8506, a deposition of oxide 8707 on pillars 8705 and the exposed regions of the desired device, such as material 8703 (i.e., those regions not covered by etch stop layer 8701), is performed as shown in FIGS. 86B and 87F.

In step 8507, an etchback of oxide 8707 to the top level of pillars 8705 as well as the removal of pillars 8705 and etch stop layer 8701, such as via various techniques (e.g., dry etch, wet etch), is performed as shown in FIGS. 86C and 87G.

In step 8508, desired material 8708 is then deposited, such as via CVD, PVD, ALD, etc., in the areas previously occupied by the removed pillars 8705 and the removed etch stop layer 8701 as shown in FIGS. 86D and 87H.

In one embodiment, in step 8509, for the tone-reversal CICE, step 8501 is repeated, in which an etch stop layer 8709 and a layer of polysilicon 8710 are deposited on the device structure shown in FIGS. 86D and 87H, resulting in the structure shown in FIG. 87I

In step 8510, step 8502 is repeated, in which portions of polysilicon 8710 are etched, such as via CICE, leaving pillar 8711 of polysilicon as shown in FIGS. 86E and 87J.

In step 8511, steps 8503-8507 are repeated, resulting in the structure with oxide 8712 as shown in FIG. 87K.

In step 8512, step 8508 is repeated, in which desired material 8713 is then deposited, such as via CVD, PVD, ALD, etc., in the areas previously occupied by the removed pillars 8711 and the removed etch stop layer 8709 forming the structure shown in FIGS. 86F and 87L, in which the formed structure includes desired material 8713, 8708 and oxide 8712, 8707.

Steps 8509-8512 may continually be repeated for the desired number of metal and/or insulator layers.

In one embodiment, method 8500 is used for metal layers in interconnects, where the structural material is a low-k dielectric, such as silicon oxide or silicon oxynitride, and the desired material is a conductor, such as Cu, Mo, W, Ru, TiN, TaN, Pd, etc. In one embodiment, CICE is used for the fabrication of metal interconnects, and the catalyst, such as catalyst 8706, for CICE is Ru. In one embodiment, the catalyst, such as catalyst 8706, is not removed after CICE, and the Ru is used as a seed layer for electroplating of Cu to create Cu interconnects using the dual-damascene process. Other metals that can be deposited for interconnects include Ru, Co, Mo, TiN, Cu, W, TaN, etc. The metals can be deposited using ALD, CVD, PVD, electroplating or thermal evaporation. In one embodiment, Cu is deposited using electroplating, and polished using CMP.

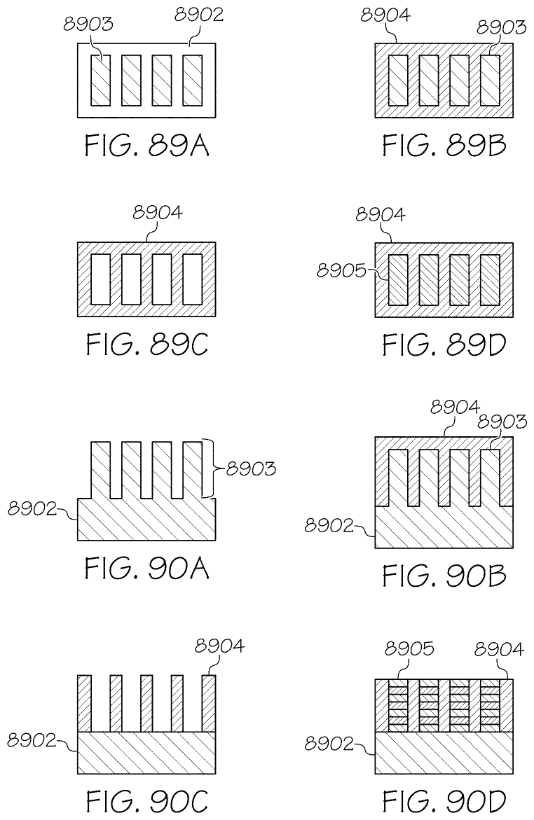

Tone-reversal CICE can be used to selectively grow superlattice structures in high aspect ratio holes, thereby enabling vertical, taper-free superlattice nanostructures with no sidewall damage, fabricated without the use of plasma etch for the superlattice materials. The superlattice materials may be deposited using selective atomic layer deposition, epitaxial growth, selective electrodeposition etc., such that each layer only grows on the previous layer deposited, and not on the structural material. FIGS. 88, 89A-89D and 90A-90D illustrate an exemplary process for making these structures. In one embodiment, the alternating layers are Si and SiGe, which are epitaxially grown, for applications in nanosheet FETs, and the structural material is an insulator.

FIG. 88 is a flowchart of a method 8800 for forming superlattices with tone-reversal CICE and selective growth in accordance with an embodiment of the present invention. FIGS. 89A-89D depict the top views for forming superlattices with tone-reversal CICE and selective growth using the steps described in FIG. 88 in accordance with an embodiment of the present invention. FIGS. 90A90D depict the cross-section views for forming superlattices with tone-reversal CICE and selective growth using the steps described in FIG. 88 in accordance with an embodiment of the present invention.

Referring to FIG. 88, in conjunction with FIGS. 89A-89D and 90A-90D, in step 8801, CICE is performed on a layer of polysilicon residing on substrate 8902 resulting in pillar shapes 8903 of polysilicon as shown in FIGS. 89A and 90A.

In step 8802, a deposition of oxide 8904 on pillars 8903 and the exposed regions of substrate 8902 is performed as shown in FIGS. 89B and 90B.

In step 8803, an etchback of oxide 8904 to the top level of pillars 8903 as well as the removal of pillars 8903, such as via various technique techniques (e.g., ALE), is performed as shown in FIGS. 89C and 90C.

In step 8804, desired material 8905 is then deposited, such as via CVD, PVD, ALD, etc., in the areas previously occupied by the removed pillars 8903 as shown in FIGS. 89D and 90D.

Roll-to-Roll (R2R) processes can be used for fabrication of silicon nanostructures using R2R deposition of silicon, R2R patterning, and R2R CICE. In one embodiment, polysilicon is deposited on a stainless steel roll and patterned using R2R nanoimprint lithography followed by removal of imprint resist residual layer thickness (RLT). Other substrates include foils of metals and metal alloys, polymer films and other flexible substrates. In another embodiment, a barrier layer is deposited between the roll substrate and the polysilicon. Barrier layers are chemically resistant to the CICE etchant solution and can act as an etch stop. Cr, Carbon, Al₂O₃ are examples of materials used for barrier layers.

Thin films of adhesion layer material and catalyst material are deposited using e-beam evaporation, thermal evaporation, physical vapor deposition, chemical vapor deposition, etc. Examples of thin films deposited include Ti, Au, Pt, Pd, Ag, Ru, RuO₂, Ir, IrO₂, TiN, W, Cu, etc. or any combination thereof. The catalyst patterned on polysilicon on the R2R substrate is then exposed to wet chemical etching for CICE. In one embodiment, the rolls are arranged in a vertical orientation, and the etchant is sprayed on the patterned side of the roll. In another embodiment, the CICE process is performed using vapor-phase etchants. In one embodiment, polysilicon nanowires are made using R2R processes for high density anodes in battery and ultracapacitor applications.

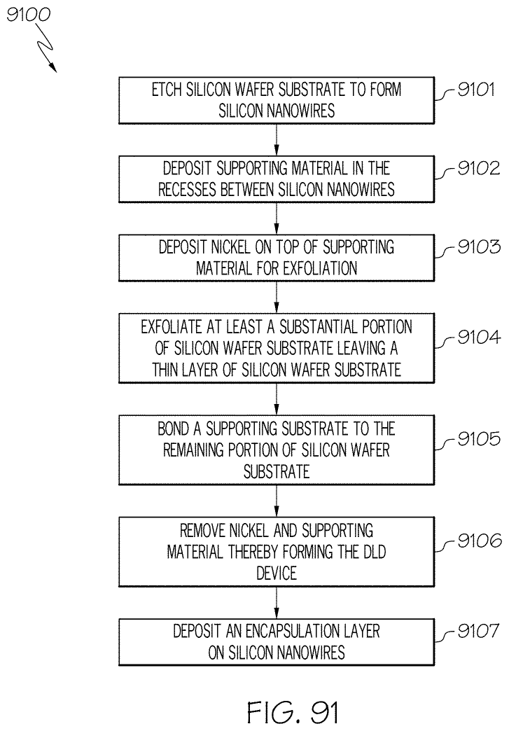

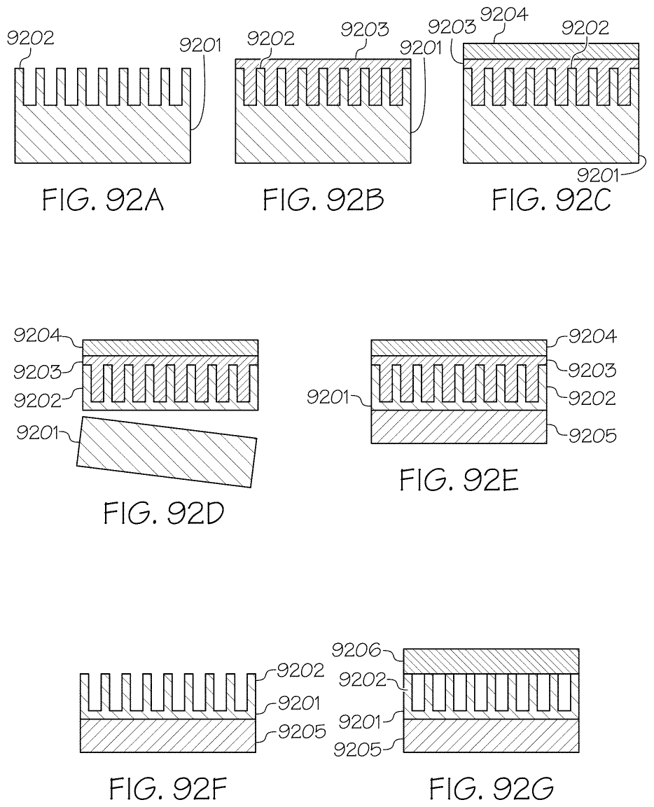

Deterministic Lateral Displacement (DLD) is a microfluidic technique which separates particles in a fluid medium based on their size, using specific arrangements of pillars arrays placed within a microfluidic channel. The gaps between the pillars and the placement of the pillars determine the separation mechanics. The pillar arrays required for DLD can be fabricated using nanolithography, such as nanoimprint lithography combined with the Catalyst Influenced Chemical Etching (CICE) process. In one embodiment, shown in FIGS. 91 and 92A-92G, the silicon pillars for DLD are made on a silicon wafer substrate. In another embodiment, the catalyst is not removed after CICE, and the DLD device is encapsulated. CICE etchant is flown through the device inlets to further etch the pillars in the encapsulated DLD device.

In one embodiment, exfoliation is used to remove a thin layer of silicon from the silicon pillars, such that the remaining silicon substrate can be polished and re-used. This process enables a reduction in cost for DLD device fabrication, which is discussed in Ward et al., “Design of Tool for Exfoliation of Monocrystalline Micro-Scale Silicon Films,” Journal of Micro and Nano-Manufacturing, Apr. 5, 2019, which is incorporated by reference herein in its entirety.

Referring to FIG. 91, FIG. 91 is a flowchart of a method 9100 for DLD device fabrication using CICE and silicon wafer exfoliation in accordance with an embodiment of the present invention. FIGS. 92A-92G depict the cross-section views for DLD device fabrication using CICE and silicon wafer exfoliation using the steps of FIG. 91 in accordance with an embodiment of the present invention.

Referring to FIG. 91, in conjunction with FIGS. 92A-92G, in step 9101, silicon wafer substrate 9201 is etched, such as via CICE, to form silicon nanowires (pillars) 9202 (also referred to herein as “silicon nanopillars”) as shown in FIG. 92A.

In step 9102, supporting material 9203 is deposited in the recesses between silicon nanowires 9202 as shown in FIG. 92B.

In step 9103, nickel 9204 is deposited on top of supporting material 9203 for exfoliation as shown in FIG. 92C.

In step 9104, at least a substantial portion of silicon wafer substrate 9201 is exfoliated leaving a thin layer of silicon wafer substrate 9201 as shown in FIG. 92D.

In step 9105, a supporting substrate 9205 is then bonded to the remaining portion of silicon wafer substrate 9201 as shown in FIG. 92E.

In step 9106, nickel 9204 and supporting material 9203 are removed, such as via an etching technique (e.g., ALE), thereby forming the DLD device as shown in FIG. 92F.

In step 9107, an encapsulation layer 9206 is deposited on silicon nanowires 9202 of the DLD device as shown in FIG. 92G.

In one embodiment, the pillars, such as silicon nanowires 9202, in the encapsulated DLD device may be further etched, such as via CICE, to increase the pillar height. For example, CICE etchant may be flown through the device inlets to further etch the pillars, such as silicon nanowires 9202, in the encapsulated DLD device.

Collapse of silicon nanopillars, such as silicon nanopillars 9202, in the DLD arrays limits the maximum height of the pillars. In one embodiment, the pillar height is increased by creating a ceiling structure on the silicon nanopillars using deposition of materials chemically resistant to the etchant, such as carbon, Cr, etc., which is discussed in Rouhani et al., “In-Situ Thermal Stability Analysis of Amorphous Carbon Films with Different Sp3 Content,” Carbon, Vol. 130, Apr. 1, 2018, pp. 401-409, which is incorporated by reference herein in its entirety.

In another embodiment, the ceiling structure, or stabilizing material, is made by co-sputtering an HF-resistant material with a HF-consumed material, thereby creating a porous mesh. In one embodiment, carbon and SiO₂ are co-sputtered to create a ceiling structure. When exposed to the CICE etchant, the SiO₂ is etched away, resulting in a porous carbon mesh. The porous carbon mesh structurally stabilizes the silicon nanopillars while the CICE etchant further increases their height.

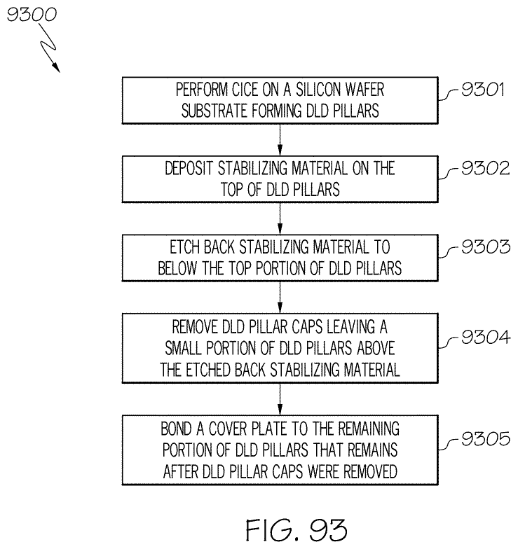

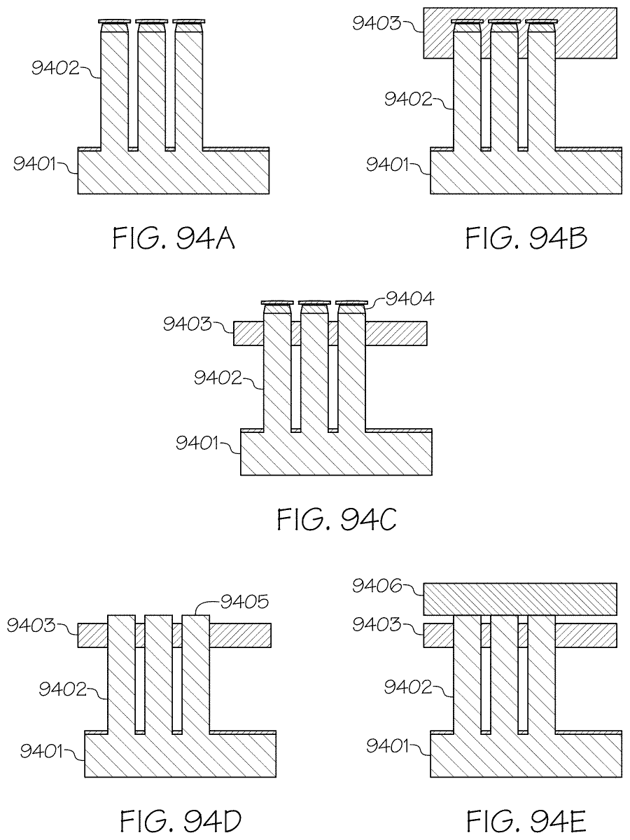

FIG. 93 is a flowchart of a method 9300 for bonding cover plates to the DLD pillars to create a DLD device after CICE without causing pillar collapse in accordance with an embodiment of the present invention. FIGS. 94A-94E depict the cross-section views for bonding cover plates to the DLD pillars to create a DLD device after CICE without causing pillar collapse using the steps of FIG. 93 in accordance with an embodiment of the present invention.

Referring to FIG. 93, in conjunction with FIGS. 94A-94E, in step 9301, CICE is performed on a silicon wafer substrate 9401 forming DLD pillars 9402 as shown in FIG. 94A.

In step 9302, stabilizing material 9403 is deposited via various deposition techniques, such as via CVD, PVD, ALD, etc., on the top of DLD pillars 9402 as shown in FIG. 94B.

In step 9303, stabilizing material 9403 is etched back to below the top portion of DLD pillars 9402 (referred to herein as the “DLD pillar caps 9404”) as shown in FIG. 94C.

In step 9304, DLD pillar caps 9404 are removed, such as via various etching techniques (e.g., ALE), leaving a small portion of DLD pillars 9402 (identified as element 9405) above the etched back stabilizing material 9403 as shown in FIG. 94D.

In step 9305, a cover plate 9406 is bonded to the remaining portion of DLD pillars 9405 that remains after DLD pillar caps 9404 were removed as shown in FIG. 94E. Such bonding may be performed using anodic bonding, fusion bonding, hybrid bonding, pneumatic suction, an adhesive, etc.

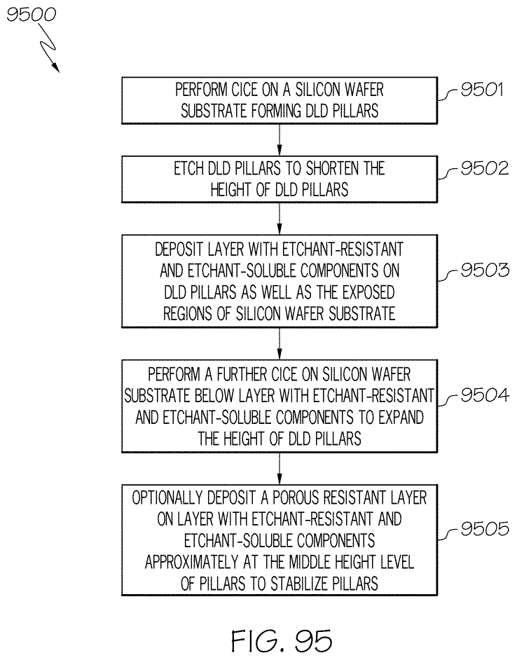

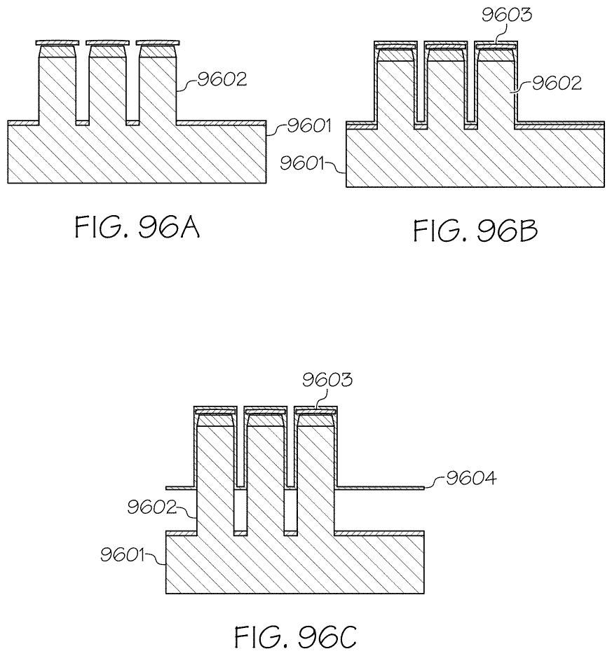

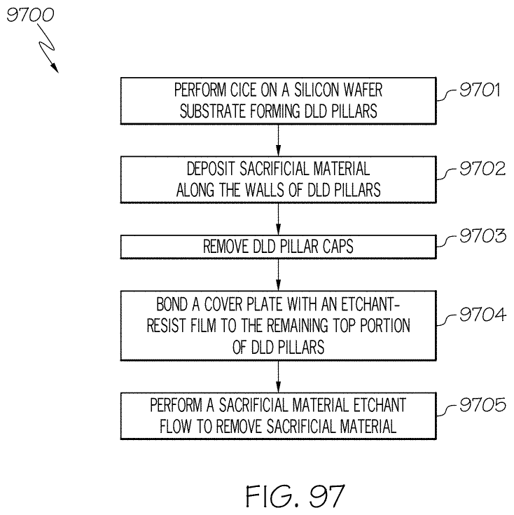

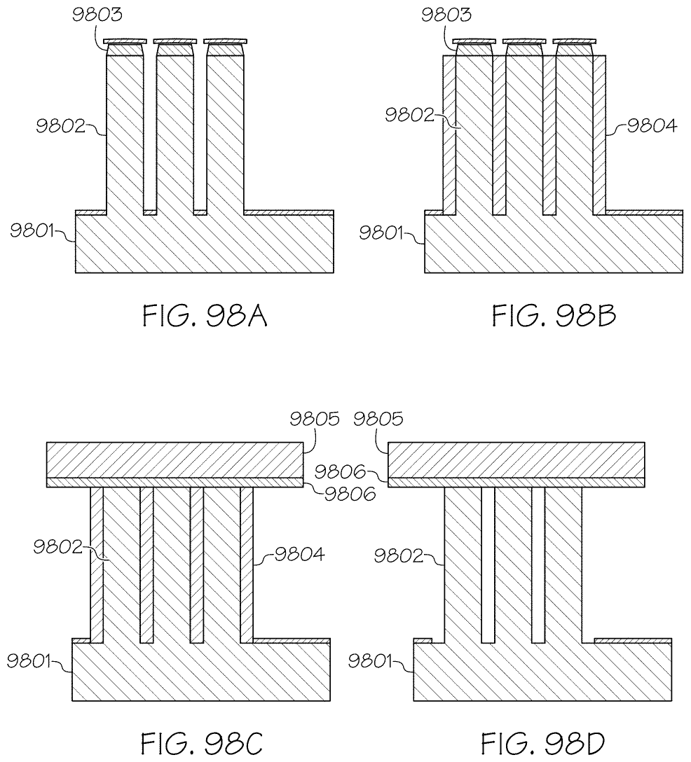

FIG. 95 is a flowchart of a method 9500 for improving pillar height using porous stabilizing material in accordance with an embodiment of the present invention. FIGS. 96A-96C depict the cross-section views for improving pillar height using porous stabilizing material using the steps of FIG. 95 in accordance with an embodiment of the present invention.

Referring to FIG. 95, in conjunction with FIGS. 96A-96C, in step 9501, CICE is performed on a silicon wafer substrate 9601 forming DLD pillars 9602.

In step 9502, DLD pillars 9602 are etched, such as via various etching techniques (e.g., ALE), to shorten the height of DLD pillars 9602 as shown in FIG. 96A.

In step 9503, a layer with etchant-resistant and etchant-soluble components 9603 is deposited on DLD pillars 9602 as well as the exposed regions of silicon wafer substrate 9601 as shown in FIG. 96B.

In step 9504, a further CICE is performed on silicon wafer substrate 9601 below layer 9603 to expand the height of DLD pillars resulting in the structure shown in FIG. 96C.

In step 9505, a porous resistant layer 9604, such as porous HF-resistant layer, is optionally deposited on layer 9603 approximately at the middle height level of pillars 9602 to stabilize pillars 9602 as shown in FIG. 96C.

FIG. 97 is a flowchart of a method 9700 for bonding the cover plate for the DLD device after CICE without causing pillar collapse in accordance with an embodiment of the present invention. FIGS. 98A-98D depict the cross-section views for bonding the cover plate for the DLD device after CICE without causing pillar collapse using the steps of FIG. 97 in accordance with an embodiment of the present invention.

Referring to FIG. 97, in conjunction with FIGS. 98A-98D, in step 9701, CICE is performed on a silicon wafer substrate 9801 forming DLD pillars 9802 as shown in FIG. 98A. Such DLD pillars 9802 include DLD pillars caps 9803, which refer to the top portion of DLD pillars 9402.

In step 9702, a sacrificial material 9804 (e.g., polyvinyl alcohol (PVA)) is deposited along the walls of DLD pillars 9802 as shown in FIG. 98B.

In step 9703, DLD pillar caps 9803 are removed, such as via various etching techniques (e.g., ALE), as shown in FIG. 98C.

In step 9704, a cover plate 9805 with an etchant-resist film 9806 is bonded to the remaining top portion of DLD pillars 9802 as shown in FIG. 98C. Such bonding may be performed using anodic bonding, fusion bonding, hybrid bonding, pneumatic suction, an adhesive, etc.

In step 9705, a sacrificial material etchant (e.g., deionized water) flow is performed to remove sacrificial material 9804 as shown in FIG. 98D. Optionally, a further CICE may be performed along with oxide growth and removal to fabricate thinner wires.

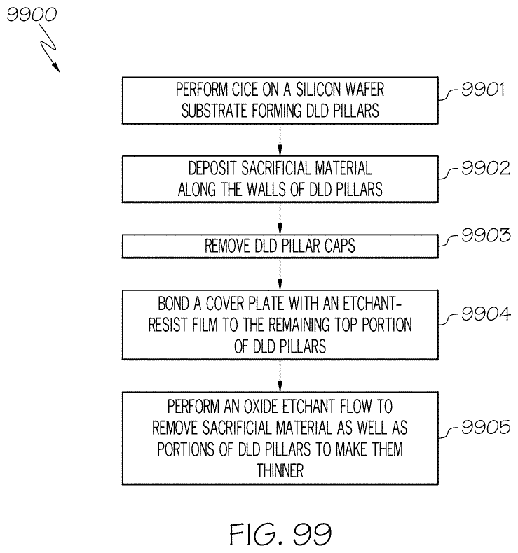

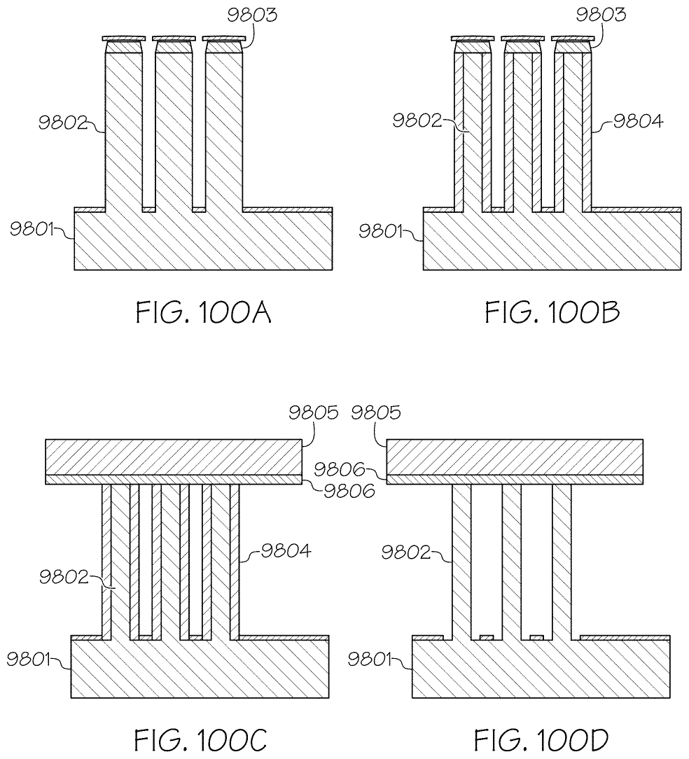

FIG. 99 is a flowchart of a method 9900 for improving collapse of thin pillars by starting with thick pillars and reducing pillar size after cover plate bonding in accordance with an embodiment of the present invention. FIGS. 100A-100D depict the cross-section views for improving collapse of thin pillars by starting with thick pillars and reducing pillar size after cover plate bonding using the steps of FIG. 99 in accordance with an embodiment of the present invention.

Referring to FIG. 99, in conjunction with FIGS. 100A-100D, in step 9901, CICE is performed on a silicon wafer substrate 9801 forming DLD pillars 9802 as shown in FIG. 100A. Such DLD pillars 9802 include DLD pillars caps 9803, which refer to the top portion of DLD pillars 9402.

In step 9902, a sacrificial material 9804 (e.g., polyvinyl alcohol (PVA)) is deposited along the walls of DLD pillars 9802 as shown in FIG. 100B.

In step 9903, DLD pillar caps 9803 are removed, such as via various etching techniques (e.g., ALE), as shown in FIG. 100C.

In step 9904, a cover plate 9805 with an etchant-resist film 9806 is bonded to the remaining top portion of DLD pillars 9802 as shown in FIG. 100C. Such bonding may be performed using anodic bonding, fusion bonding, hybrid bonding, pneumatic suction, an adhesive, etc.

In step 9905, an oxide etchant (e.g., dilute hydrofluoric acid) flow is performed to remove sacrificial material 9804 as well as portions of DLD pillars 9802 to make them thinner as shown in FIG. 100D.

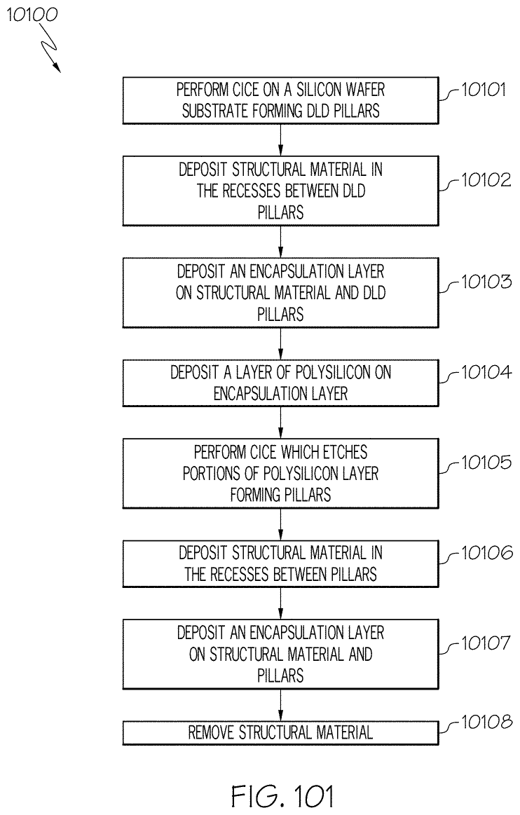

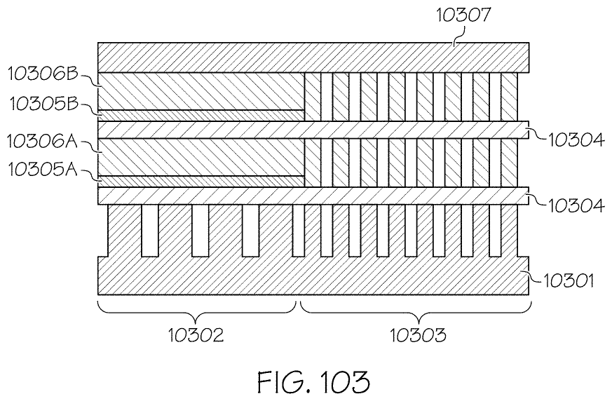

In another embodiment, multiple layers of DLD devices are made using polysilicon deposition and CICE, as discussed below in connection with FIGS. 101, 102A-102F and 103. The polysilicon may be recrystallized using laser recrystallization methods. In one embodiment, the structural material is a water-soluble polymer, such as PVA, and the material is removed by flowing water through the device after fabrication. The encapsulation layer may be made of glass, Cr, polymer, silicon, oxide-coated polymer, etc. In another embodiment, the multi-stack DLD pillars are made in the nanoscale feature size DLD regions as shown in FIG. 103. This may enable matching the flow resistance of the fluid sample in the micrometer-scale and nanometer-scale areas of the DLD device. In one embodiment, the porous layers between the multilayer stacks are made by co-sputtering an HF-resistant material with a HF-consumed material thereby creating a porous mesh. In one embodiment, carbon and SiO₂ are co-sputtered to create the porous layer. When exposed to the CICE etchant, the SiO₂ is etched away, resulting in a porous carbon mesh. The porous carbon mesh structurally stabilizes the silicon nanopillars and enables transport of fluid sample through the different layers of the DLD device.

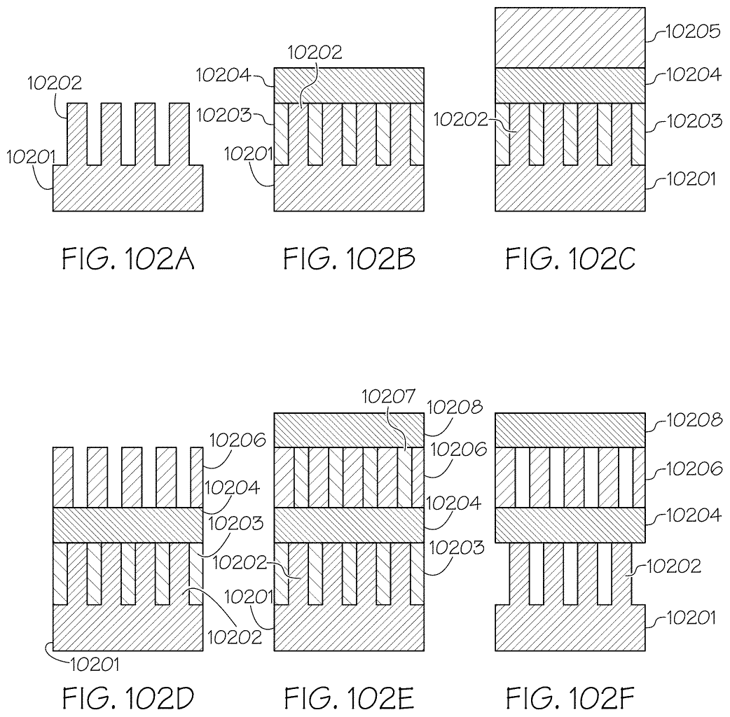

FIG. 101 is a flowchart of a method 10100 for multi-stack DLD device fabrication using CICE of polysilicon in accordance with an embodiment of the present invention. FIGS. 102A-102F depict the cross-section views for multi-stack DLD device fabrication using CICE of polysilicon using the steps of FIG. 101 in accordance with an embodiment of the present invention.

Referring to FIG. 101, in conjunction with FIGS. 102A-102F, in step 10101, CICE is performed on a silicon wafer substrate 10201 forming DLD pillars 10202 as shown in FIG. 102A.

In step 10102, structural material 10203 is deposited in the recesses between DLD pillars 10202 as shown in FIG. 102B.

In step 10103, an encapsulation layer 10204 is deposited on structural material 10203 and DLD pillars 10202 as shown in FIG. 102B.

In step 10104, a layer of polysilicon 10205 is deposited on encapsulation layer 10204 as shown in FIG. 102C.

In step 10105, CICE is performed which etches portions of polysilicon layer 10205 forming pillars 10206 as shown in FIG. 102D.

In step 10106, structural material 10207 is deposited in the recesses between pillars 10206 as shown in FIG. 102E.

In step 10107, an encapsulation layer 10208 is deposited on structural material 10207 and pillars 10206 as shown in FIG. 102E.

It is noted that steps 10104-10107 may be repeated to increase the number of DLD stacks.

In step 10108, structural material 10207, 10203 is removed, such as via various etching techniques (e.g., CICE), as shown in FIG. 102F.

FIG. 103 illustrates the cross-section of multi-stack DLD devices in nanoscale areas to improve the overall throughput in accordance with an embodiment of the present invention.

As shown in FIG. 103, substrate 10301 includes micrometer-scaled DLD pillars 10302 and nanometer-scaled DLD pillars 10303. Furthermore, as shown in FIG. 103, there are porous layers 10304 along with flow and etch stop layers 10305A-10305B below a layer of polysilicon 10306A-10306B, respectively. Additionally, FIG. 103 illustrates a cover plate 10307 placed on the top polysilicon layer 10306B and nanoscale DLD pillars 10303 located alongside the top polysilicon layer 10306B.

In one embodiment, particles separated by the DLD device can be detected on-chip using spectroscopy methods, such as surface enhanced Raman spectroscopy (SERS). The SERS substrates are integrated into the DLD chip with porous silicon for filtration of the carrier fluids, such that the particles to be detected are on the porous silicon. The particle detection can be enhanced by patterning SERS enhancement structures, such as gold nanostructures. In one embodiment, the porous silicon for the SERS detectors is made using CICE, where the areas with porous silicon are doped using ion implantation. Alternatively, areas with porous silicon are patterned with a higher CICE catalytic activity catalyst, such as Pt, Pd or Ru, while areas with non-porous DLD pillar arrays are patterned with a lower CICE catalytic activity catalyst, such as Au.

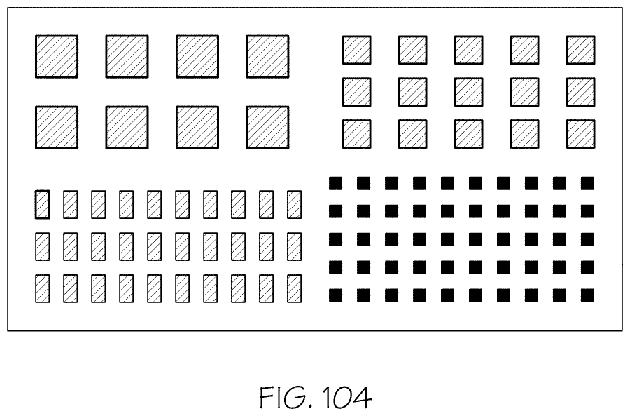

The ability of creating nanostructures with vertical sidewalls and varying critical dimensions and shapes can be used for applications, such as metalenses and metasurfaces. In one embodiment, a metasurface includes arrays of pillars with varying silicon nanopillar shapes and geometries, such that the metasurface can focus light with specific wavelengths, such as near IR and mid IR. Additionally, arrays can also be made of oxidized porous silicon, which enables focusing of visible wavelengths. FIG. 104 shows an exemplary pixel geometry where one section of the pillars is oxidized silicon. In particular, FIG. 104 illustrates a metasurface that includes four arrays of pillars for focusing of various wavelengths of light using silicon nanopillars and oxidized porous silicon nanopillars made by CICE in accordance with an embodiment of the present invention. Porous silicon pillars can be made by intentionally increasing the doping concentration of silicon in desired areas of the pixel using lithography and ion implantation. The CICE process is optimized to create porous silicon pillars in highly doped areas, and non-porous silicon pillars in low-doped areas of the material to be etched. In one embodiment, oxidation of the porous silicon nanopillars completely converts them to porous silicon oxide nanopillars while a thin oxide shell grows on non-porous pillars.

In one embodiment, 3D integration methods, such as nMASC, are used for integration of III-V detectors in the metasurfaces.

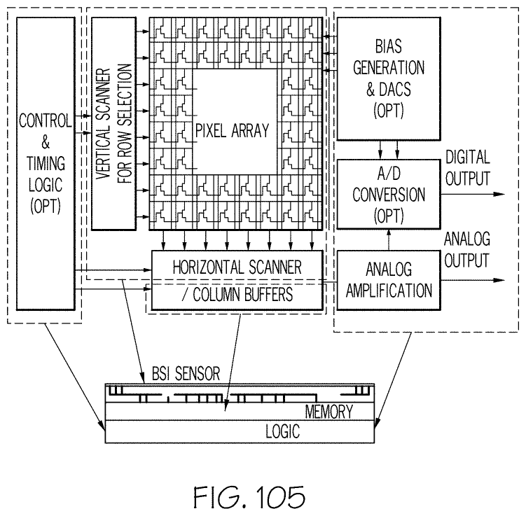

FIG. 105 illustrates an exemplary 3D stacked image sensor in accordance with an embodiment of the present invention.

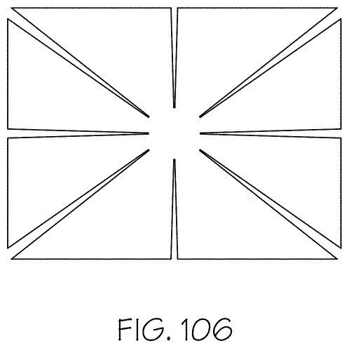

FIG. 106 illustrates an exemplary petal-ed imager die in accordance with an embodiment of the present invention.

The following discussion is based on FIGS. 105 and 106.

In one embodiment, the tool for pick and place assembly is used to assemble two or more fields, where at least one of the fields is a light sensitive pixel array, and at least a pair of fields are assembled one on top of another. In one embodiment, the tool for pick and place assembly is used to assemble two or more fields, where at least one of the fields is a light sensitive pixel array, and at least one of the fields is composed of logic circuits. In one embodiment, the tool for pick and place assembly is used to assemble two or more fields, where at least one of the fields is a light sensitive pixel array, and at least one of the fields is composed of logic circuits, and at least one of the fields is composed of memory circuits.

In one embodiment, the total thickness of the imager assembly is less than 25 μm. In one embodiment, groups of one or more pixels are addressed using logic circuit that physically lies underneath the pixels.

In one embodiment, one or more image sensors are curved into a spherical shape. The curvature of the imagers could be produced by pressurizing the front side of the imagers using a transfer chuck, while the backside of the imager conforms to a spherical mold. The mold could optionally be transparent. In one embodiment, the mold has adhesive on it to secure the curved imagers. The adhesive could be UV-curable. The UV curing could be performed from the backside of the transparent mold. In one embodiment, the adhesive is inkjetted prior to the imager curving. In one embodiment, multiple imagers are picked up from a source substrate, such as source substrate 103, and placed and curved onto a group of molds simultaneously. In one embodiment, the group of molds are made as a single contiguous part using a transparent polymer. In one embodiment, the edges of the imager dies are fixed during the assembly process. In one embodiment, the edges of the imager dies are unconstrained during the assembly process. In one embodiment, the imager has a petal-type structure. In one embodiment, the one or more edges of one or more petals reside behind an adjacent petal after the curving process.

In one embodiment, the throughput of DLD devices can be improved by stacking multiple DLD devices and running the samples in parallel. In one embodiment, the DLD devices are stacked using 3D integration techniques. In one embodiment, the 3D integration technique is n-MASC.

As a result of the foregoing, the principles of the present invention provide a means for utilizing the CICE process to effectively fabricate features in semiconductors using the equipment and process technologies for catalyst influenced chemical etching of the present invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A system for changing a relative position of a group of items, the system comprising:
a first set of parallel rails, wherein each parallel rail in said first set of parallel rails is moveable with respect to each other;
a second set of parallel rails, wherein each parallel rail in said second set of parallel rails is moveable with respect to each other and said first set of parallel rails; and
a guiding mechanism configured to guide one or more items of said group of items on one or more of said first and second sets of parallel rails.

2. The system as recited in claim 1, wherein said group of items comprises one or more of the following: chucks, die chucks, motion stages, short-stroke motion stages, actuators, thermal actuators, electromagnetic actuators, thermo-mechanical actuators, sensors, optical sensors, microscopes, moiré microscopes, and infrared moiré microscopes.

3. The system as recited in claim 1, wherein a precision in a change of a relative position of said one or more items of said group of items on one or more of said first and second sets of parallel rails using said guiding mechanism is sub-1 μm, sub-500 nm, sub-200 nm or sub-100 nm.

4. The system as recited in claim 1, wherein bearings for said one or more of said first and second sets of parallel rails and said one or more items of said group of items that are guided on said first and second sets of parallel rails comprise one or more of the following: air bearings, fluidic bearings, flexure bearings, and electromagnetic bearings.

5. The system as recited in claim 1 further comprising:
an actuation mechanism configured to actuate said one or more of said first and second sets of parallel rails and said one or more items of said group of items, wherein said actuation mechanism comprises one or more of the following: linear motors, voice coils, electromagnetic actuators, thermal actuators, and pneumatic actuators.

6. The system as recited in claim 1 further comprising:
a motion sensing mechanism configured to detect a change of a relative position of said one or more items of said group of items on one or more of said first and second sets of parallel rails using said guiding mechanism, wherein said motion sensing mechanism comprises one or more of the following: capacitive sensors, laser sensors, optical sensors, imagers, and moiré microscopes.

7. The system as recited in claim 1 further comprising:
a clamping mechanism for clamping said one or more items of said group of items onto a substrate, wherein said clamping mechanism comprises one or more of the following: a vacuum, magnetic forces, and electrostatic forces.

8. The system as recited in claim 1, wherein said group of items comprises die chucks configured to pick die from a first substrate and place said picked die onto a second substrate, wherein said die chucks change a relative position of said die.

9. A method to chuck dies of various sizes, the method comprising:
identifying addressable regions of one or more dies using vacuum or electrostatic attraction; and
chucking said one or more dies using said identified addressable regions, wherein said one or more dies have a size ranging from 0.5 mm on a side to 200 mm on said side, wherein said chucking utilizes a material that has a higher hardness in comparison to said one or more dies.

10. The method as recited in claim 9, wherein said addressable regions are identified using one or more of an array of the following: thin film transistors, pneumatic valves, and inkjettable transient materials.

11. The method as recited in claim 9, wherein said one or more dies comprise one or more substrates of various sizes.

12. A three-dimensional (3D) integrated circuit (IC), comprising:
one or more two-dimensional (2D)-die, wherein said one or more 2D-die are fabricated by assembling said one or more 2D-die onto a product substrate, wherein one or more of said one or more 2D-die comprise a light sensitive pixel array, wherein said assembling is enabled by:
selectively picking said one or more 2D-die from a source wafer by a superstrate attached to said one or more 2D-die; and
placing and bonding said selectively picked one or more 2D-die onto said product substrate with precision overlay, wherein said precision overlay is enabled by a fluid deployed between said one or more 2D-die and said product substrate, wherein said precision overlay comprises a difference between a vector position of points on said one or more 2D-die and a vector position of corresponding points on said product substrate.

13. The 3D IC as recited in claim 12, wherein said 3D IC is an application specific integrated circuit (ASIC) system.

14. The 3D IC as recited in claim 12, wherein said 3D IC is a system-on-a chip (SoC).

15. The 3D IC as recited in claim 12, wherein said 3D IC comprises logic and memory circuitry.

16. The 3D IC as recited in claim 12, wherein said 3D IC comprises a system designed using any of the following design approaches: a two-dimensional (2D) logic implementation with a three-dimensional (3D) memory implementation, a 3D logic implementation with a 2D memory implementation, and a 3D logic implementation with a 3D memory implementation.

17. The 3D IC as recited in claim 12, wherein said 3D IC comprises a system that utilizes one or more of the following: Static Random Access Memory (SRAM), 3D SRAM, 3D stand-alone stacked SRAM, a 3D only-bitcell stacked SRAM, Dynamic Random Access Memory (DRAM), 3D DRAM, analog IP and input/output.

18. The 3D IC as recited in claim 12, wherein said one or more 2D-die comprise multiple die.

19. The 3D IC as recited in claim 12, wherein said precision overlay between said one or more 2D-die and said product substrate is achieved using a nanometer overlay metrology scheme.

20. The 3D IC as recited in claim 12, wherein a thickness of said one or more 2D-die is less than one of the following: 10 μm, 1 μm and 100 nm.

21. The 3D IC as recited in claim 12, wherein said source wafer is one of the following: a silicon wafer, a non-silicon wafer comprising GaN, GaAs, InP or SiC, and sapphire

22. The 3D IC as recited in claim 12, wherein said source wafer incorporates a sacrificial layer.

23. The 3D IC as recited in claim 22, wherein said source wafer incorporated with said sacrificial layer is constructed from a substrate with two or more layers of differing doping levels and/or types.

24. The 3D IC as recited in claim 12, wherein said 3D IC is an imager.

25. The 3D IC as recited in claim 24, wherein said imager is curved.
